(19) United States
(12) Patent Application Publication
(10) Pub. No.: US 2025/0344501 A1
(43) Pub. Date: Nov. 6, 2025

(54) COMPLEMENTARY METAL OXIDE TRANSISTORS USING CHANNEL-TYPE MODULATION AND METHODS FOR FORMING THE SAME

(71) Applicant: Taiwan Semiconductor Manufacturing Company Limited, Hsinchu (TW)

(72) Inventors: Chih-Yu Chang, New Taipei City (TW); Georgios Vellianitis, Heverlee (BE); Gerben Doornbos, Kessel-Lo (BE); Viraj Nilesh Madhiwala, Kessel-Lo (BE); Marcus Johannes Henricus Van Dal, Linden (BE); Kuo-Chang Chiang, Hsinchu (TW); Katherine H. Chiang, New Taipei City (TW)

(21) Appl. No.: 18/655,240

(22) Filed: May 4, 2024

(51) Int. Cl. H01L 27/092; H01L 21/822; H01L 21/8238; H01L 23/522; H01L 23/528; H01L 27/06; H01L 29/786

(52) U.S. Cl. CPC H10D 84/856; H01L 23/5226; H01L 23/5283; H10D 30/6756; H10D 30/6757; H10D 84/0167; H10D 84/017; H10D 84/0177; H10D 84/0186; H10D 84/038; H10D 88/00; H10D 88/01

(57) ABSTRACT

A combination of a first-type insulating surface and a second-type insulating surface may be formed over a substrate. The first-type insulating surface is a surface of a hydrogen-containing dielectric material, and the second-type insulating surface of a hydrogen-impermeable surface. An amorphous metal oxide layer may be deposited on the first-type insulating surface and the second-type insulating surface. An anneal process may be performed at an elevated temperature. A first portion of the amorphous metal oxide layer in contact with the first-type insulating surface is converted into a p-type metal oxide semiconductor layer, and a second portion of the amorphous metal oxide layer in contact with the second-type insulating surface is converted into an n-type metal oxide semiconductor layer. Complementary thin-film transistors may be formed using the semiconductor structure.

### BACKGROUND

A complementary transistor (e.g., thin film transistor or TFT) circuit requires p-channel transistors and n-channel transistors. P-channel transistors include a p-type semiconductor material as a channel material, and n-channel transistors include an n-type semiconductor material as a channel material. In instances in which a transistor operates in an accumulation mode, the conductivity type of charge carriers during operation may be the same as the conductivity type of the channel material. In thin film transistors operating in an accumulation mode, holes are the charge carriers in p-channel thin film transistors, and electrons are charge carriers in n-channel thin film transistors. Typically, a p-type compound semiconductor material and an n-type compound semiconductor material are typically separately deposited to form p-channel transistors and n-channel transistors. Multiple processing steps are used to deposit and to pattern the two types of compound semiconductor materials. This contributes greatly to an increase in the manufacturing cost.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a vertical cross-sectional view of a first exemplary structure after formation of complementary metal-oxide-semiconductor (CMOS) transistors, first metal interconnect structures formed in lower-level dielectric layers, an insulating material layer, and an optional etch stop dielectric layer according to an embodiment of the present disclosure.

FIGS. 2A and 2B are vertical cross-sectional views of regions of the first exemplary structure after formation of a first electrically conductive material layer, a first hydrogen-containing dielectric layer, a second electrically conductive material layer, a first hydrogen-blocking dielectric layer, and a third electrically conductive material layer according to an embodiment of the present disclosure.

FIGS. 3A and 3B are vertical cross-sectional views of regions of the first exemplary structure after patterning the first hydrogen-blocking dielectric layer and the third electrically conductive material layer according to an embodiment of the present disclosure.

FIGS. 4A and 4B are vertical cross-sectional views of regions of the first exemplary structure after formation of a second hydrogen-containing dielectric layer and a fourth electrically conductive material layer according to an embodiment of the present disclosure.

FIGS. 5A and 5B are vertical cross-sectional views of regions of the first exemplary structure after patterning the second hydrogen-containing dielectric layer and the fourth electrically conductive material layer according to an embodiment of the present disclosure.

FIGS. 6A and 6B are vertical cross-sectional views of regions of the first exemplary structure after formation of a second hydrogen-blocking dielectric layer and a fifth electrically conductive material layer according to an embodiment of the present disclosure.

FIGS. 7A and 7B are vertical cross-sectional views of regions of the first exemplary structure after patterning the second hydrogen-blocking dielectric layer and the fifth electrically conductive material layer according to an embodiment of the present disclosure.

FIGS. 8A and 8B are vertical cross-sectional views of regions of the first exemplary structure after formation of first via cavities according to an embodiment of the present disclosure.

FIGS. 9A and 9B are vertical cross-sectional views of regions of the first exemplary structure after formation of second via cavities according to an embodiment of the present disclosure.

FIGS. 10A and 10B are vertical cross-sectional views of regions of the first exemplary structure after formation of third via cavities according to an embodiment of the present disclosure.

FIGS. 11A and 11B are vertical cross-sectional views of regions of the first exemplary structure after deposition of an amorphous metal oxide layer according to an embodiment of the present disclosure.

FIGS. 12A and 12B are vertical cross-sectional views of regions of the first exemplary structure after deposition of a gate dielectric layer according to an embodiment of the present disclosure.

FIGS. 13A and 13B are vertical cross-sectional views of regions of the first exemplary structure after conversion of the amorphous metal oxide layer into p-type metal oxide semiconductor layers and n-type metal oxide semiconductor layers according to an embodiment of the present disclosure.

FIGS. 14A and 14B are vertical cross-sectional views of regions of the first exemplary structure after formation of gate electrodes according to an embodiment of the present disclosure.

FIGS. 15A and 15B are vertical cross-sectional views of regions of the first exemplary structure after patterning the electrically conductive material layers, the hydrogen-containing dielectric layers, and the hydrogen-blocking dielectric layers according to an embodiment of the present disclosure.

FIGS. 16A and 16B are vertical cross-sectional views of regions of the first exemplary structure after formation of a contact-level dielectric layer and contact via structures according to an embodiment of the present disclosure.

FIGS. 17A and 17B are top down views of configurations of a field effect transistor stack and contact via structures in the first exemplary structure according to embodiments of the present disclosure.

FIG. 18 is a vertical cross-sectional view of a region of a second exemplary structure after formation of a hydrogen-containing dielectric layer according to an embodiment of the present disclosure.

FIG. 19 is a vertical cross-sectional view of a region of the second exemplary structure after formation of recess regions according to an embodiment of the present disclosure.

FIG. 20 is a vertical cross-sectional view of a region of the second exemplary structure after formation of hydrogen-blocking dielectric material portions according to an embodiment of the present disclosure.

FIG. 21 is a vertical cross-sectional view of a region of the second exemplary structure after formation of source/drain cavities according to an embodiment of the present disclosure.

FIG. 22 is a vertical cross-sectional view of a region of the second exemplary structure after formation of source/drain electrodes according to an embodiment of the present disclosure.

FIG. 23 is a vertical cross-sectional view of a region of the second exemplary structure after formation of an amorphous metal oxide layer and a gate dielectric layer according to an embodiment of the present disclosure.

FIG. 24 is a vertical cross-sectional view of a region of the second exemplary structure after conversion of the amorphous metal oxide layer into p-type metal oxide semiconductor layers and n-type metal oxide semiconductor layers according to an embodiment of the present disclosure.

FIG. 25 is a vertical cross-sectional view of a region of the second exemplary structure after deposition of a gate electrode material layer according to an embodiment of the present disclosure.

FIG. 26 is a vertical cross-sectional view of a region of the second exemplary structure after patterning gate structures according to an embodiment of the present disclosure.

FIG. 27 is a vertical cross-sectional view of a region of the second exemplary structure after formation of a contact-level dielectric layer and gate contact via structures according to an embodiment of the present disclosure.

FIG. 28 is a vertical cross-sectional view of a region of an alternative configuration of the second exemplary structure after formation of a contact-level dielectric layer and gate contact via structures according to an embodiment of the present disclosure.

FIG. 29 is a vertical cross-sectional view of a region of a third exemplary structure after formation of gate electrodes in a dielectric matrix layer according to an embodiment of the present disclosure.

FIG. 30 is a vertical cross-sectional view of a region of the third exemplary structure after formation of gate dielectric component layers according to an embodiment of the present disclosure.

FIG. 31 is a vertical cross-sectional view of a region of the third exemplary structure after patterning a second gate dielectric component layer according to an embodiment of the present disclosure.

FIG. 32 is a vertical cross-sectional view of a region of the third exemplary structure after deposition of a hydrogen-containing dielectric layer according to an embodiment of the present disclosure.

FIG. 33 is a vertical cross-sectional view of a region of the third exemplary structure after patterning the hydrogen-containing dielectric layer according to an embodiment of the present disclosure.

FIG. 34 is a vertical cross-sectional view of a region of the third exemplary structure after deposition of an amorphous metal oxide layer according to an embodiment of the present disclosure.

FIG. 35 is a vertical cross-sectional view of a region of the third exemplary structure after patterning the amorphous metal oxide layer according to an embodiment of the present disclosure.

FIG. 36 is a vertical cross-sectional view of a region of the third exemplary structure after converting the amorphous metal oxide layer into p-type metal oxide semiconductor layers and n-type metal oxide semiconductor layers according to an embodiment of the present disclosure.

FIG. 37 is a vertical cross-sectional view of a region of the third exemplary structure after formation of a contact-level dielectric layer and source/drain cavities according to an embodiment of the present disclosure.

FIG. 38 is a vertical cross-sectional view of a region of the third exemplary structure after formation of source/drain electrodes according to an embodiment of the present disclosure.

FIG. 39 is a vertical cross-sectional view of a region of a fourth exemplary structure after deposition of a first gate dielectric component layer and a hydrogen-containing dielectric layer and patterning the hydrogen-containing dielectric layer according to an embodiment of the present disclosure.

FIG. 40 is a vertical cross-sectional view of a region of the fourth exemplary structure after deposition of a second gate dielectric component layer according to an embodiment of the present disclosure.

FIG. 41 is a vertical cross-sectional view of a region of the fourth exemplary structure after patterning the hydrogen-blocking dielectric layer according to an embodiment of the present disclosure.

FIG. 42 is a vertical cross-sectional view of a region of the fourth exemplary structure after deposition of an amorphous metal oxide layer according to an embodiment of the present disclosure.

FIG. 43 is a vertical cross-sectional view of a region of the fourth exemplary structure after patterning the amorphous metal oxide layer according to an embodiment of the present disclosure.

FIG. 44 is a vertical cross-sectional view of a region of the fourth exemplary structure after converting the amorphous metal oxide layer into p-type metal oxide semiconductor layers and n-type metal oxide semiconductor layers according to an embodiment of the present disclosure.

FIG. 45 is a vertical cross-sectional view of a region of the fourth exemplary structure after formation of a contact-level dielectric layer and source/drain cavities according to an embodiment of the present disclosure.

FIG. 46 is a vertical cross-sectional view of a region of the fourth exemplary structure after formation of source/drain electrodes according to an embodiment of the present disclosure.

FIG. 47 is a vertical cross-sectional view of the first exemplary structure after formation of upper-level metal interconnect structures according to an embodiment of the present disclosure.

FIG. 48 is a vertical cross-sectional view of the second, third, or fourth exemplary structure after formation of upper-level metal interconnect structures according to an embodiment of the present disclosure.

FIG. 49 is a first flowchart that illustrates the general processing steps for manufacturing the semiconductor devices of the present disclosure.

FIG. 50 is a second flowchart that illustrates the general processing steps for manufacturing the semiconductor devices of the present disclosure.

### DETAILED DESCRIPTION

The following disclosure provides many different embodiments, or examples, for implementing different features of the provided subject matter. Specific examples of components and arrangements are described below to simplify the present disclosure. These are merely examples, and are not limiting. Drawings are not drawn to scale. Elements with the same reference numerals refer to the same element, and are presumed to have the same material composition and the same thickness range unless expressly indicated otherwise. Embodiments are expressly contemplated in which multiple instances of any described element are repeated unless expressly stated otherwise. Embodiments are expressly contemplated in which non-essential elements are omitted even if such embodiments are not expressly disclosed but are known in the art.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure is directed to semiconductor devices using composition-modulated metal oxide semiconductor materials and methods for manufacturing the same. Specifically, electrical conductivity of a metal oxide semiconductor material is modulated through control of local density of oxygen vacancies. A local high concentration of oxygen vacancies in a metal oxide semiconductor material may induce n-type conductivity, and a local low concentration of oxygen vacancies in the metal oxide semiconductor material may induce p-type conductivity. According to an aspect of the present disclosure, an n-type semiconductor material may be provided by increasing the concentration of oxygen vacancies within a first portion of the metal oxide semiconductor material, and a p-type semiconductor material is provided by decreasing the concentration of oxygen vacancies within a second portion of the metal oxide semiconductor material.

According to an aspect of the present disclosure, embodiments of the present disclosure enhance the efficiency of fabricating complementary field-effect transistors by using a single semiconductor channel material deposition process that may be subsequently used to form n-type and p-type metal oxide semiconductor channels. This innovative approach eliminates the need for separate channel material deposition processes that are traditionally required for each type of semiconductor material, thereby reducing manufacturing costs and processing time. Furthermore, embodiments of the present disclosure may facilitate the integration of complementary field effect transistors into various electronic devices by simplifying the manufacturing process and enhancing the scalability of production. The single deposition process used by various embodiments disclosed herein not only streamlines the overall manufacturing sequence, but also ensures consistent process control and reliability of device characteristics for the complementary field effect transistors.

According to an aspect of the present disclosure, an n-type metal oxide semiconductor layer and a p-type metal oxide semiconductor layer may be provided by depositing an amorphous metal oxide layer using a single deposition process, and by locally modulating the conductivity type of the deposited amorphous metal oxide layer during an anneal process. An n-type metal oxide semiconductor material may be formed by promoting hydrogen diffusion from a hydrogen-containing dielectric layer into a first portion of the metal oxide semiconductor layer. For example, in some embodiments, an n-type metal oxide semiconductor material may be formed by promoting hydrogen diffusion from a hydrogen-containing dielectric layer into a first portion of the metal oxide semiconductor layer during an anneal process that crystallizes the amorphous metal oxide layer. However, in other embodiments, the n-type metal oxide semiconductor material may be formed by promoting hydrogen diffusion from a hydrogen-containing dielectric layer into a first portion of an amorphous metal oxide layer. Further, a hydrogen-blocking dielectric layer such as an alkaline-earth oxide layer may be in direct contact with a second portion of the metal oxide semiconductor layer to inhibit hydrogen diffusion into the second portion of the amorphous metal oxide layer, thereby forming a p-type metal oxide semiconductor layer during the anneal process.

By enabling formation of a p-type metal oxide semiconductor layer and an n-type semiconductor layer using only a single amorphous metal oxide deposition process, the various embodiment methods disclosed herein may facilitate the manufacture of various types of thin-film transistor devices using complementary metal-oxide-semiconductor (CMOS) circuits. Further, the various embodiments disclosed herein facilitate the process flow and device integration for vertical thin-film transistors by providing p-type metal oxide semiconductor layers and n-type semiconductor layers that are vertically stacked. For example, CMOS inverters including vertical channels of different conductivities may be formed in a single via cavity. Thus, formation of a high-density CMOS thin-film transistor circuits may be facilitated through embodiments of the present disclosure. The various aspects of the present disclosure are now described with reference to accompanying drawings.

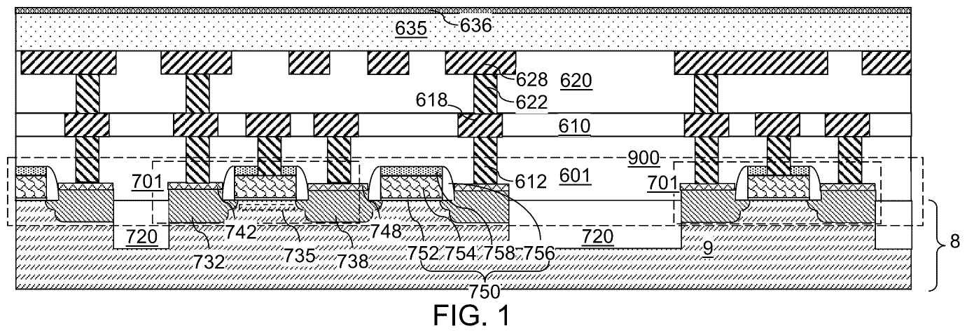

Referring to FIG. 1, a first exemplary structure according to an embodiment of the present disclosure is illustrated. The exemplary structure includes a substrate 8. Generally, the substrate 8 comprises, and/or consists essentially of, at least one material selected from an insulating material, a semiconductor material, and a metallic material. In one embodiment, the substrate 8 may be a semiconductor substrate such as a commercially available silicon substrate. The substrate 8 may include a semiconductor material layer 9 at least at an upper portion thereof. The semiconductor material layer 9 may be a surface portion of a bulk semiconductor substrate, or may be a top semiconductor layer of a semiconductor-on-insulator (SOI) substrate. In one embodiment, the semiconductor material layer 9 includes a single crystalline semiconductor material such as single crystalline silicon. In one embodiment, the substrate 8 may include a single crystalline silicon substrate including a single crystalline silicon material.

Shallow trench isolation structures 720 including a dielectric material such as silicon oxide may be formed in an upper portion of the semiconductor material layer 9. Suitable doped semiconductor wells, such as p-type wells and n-type wells, may be formed within each area that is laterally enclosed by a portion of the shallow trench isolation structures 720. Field effect transistors 701 may be formed over the top surface of the semiconductor material layer 9. For example, each field effect transistor 701 may include a source region 732, a drain region 738, a semiconductor channel 735 that includes a surface portion of the substrate 8 extending between the source region 732 and the drain region 738, and a gate structure 750. The semiconductor channel 735 may include a single crystalline semiconductor material. Each gate structure 750 may include a gate dielectric layer 752, a gate electrode 754, a gate cap dielectric 758, and a dielectric gate spacer 756. A source-side metal-semiconductor alloy region 742 may be formed on each source region 732, and a drain-side metal-semiconductor alloy region 748 may be formed on each drain region 738.

One or more of the field effect transistors 701 in a CMOS circuitry 900 may include a semiconductor channel 735 that contains a portion of the semiconductor material layer 9 in the substrate 8. In embodiments in which the semiconductor material layer 9 includes a single crystalline semiconductor material such as single crystalline silicon, the semiconductor channel 735 of each field effect transistor 701 in the CMOS circuitry 900 may include a single crystalline semiconductor channel such as a single crystalline silicon channel.

In one embodiment, the substrate 8 may include a single crystalline silicon substrate, and the field effect transistors 701 may include a respective portion of the single crystalline silicon substrate as a semiconducting channel. As used herein, a “semiconducting” element may refer to an element having electrical conductivity in the range from 1.0×10⁻⁵ S/m to 1.0×10⁵ S/m. As used herein, a “semiconductor material” may refer to a material having electrical conductivity less than 1.0 S/m in the absence of electrical dopants therein, and is capable of producing a doped material having electrical conductivity in a range from 1.0 S/m to 1.0×10⁷ S/m upon suitable doping with an electrical dopant. As used herein, a dielectric material or an insulating material refers to a material having electrical conductivity less than 1.0×10⁻⁵ S/m. A conductive material refers to a material having electrical conductivity greater than 1.0×10⁵ S/m or otherwise expressly identified as a conductive material in this disclosure. All measurements are taken at the standard condition, i.e., at 0 degrees Celsius and at 1 atmospheric pressure.

Various metal interconnect structures formed within dielectric layers may be subsequently formed over the substrate 8 and the semiconductor devices thereupon (such as field effect transistors 701). In an illustrative example, the dielectric layers may include, for example, a contact-level dielectric layer 601 that may be a layer that surrounds the contact structure connected to the source and drains, a first interconnect-level dielectric layer 610, and a second interconnect-level dielectric layer 620. The metal interconnect structures may include device contact via structures 612 formed in the contact-level dielectric layer 601 and contact a respective component of the CMOS circuitry 900, first metal line structures 618 formed in the first interconnect-level dielectric layer 610, first metal via structures 622 formed in a lower portion of the second interconnect-level dielectric layer 620, and second metal line structures 628 formed in an upper portion of the second interconnect-level dielectric layer 620.

Each of the dielectric material layers (601, 610, 620) may include a dielectric material such as undoped silicate glass, a doped silicate glass, organosilicate glass, amorphous fluorinated carbon, porous variants thereof, or combinations thereof. Each of the metal interconnect structures (612, 618, 622, 628) may include at least one conductive material, which may be a combination of a metallic barrier liner (such as a metallic nitride or a metallic carbide) and a metallic fill material. Each metallic barrier liner may include TiN, TaN, WN, TiC, TaC, and WC, and each metallic fill material portion may include W, Cu, Al, Co, Ru, Mo, Ta, Ti, alloys thereof, and/or combinations thereof. Other suitable metallic barrier liner materials and metallic fill materials are within the contemplated scope of disclosure. In one embodiment, the first metal via structures 622 and the second metal line structures 628 may be formed as integrated line and via structures by a dual damascene process. The dielectric material layers (601, 610, 620) may also be referred to as lower-level dielectric material layers (601, 610, 620). The metal interconnect structures (612, 618, 622, 628) formed within in the lower-level dielectric material layers (601, 610, 620) are herein referred to as lower-level metal interconnect structures (612, 618, 622, 628).

In one embodiment, the substrate 8 may include a single crystalline silicon substrate, and lower-level dielectric material layers (601, 610, 620) embedding lower-level metal interconnect structures (612, 618, 622, 628) may be located above the single crystalline silicon substrate. Field effect transistors 701 including a respective portion of the single crystalline silicon substrate as a channel may be embedded within the lower-level dielectric material layers (601, 610, 620). The field effect transistors may be subsequently electrically connected to at least one of a gate electrode, a source electrode, and a drain electrode of one or more, or each, of thin-film transistors to be subsequently formed.

While the present disclosure is described using an embodiment in which a semiconductor substrate is used as the substrate 8, embodiments are expressly contemplated herein in which an insulating substrate or a conductive substrate is used as the substrate 8.

Transistors, such as thin-film transistors (TFTs) may be formed in subsequent processing steps. The set of all dielectric layer that are formed prior to formation of the thin-film transistors is collectively referred to as lower-level dielectric material layers (601, 610, 620). The set of all metal interconnect structures that is formed within the lower-level dielectric material layers (601, 610, 620) is herein referred to as lower-level metal interconnect structures (612, 618, 622, 628). Generally, the lower-level metal interconnect structures (612, 618, 622, 628) are formed over the semiconductor material layer 9 in the substrate 8, and are embedded in the lower-level dielectric material layers (601, 610, 620).

In one embodiment, a planar dielectric layer having a uniform thickness may be formed over the lower-level dielectric material layers (601, 610, 620). The planar dielectric layer is herein referred to as an insulating material layer 635. The insulating material layer 635 includes a dielectric material such as undoped silicate glass, a doped silicate glass, organosilicate glass, or a porous dielectric material, and may be deposited by chemical vapor deposition. The thickness of the insulating material layer 635 may be in a range from 30 nm to 300 nm, although lesser and greater thicknesses may also be used.

An etch stop dielectric layer 636 may be optionally formed over the insulating material layer 635. The etch stop dielectric layer 636 includes an etch stop dielectric material providing higher etch resistance to an etch chemistry during a subsequently anisotropic etch process that etches a dielectric material to be subsequently deposited over the etch stop dielectric layer 636. For example, the etch stop dielectric layer 636 may include silicon carbide nitride, silicon nitride, silicon oxynitride, or a dielectric metal oxide such as aluminum oxide. The thickness of the etch stop dielectric layer 636 may be in a range from 3 nm to 40 nm, such as from 4 nm to 30 nm, although lesser and greater thicknesses may also be used.

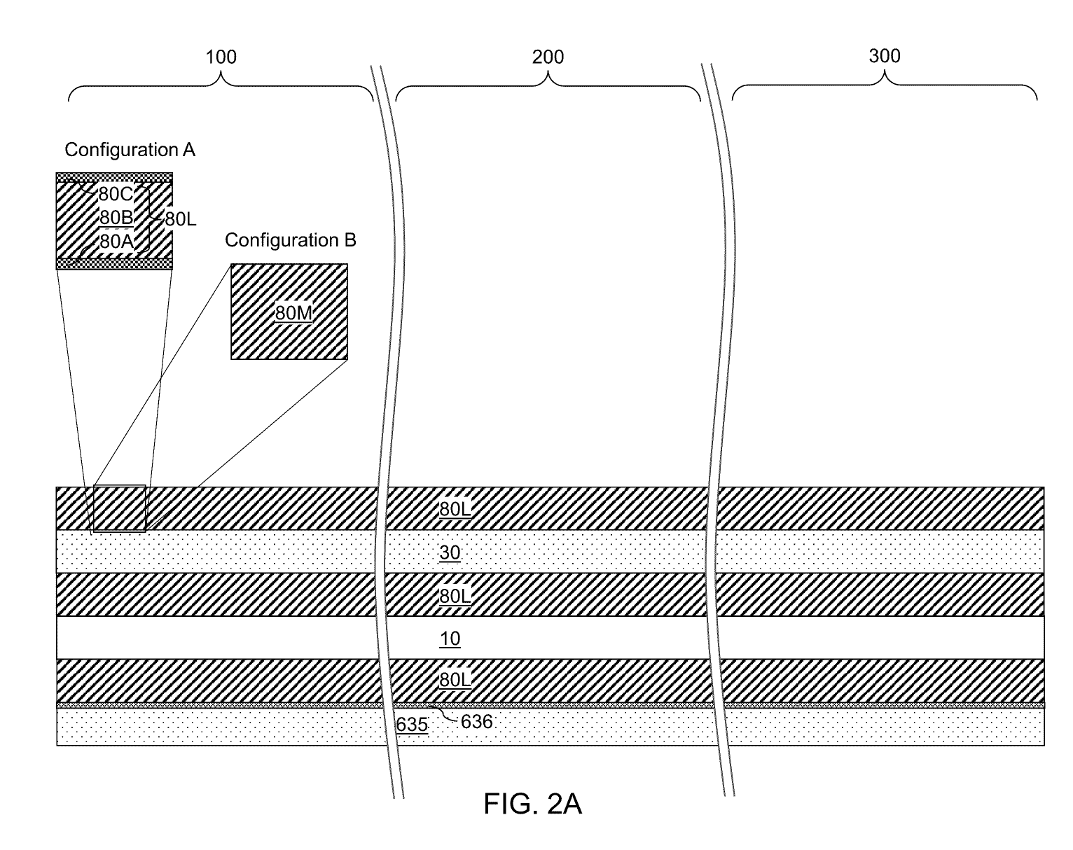

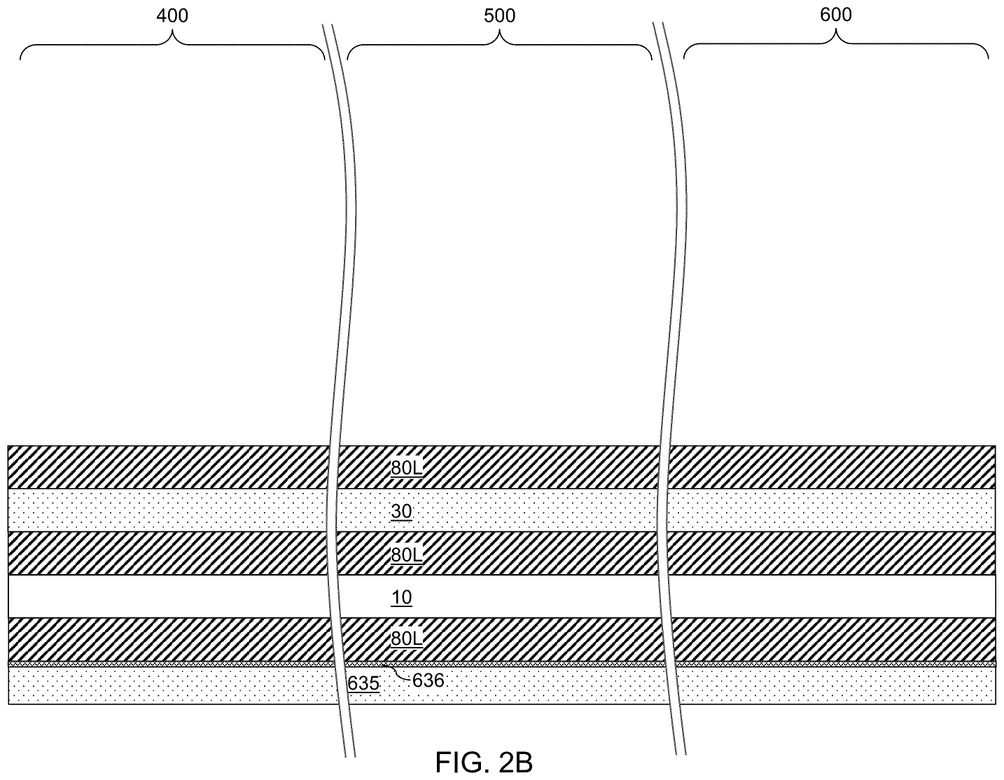

Referring to FIGS. 2A and 2B, various device regions (100, 200, 300, 400, 500, 600) that may be formed over the insulating material layer 635 is illustrated. The various device regions (100, 200, 300, 400, 500, 600) may comprise a first device region 100 in which a first thin-film transistor device is to be subsequently formed; a second device region 200 in which a second thin-film transistor device is to be subsequently formed; a third device region 300 in which a third thin-film transistor device is to be subsequently formed; a fourth device region 400 in which a fourth thin-film transistor device is to be subsequently formed; a fifth device region 500 in which a fifth thin-film transistor device is to be subsequently formed; and sixth device region 600 in which a sixth thin-film transistor device is to be subsequently formed. The six device regions (100, 200, 300, 400, 500, 600) used in the present disclosure are exemplary, and represent examples of thin-film transistor devices that may be formed according to embodiments of the present disclosure. As such, not all of the six device regions (100, 200, 300, 400, 500, 600) needs to be formed. Generally, one or more of the device regions (100, 200, 300, 400, 500, 600) in the first exemplary structure may be arbitrarily selected for formation in the first exemplary structure.

According to an aspect of the present disclosure, a sequence of material layers may be formed over the insulating material layer 635 and the optional etch stop dielectric layer 636. The sequence of material layers may comprise, from bottom to top, a first electrically conductive material layer 80L, a first hydrogen-containing dielectric layer 10, a second electrically conductive material layer 80L, a first hydrogen-blocking dielectric layer 30, and a third electrically conductive material layer 80L.

Each of the first electrically conductive material layer 80L, the second electrically conductive material layer 80L, and the third electrically conductive material layer 80L comprises, and/or consists of, a respective set of at least one conductive material, which may be a respective set of at least one metallic material. In one embodiment, each set of at least one metallic material may comprise a bottom metallic barrier liner 80A, a high-conductivity metal layer 80B, and a top metallic barrier liner 80C as illustrated in the inset for configuration A, or may consist of a metallic layer 80M as illustrated in the inset for configuration B. In embodiments in which a stack of a bottom metallic barrier liner 80A, a high-conductivity metal layer 80B, and a top metallic barrier liner 80C is used for any of the electrically conductive material layers 80L, the bottom metallic barrier liner 80A and the top metallic barrier liner 80C may comprise at least one conductive metal nitride material such as TiN, TaN, WN, and/or MON, and the high-conductivity metal layer 80B may comprise a metal such as Cu, Co, Ru, Mo, W, Ti, Ta, etc. In embodiments in which any of the electrically conductive material layers 80L consists of a respective metallic layer 80M, the material of the metallic layer 80M is selected from refractory metals such as W, Ta, Re, Nb, and Mo or from metal nitride materials such as TiN, TaN, WN, and/or MoN to minimize the diffusion of metallic elements into neighboring dielectric material layers (10, 30).

The thickness of each electrically conductive material layer 80L may be independently selected from a range from 5 nm to 100 nm, such as from 10 nm to 50 nm, although lesser and greater thicknesses may also be used. The thicknesses of the electrically conductive material layers 80L may be the same as other, or may be different from one another. The electrically conductive material layers 80L may be deposited by chemical vapor deposition, physical vapor deposition, electroplating, or combinations thereof.

The first hydrogen-containing dielectric layer 10 comprises a dielectric material that contains hydrogen at an atomic concentration greater than a first atomic concentration, which may be 100 parts per million, and preferably greater than 300 parts per million, and more preferably greater than 1,000 parts per million. Examples of dielectric materials that contain hydrogen atoms at an atomic concentration greater than 100 parts per million include silicon nitride, hydrogenated silicon oxide, silicon oxycarbide, silicon oxynitride, undoped silicate glass, doped silicate glasses, organosilicate glass, and hydrogenated aluminum oxide. According to an aspect of the present disclosure, the hydrogen-blocking dielectric layer 30 may have lower hydrogen content relative to the first hydrogen-containing dielectric layer 10. The atomic concentration of hydrogen atoms in the hydrogen-blocking dielectric layer 30 may be less than a second atomic concentration, which may be 30 parts per million, and preferably less than 10 parts per million, thereby effectively blocking the diffusion of hydrogen atoms therethrough.

Silicon nitride deposited by plasma-enhanced chemical vapor deposition may include hydrogen atoms in a range from 400 parts per million to 2,000 parts per million. Hydrogen is incorporated into the silicon nitride material during the plasma-enhanced chemical vapor deposition process, and bonds with silicon and nitrogen.

Hydrogenated silicon oxide, i.e., hydrogenated silicate glass, may include hydrogen atoms in a range from 1,000 parts per million to 3,000 parts per million, and may be formed by deposition of silicate glass by decomposition of a precursor material such as tetraethylorthosilicate (TEOS) in a plasma-enhanced chemical vapor deposition process, followed by an anneal in a hydrogen-containing environment. Hydrogen atoms in the hydrogenated silicon oxide passivate dangling bonds in the silicon oxide material.

Silicon Oxycarbide and silicon oxynitride may include hydrogen atoms in a range from 1,000 parts per million to 1,500 parts per million, and may be formed by plasma-enhanced chemical vapor deposition.

Undoped silicate glass and doped silicate glasses may contain hydrogen at a concentration in a range from 100 parts per million to 500 parts per million. Undoped silicate glass and doped silicate glasses may be formed by decomposition of a precursor gas such as tetraethylorthosilicate (TEOS) in a plasma-enhanced chemical vapor deposition process. Dopant gases such as diborane, phosphene, arsine, and/or fluorine may be flowed concurrently with the flow of the precursor gas to deposit the doped silicate glasses.

Organosilicate glass may contain hydrogen at a concentration in a range from 100 parts per million to 300 parts per million, and may be formed by plasma-enhanced chemical vapor deposition. Other dielectric material such as aluminum oxide may be used provided that the dielectric materials may be hydrogenated to contain a high level of hydrogen atoms above 100 parts per million.

The thickness of the first hydrogen-containing dielectric layer 10 may be in a range from 5 nm to 100 nm, such as from 10 nm to 50 nm, although lesser and greater thicknesses may also be used.

The first hydrogen-blocking dielectric layer 30 comprises a dielectric material that is substantially free of hydrogen atoms, or contains hydrogen atoms at a low atomic concentration such as an atomic concentration lower than a second atomic concentration (which may be 30 parts per million or less, and preferably 10 parts per million or less, and more preferably 3 parts per million or less). Further, the dielectric material of the first hydrogen-blocking dielectric layer 30 is selected from dielectric materials that effectively block diffusion of hydrogen atoms therethrough. Due to the small size of hydrogen atoms and high diffusivity of hydrogen atoms, only a small group of dielectric materials may effectively block hydrogen atoms. Examples of such dielectric materials include alkaline-earth oxides such as magnesium oxide, calcium oxide, and strontium oxide. In one embodiment, the first hydrogen-blocking dielectric layer 30 comprises, and/or consists essentially of, at least one alkaline-earth oxide material. In one embodiment, the first hydrogen-blocking dielectric layer 30 consists of magnesium oxide, calcium oxide, or an alloy or a stack thereof.

The first hydrogen-blocking dielectric layer 30 may be deposited by pulsed layer deposition in which a high-power laser ablates a target including a source material, an electron beam physical vapor deposition in which an electron beam evaporates a target including a source material, atomic layer deposition, or other deposition methods known in the art. The thickness of the first hydrogen-blocking dielectric layer 30 may be in a range from 5 nm to 100 nm, such as from 10 nm to 50 nm, although lesser and greater thicknesses may also be used.

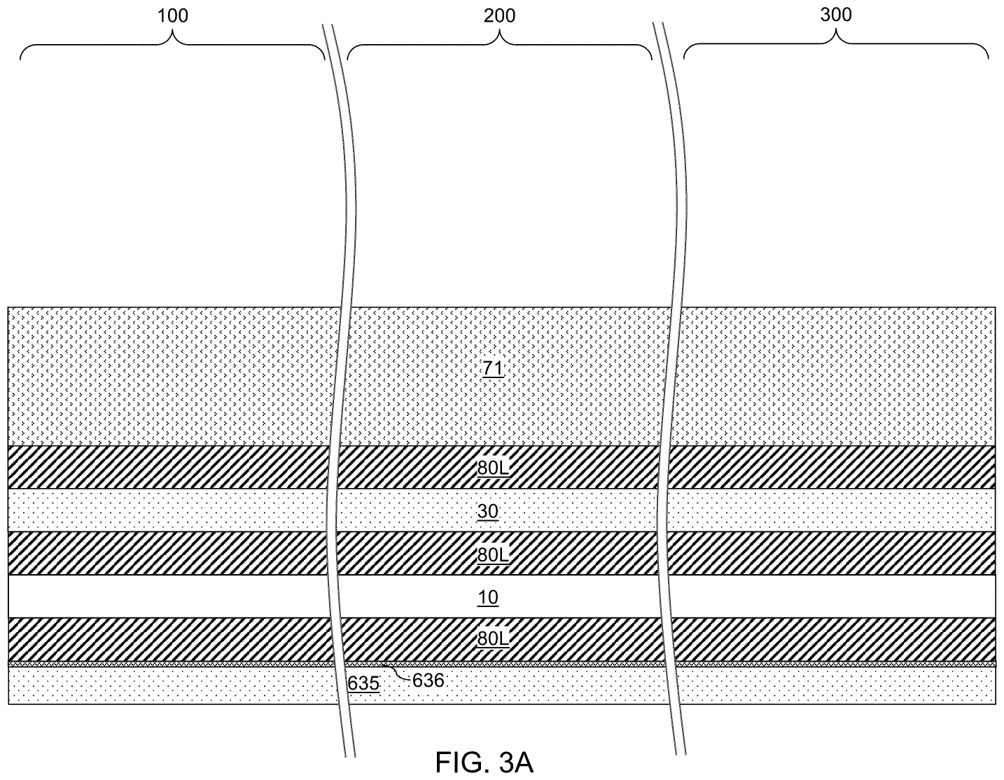

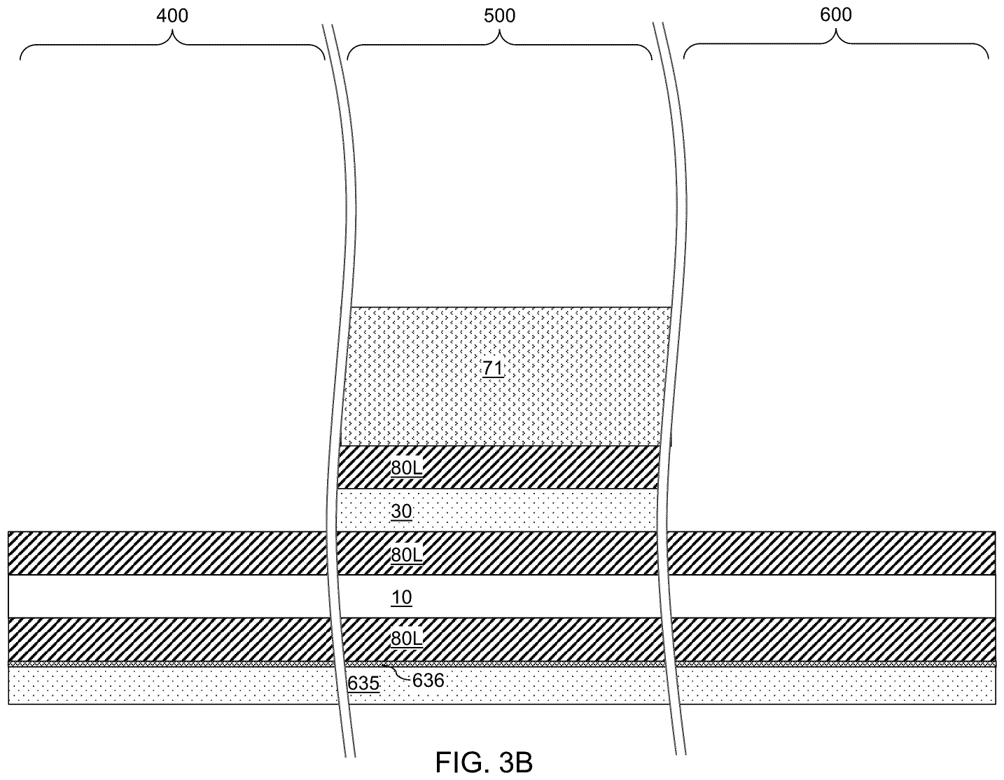

Referring to FIGS. 3A and 3B, a first block-level photoresist layer 71 may be applied over the layer stack of the electrically conductive material layers 80L, the first hydrogen-containing dielectric layer 10, and the first hydrogen-blocking dielectric layer 30. The first block-level photoresist layer 71 may be lithographically patterned to cover a first set of one or more of the device regions (100, 200, 300, 400, 500, 600) without covering a second set of one or more of the device regions (100, 200, 300, 400, 500, 600) which is a complementary set of the first set. In the illustrated example, the first block-level photoresist layer 71 may cover the first device region 100, the second device region 200, the third device region 300, and the fifth device region 500 without covering the fourth device region 400 or the sixth device region 600. An anisotropic etch process may be performed using the first block-level photoresist layer 71 as an etch mask to etch through portions of the topmost electrically conductive material layer 80L and the first hydrogen-blocking dielectric layer 30 that are not masked by the first block-level photoresist layer 71. A terminal step of the anisotropic etch process may etch the material of the first hydrogen-blocking dielectric layer 30 selective to the material of the underlying electrically conductive material layer 80L. The first block-level photoresist layer 71 may be subsequently removed, for example, by ashing.

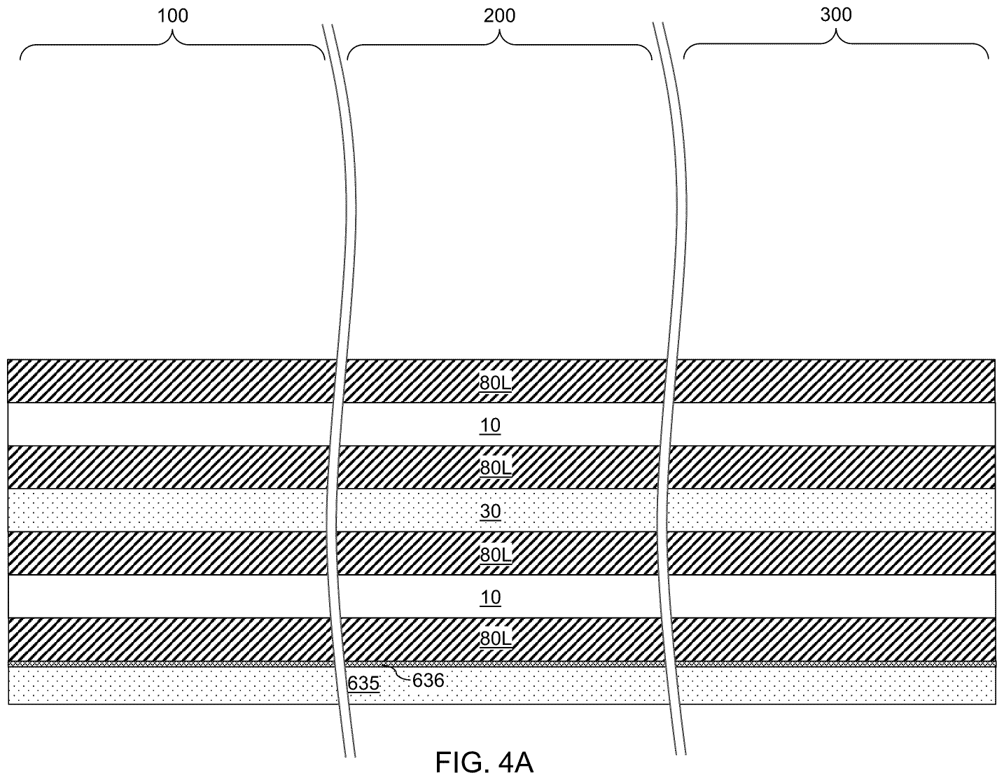

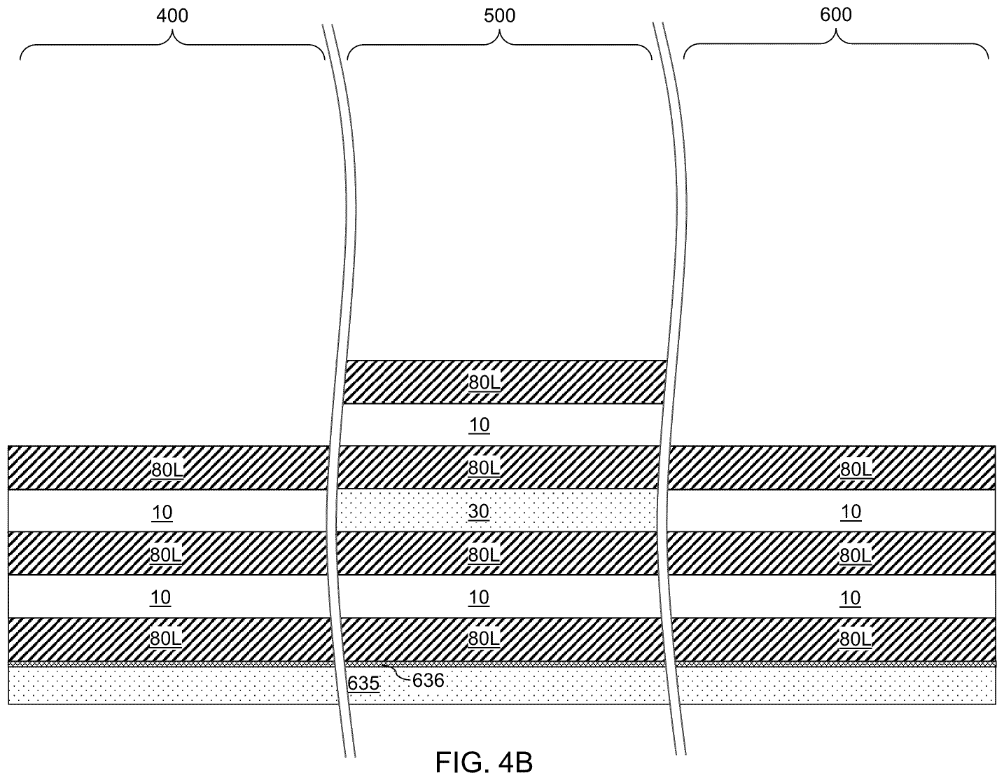

Referring to FIGS. 4A and 4B, a second hydrogen-containing dielectric layer 10 and a fourth electrically conductive material layer 80L may be sequentially deposited over the underlying layer stack (80L, 10, 30). The second hydrogen-containing dielectric layer 10 may comprise any material that may be used for the first hydrogen-containing dielectric layer 10 described above. The second hydrogen-containing dielectric layer 10 may have any thickness that may be used for the first hydrogen-containing dielectric layer 10. The material composition of the second hydrogen-containing dielectric layer 10 may be the same as, or may be different from, the material composition of the first hydrogen-containing dielectric layer 10. The thickness of the second hydrogen-containing dielectric layer 10 may be the same as, or may be different from, the thickness of the first hydrogen-containing dielectric layer 10.

The fourth electrically conductive material layer 80L may comprise any material that may be used for the first, second, and third electrically conductive material layers 80L described above. The fourth electrically conductive material layer 80L may have any thickness that may be used for the first, second, and third electrically conductive material layers 80L. The material composition of the fourth electrically conductive material layer 80L may be the same as, or may be different from, the material composition of any of the first, second, and third electrically conductive material layers 80L. The thickness of the fourth electrically conductive material layer 80L may be the same as, or may be different from, the thickness of any of the first, second, and third electrically conductive material layers 80L.

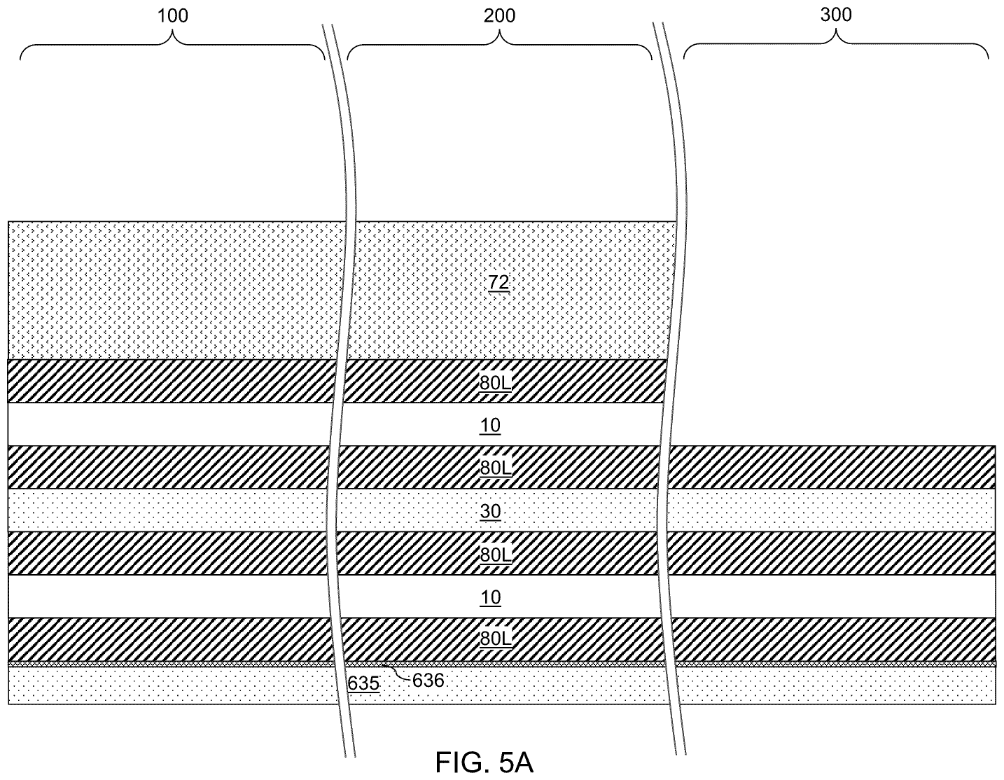

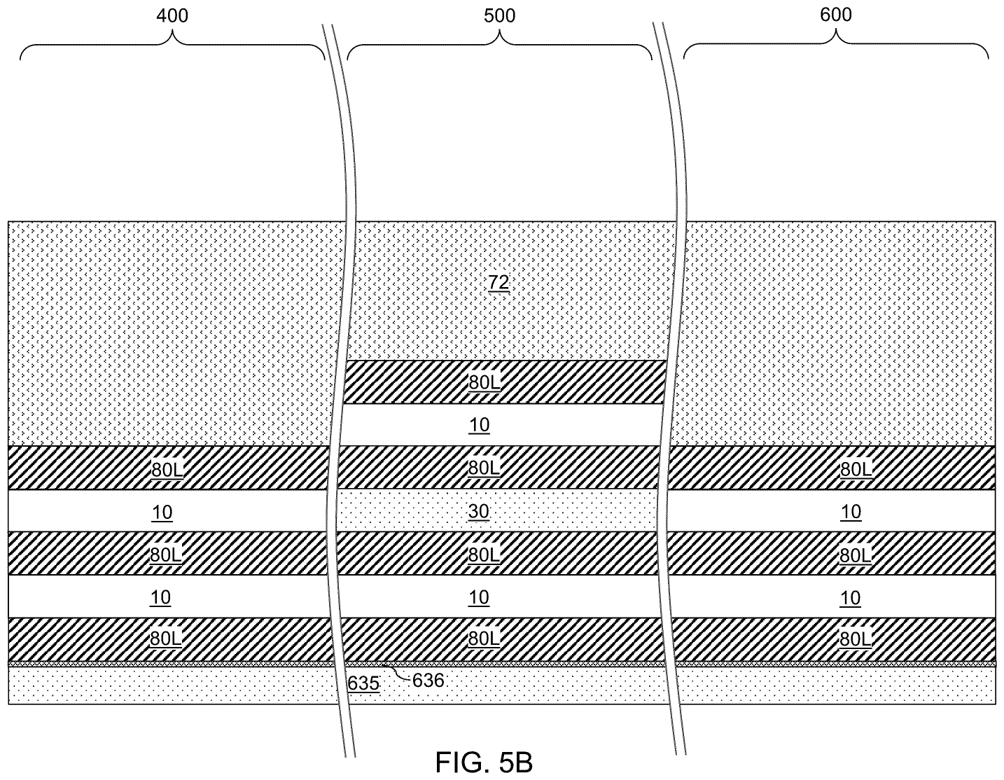

Referring to FIGS. 5A and 5B, a second block-level photoresist layer 72 may be applied over the layer stack of the electrically conductive material layers 80L, the hydrogen-containing dielectric layers 10, and the first hydrogen-blocking dielectric layer 30. The second block-level photoresist layer 72 may be lithographically patterned to cover a third set of one or more of the device regions (100, 200, 300, 400, 500, 600) without covering a fourth set of one or more of the device regions (100, 200, 300, 400, 500, 600) which is a complementary set of the third set. The third set may be selected independent of the composition of the first set described above. In the illustrated example, the second block-level photoresist layer 72 may cover the first device region 100, the second device region 200, the fourth device region 400, the fifth device region 500, and the sixth device region 600 without covering the third device region 300. An anisotropic etch process may be performed using the second block-level photoresist layer 72 as an etch mask to etch through unmasked portions of a topmost electrically conductive material layer 80L (the fourth electrically conductive material layer 80L) and an underlying dielectric layer (such as the second hydrogen-containing dielectric layer 10). A terminal step of the anisotropic etch process may etch the material of the second hydrogen-containing dielectric layer 10 selective to the material of the underlying electrically conductive material layer 80L (such as the third electrically conductive material layer 80L). The second block-level photoresist layer 72 may be subsequently removed, for example, by ashing.

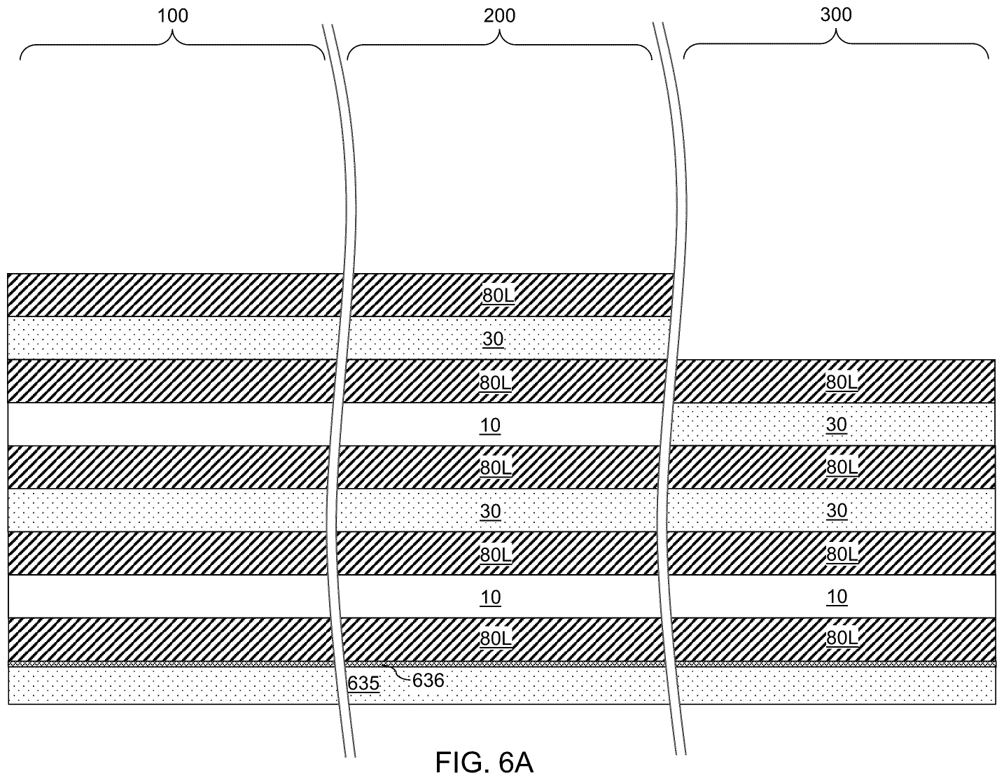

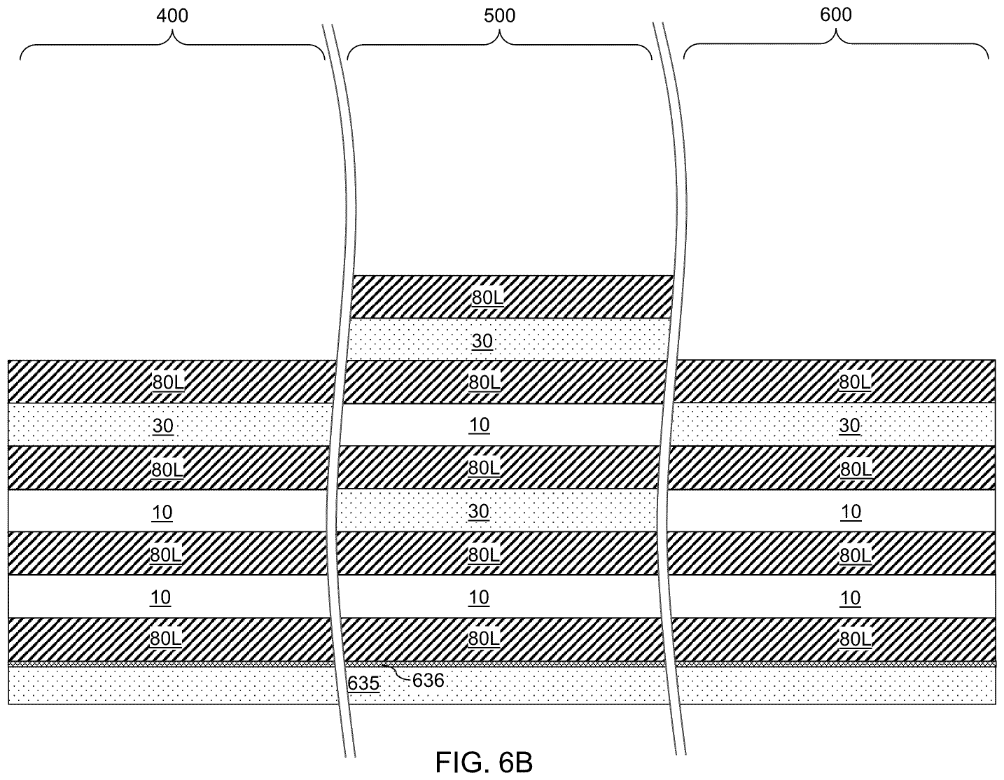

Referring to FIGS. 6A and 6B, a second hydrogen-blocking dielectric layer 30 and a fifth electrically conductive material layer 80L may be sequentially deposited over the underlying layer stack (80L, 10, 30). The second hydrogen-blocking dielectric layer 30 may comprise any material that may be used for the first hydrogen-blocking dielectric layer 30 described above. The second hydrogen-blocking dielectric layer 30 may have any thickness that may be used for the first hydrogen-blocking dielectric layer 30. The material composition of the second hydrogen-blocking dielectric layer 30 may be the same as, or may be different from, the material composition of the first hydrogen-blocking dielectric layer 30. The thickness of the second hydrogen-blocking dielectric layer 30 may be the same as, or may be different from, the thickness of the first hydrogen-blocking dielectric layer 30.

The fifth electrically conductive material layer 80L may comprise any material that may be used for the first, second, third, and fourth electrically conductive material layers 80L described above. The fifth electrically conductive material layer 80L may have any thickness that may be used for the first, second, third, and fourth electrically conductive material layers 80L. The material composition of the fifth electrically conductive material layer 80L may be the same as, or may be different from, the material composition of any of the first, second, third, and fourth electrically conductive material layers 80L. The thickness of the fifth electrically conductive material layer 80L may be the same as, or may be different from, the thickness of any of the first, second, third, and fourth electrically conductive material layers 80L.

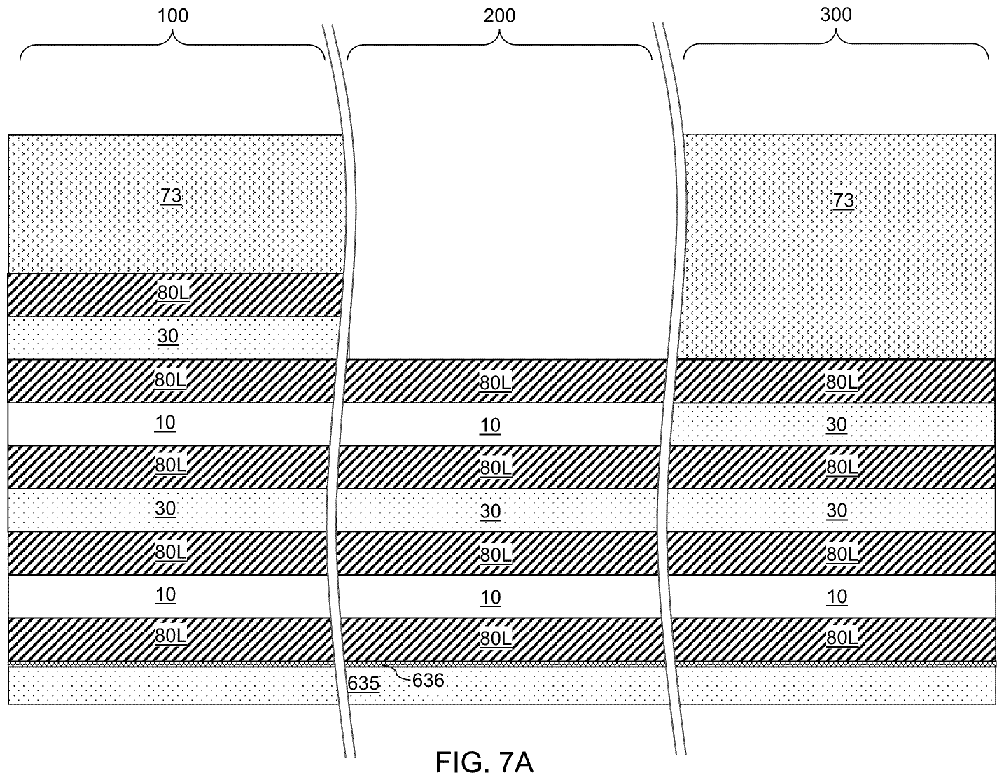

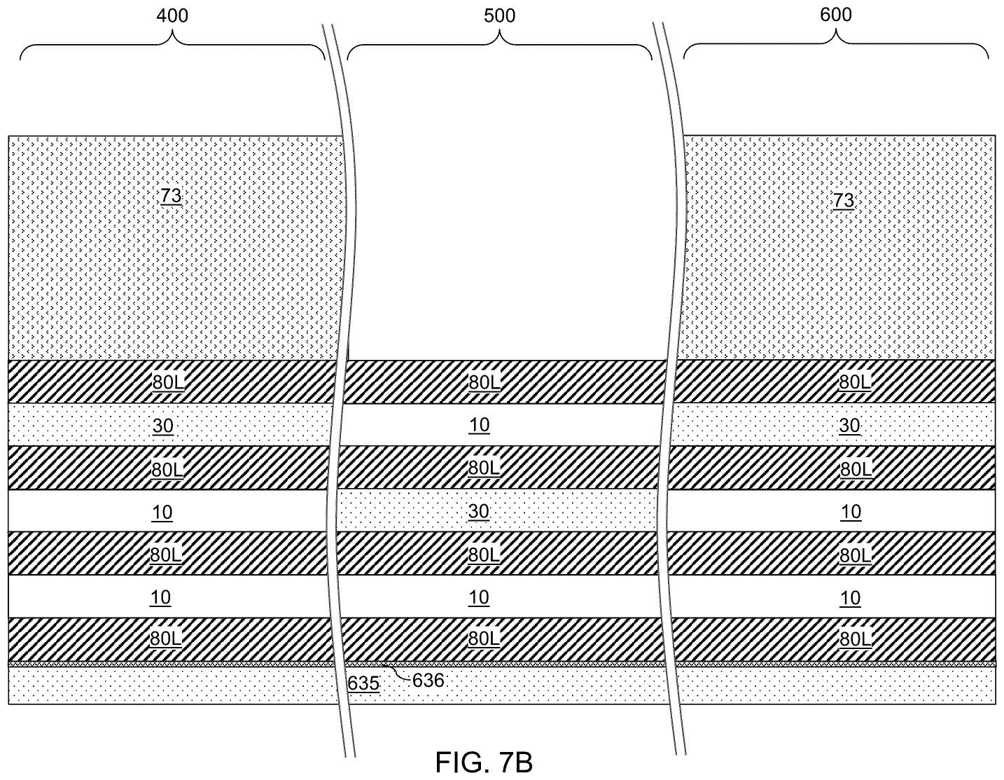

Referring to FIGS. 7A and 7B, a third block-level photoresist layer 73 may be applied over the layer stack of the electrically conductive material layers 80L, the hydrogen-containing dielectric layers 10, and the hydrogen-blocking dielectric layers 30. The third block-level photoresist layer 73 may be lithographically patterned to cover a fifth set of one or more of the device regions (300, 200, 300, 400, 500, 600) without covering a sixth set of one or more of the device regions (300, 200, 300, 400, 500, 600) which is a complementary set of the fifth set. The fifth set may be selected independent of the composition of the third set described above, and may be selected independent of the composition of the first set described above. In the illustrated example, the third block-level photoresist layer 73 may cover the first device region 100, the third device region 300, the fourth device region 400, and the sixth device region 600 without covering the second device region 200 or the fifth device region 500. An anisotropic etch process may be performed using the third block-level photoresist layer 73 as an etch mask to etch through unmasked portions of a topmost electrically conductive material layer 80L (the fifth electrically conductive material layer 80L) and an underlying dielectric layer (such as the second hydrogen-blocking dielectric layer 30). A terminal step of the anisotropic etch process may etch the material of the second hydrogen-blocking dielectric layer 30 selective to the material of the underlying electrically conductive material layer 80L (such as the fourth electrically conductive material layer 80L or the third electrically conductive material layer 80L). The third block-level photoresist layer 73 may be subsequently removed, for example, by ashing.

Generally, a vertical stack (80L, 10, 30) is formed in each device region (100, 200, 300, 400, 500, 600). Each vertical stack (80L, 10, 30) comprises, from bottom to top or from bottom to top, a first electrically conductive material layer 80L, a first insulating material layer (such as a hydrogen-containing dielectric layer 10) comprising the hydrogen-containing dielectric material, a second electrically conductive material layer 80L, a second insulating material layer (such as a hydrogen-blocking dielectric layer 30) comprising the hydrogen-blocking dielectric material, and a third electrically conductive material layer 80L. One or more of the vertical stacks (80L, 10, 30) may additionally comprise at least one additional insulating material layer, which may comprise an additional hydrogen-containing dielectric layer 10 and/or an additional hydrogen-blocking dielectric layer 30. One or more of the vertical stacks (80L, 10, 30) may additionally comprise at least one electrically conductive material layer 80L.

Each vertical stack (80L, 10, 30) in each device region (100, 200, 300, 400, 500, 600) may comprise a respective vertically alternating sequence of electrically conductive material layers 80L and dielectric layers (10, 30). The type of the dielectric layers (10, 30) in each vertical stack (80L, 10, 30) may be selected in any order. In other words, implementation of the present invention is not limited by the order of types of the dielectric layers (10, 30) in each vertical stack (80L, 10, 30). Generally, if (N+1) electrically conductive material layers 80L and N dielectric layers (10, 30) are deposited and patterned, 2^{N}−1 types of vertical stacks (80L, 10, 30) may be formed such that each vertical stack (80L, 10, 30) comprises one or more dielectric layer (10, 30) selected from the N dielectric layers (10, 30).

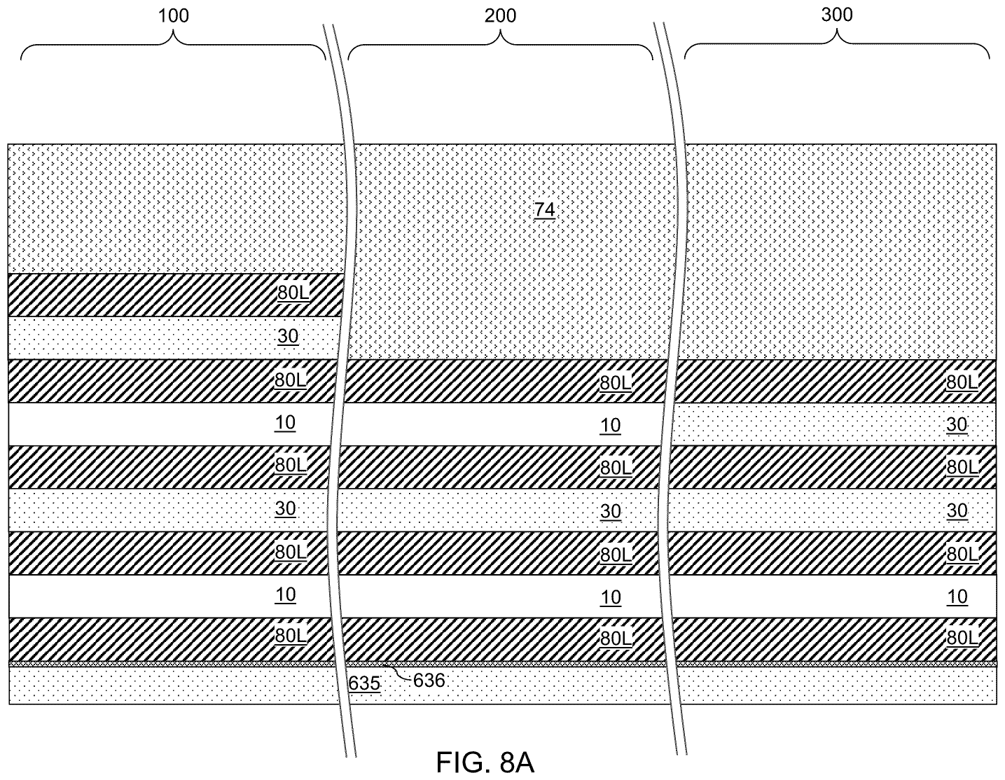

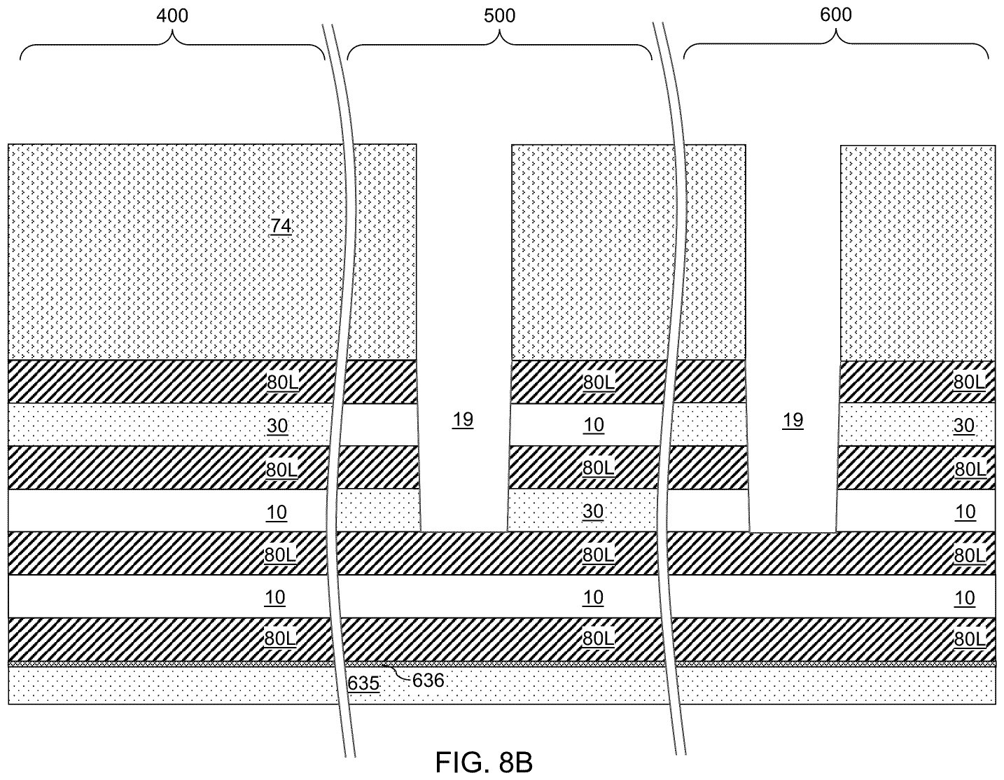

Referring to FIGS. 8A and 8B, a patterned etch mask layer may be formed, and a patterning process may be performed to form vertically-extending via cavities 19. For example, a first photoresist layer 74 may be applied over the vertical stacks (80L, 10, 30), and may be lithographically patterned to form discrete openings in areas in which vertical channels of first thin-film transistors are to be subsequently formed. The horizontal cross-sectional shapes of the discrete openings in the first photoresist layer 74 may be a circle, an oval, a rectangle, a rounded rectangle, or any two-dimensional shape having a closed periphery. A first anisotropic etch process may be performed to transfer the pattern of the discrete openings in the first photoresist layer 74 through a first subset of layers in the vertical stacks (80L, 10, 30). The first photoresist layer 74 may be subsequently removed, for example, by ashing. Alternatively, an ion beam etch process using a patterned hard mask layer may be used to form the vertically-extending via cavities 19 instead of the anisotropic etch process.

In the illustrated example, the first anisotropic etch process may transfer the pattern of the discrete openings in the first photoresist layer 74 through two electrically conductive material layers 80L and two dielectric layers (10, 30). Vertically-extending via cavities 19 may be formed underneath each discrete opening in the first photoresist layer 74. A surface segment of a top surface of an electrically conductive material layer 80L may be physically exposed underneath each vertically-extending via cavity 19. A lateral dimension of each vertically-extending via cavity 19 (such as a diameter at a top portion) may be in a range from 20 nm to 300 nm, such as from 30 nm to 100 nm, although lesser and greater lateral dimensions may also be used.

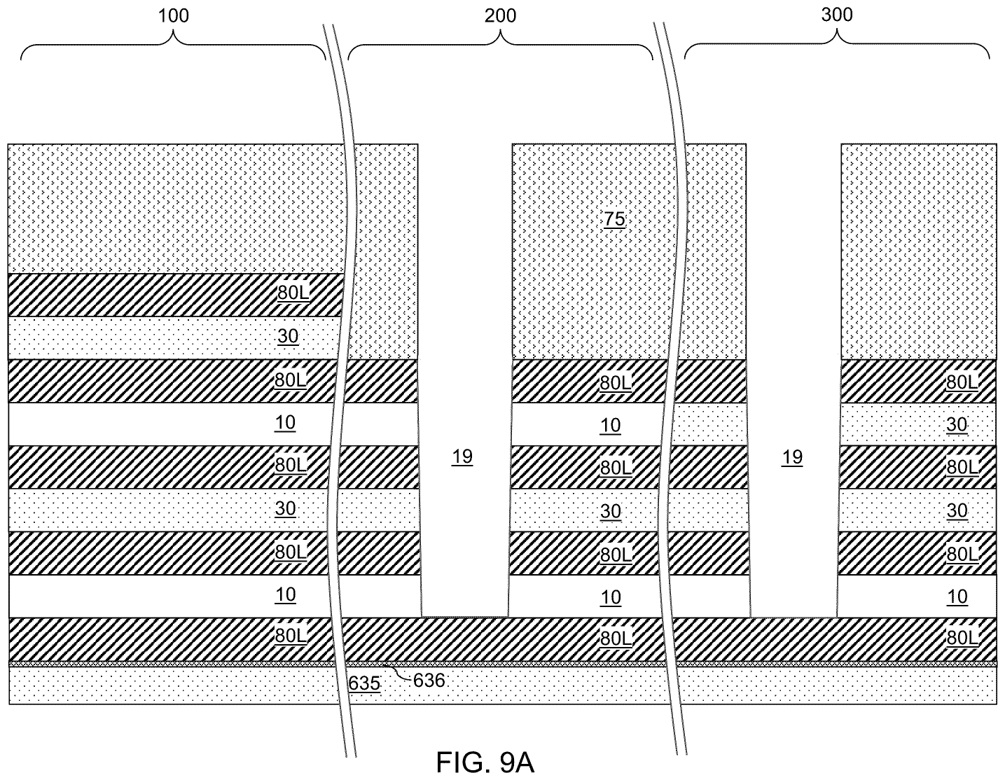

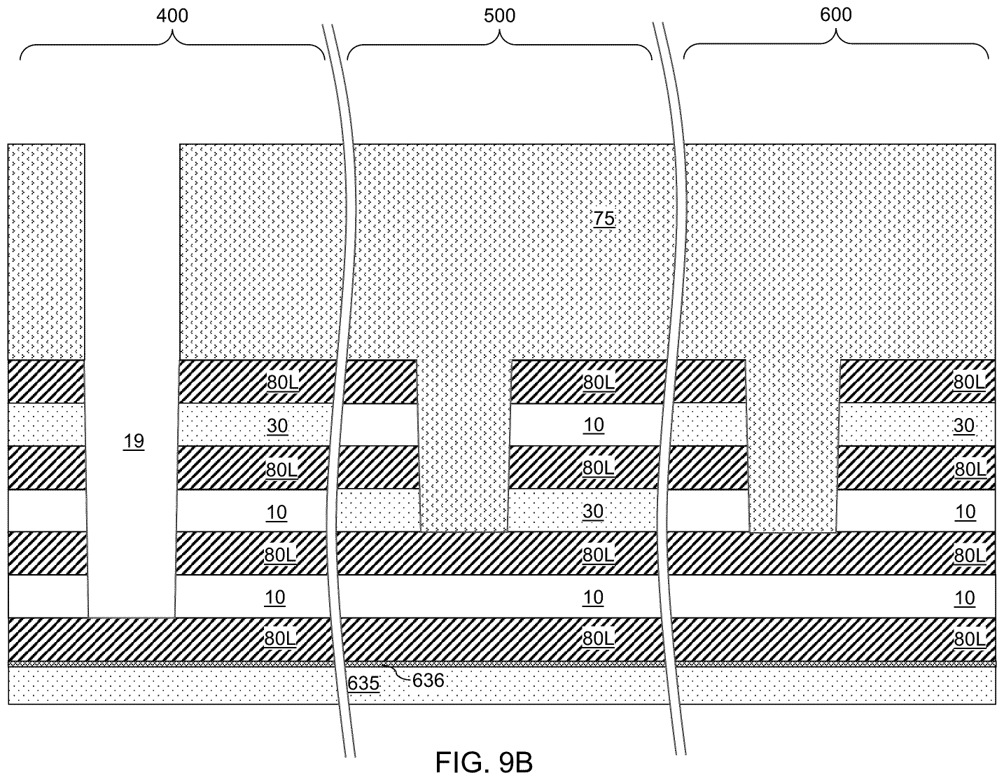

Referring to FIGS. 9A and 9B, a patterned etch mask layer may be formed, and a patterning process may be performed to form additional vertically-extending via cavities 19. For example, a second photoresist layer 75 may be applied over the vertical stacks (80L, 10, 30), and may be lithographically patterned to form discrete openings in areas in which vertical channels of second thin-film transistors are to be subsequently formed. The horizontal cross-sectional shapes of the discrete openings in the second photoresist layer 75 may be a circle, an oval, a rectangle, a rounded rectangle, or any two-dimensional shape having a closed periphery. A second anisotropic etch process may be performed to transfer the pattern of the discrete openings in the second photoresist layer 75 through a second subset of layers in the vertical stacks (80L, 10, 30). The second photoresist layer 75 may be subsequently removed, for example, by ashing. Alternatively, an ion beam etch process using a patterned hard mask layer may be used to form the vertically-extending via cavities 19 instead of the anisotropic etch process.

In the illustrated example, the second anisotropic etch process may transfer the pattern of the discrete openings in the second photoresist layer 75 through three electrically conductive material layers 80L and three dielectric layers (10, 30). Vertically-extending via cavities 19 are formed underneath each discrete opening in the second photoresist layer 75. A surface segment of a top surface of an electrically conductive material layer 80L may be physically exposed underneath each vertically-extending via cavity 19. A lateral dimension of each vertically-extending via cavity 19 (such as a diameter at a top portion) may be in a range from 20 nm to 300 nm, such as from 30 nm to 100 nm, although lesser and greater lateral dimensions may also be used.

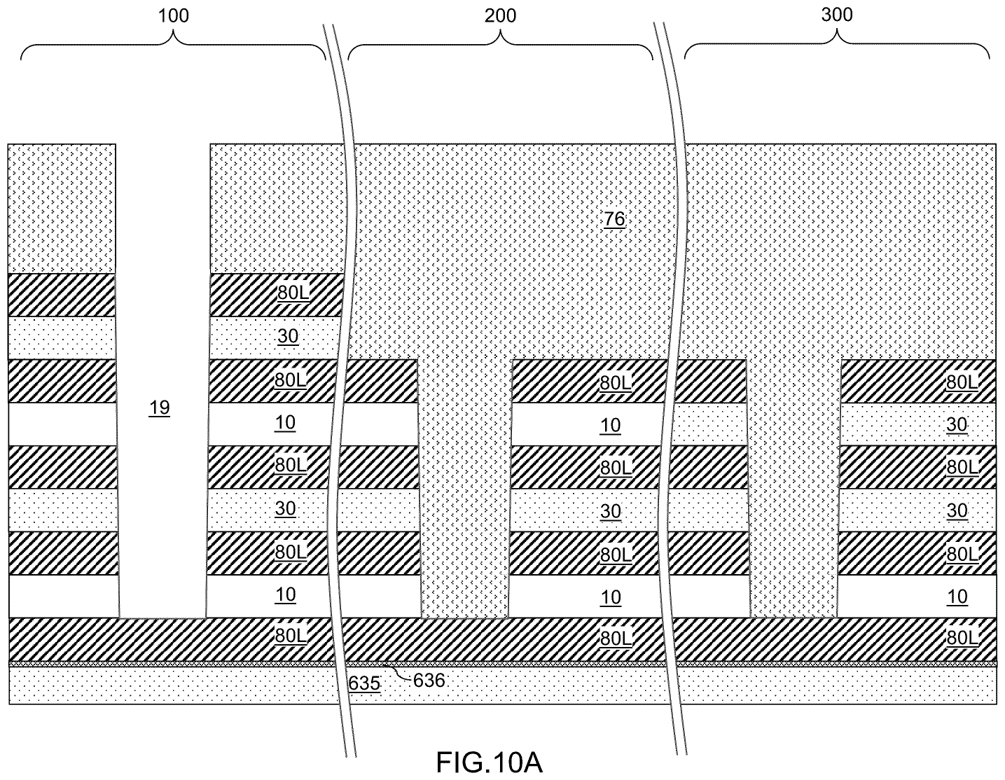

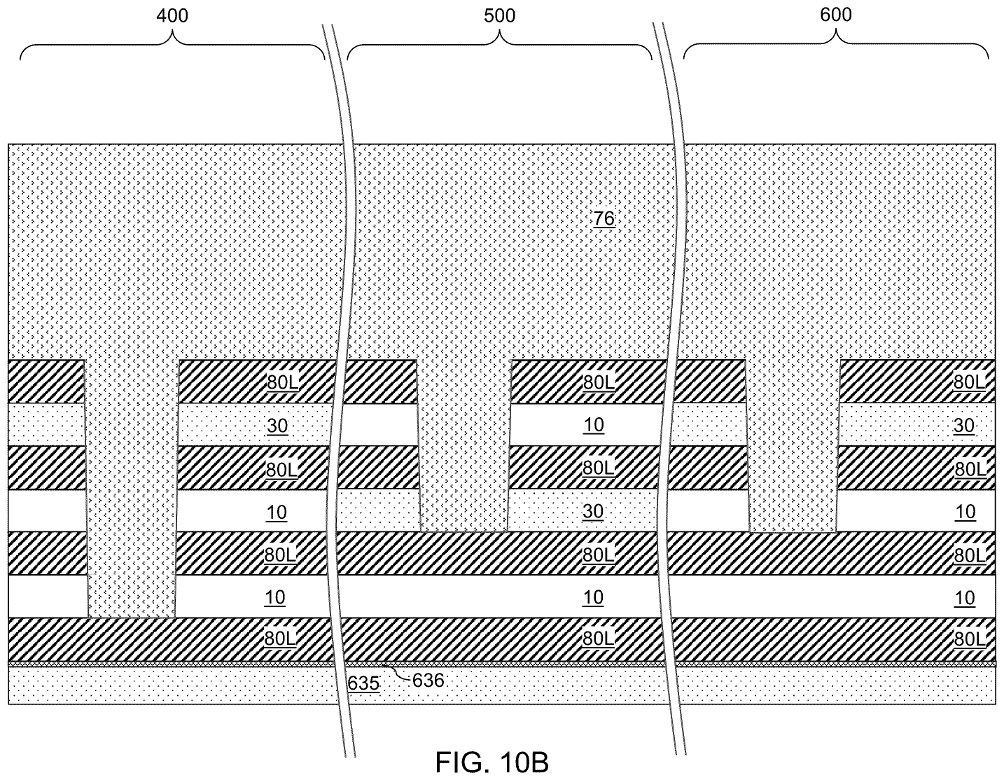

Referring to FIGS. 10A and 10B, a patterned etch mask layer may be formed, and a patterning process may be performed to form additional vertically-extending via cavities 19. For example, a third photoresist layer 76 may be applied over the vertical stacks (80L, 10, 30), and may be lithographically patterned to form discrete openings in areas in which vertical channels of third thin-film transistors are to be subsequently formed. The horizontal cross-sectional shapes of the discrete openings in the third photoresist layer 76 may be a circle, an oval, a rectangle, a rounded rectangle, or any two-dimensional shape having a closed periphery. A third anisotropic etch process may be performed to transfer the pattern of the discrete openings in the third photoresist layer 76 through a third subset of layers in the vertical stacks (80L, 10, 30). The third photoresist layer 76 may be subsequently removed, for example, by ashing. Alternatively, an ion beam etch process using a patterned hard mask layer may be used to form the vertically-extending via cavities 19 instead of the anisotropic etch process.

In the illustrated example, the third anisotropic etch process may transfer the pattern of the discrete openings in the third photoresist layer 76 through four electrically conductive material layers 80L and four dielectric layers (10, 30). Vertically-extending via cavities 19 are formed underneath each discrete opening in the third photoresist layer 76. A surface segment of a top surface of an electrically conductive material layer 80L may be physically exposed underneath each vertically-extending via cavity 19. A lateral dimension of each vertically-extending via cavity 19 (such as a diameter at a top portion) may be in a range from 20 nm to 300 nm, such as from 30 nm to 100 nm, although lesser and greater lateral dimensions may also be used.

Referring collectively to FIGS. 8A-10B, at least one anisotropic etch process may be performed to pattern the vertical stacks (80L, 10, 30) using a respective etch mask such as a respective patterned photoresist layer (74, 75, 76). Each anisotropic etch process forms at least one vertically-extending via cavity 19 through a respective vertical stack (80L, 10, 30) such that the at least one vertically-extending via cavity 19 extends through at least one pair of an electrically conductive material layer 80L and a dielectric layer (10, 30), which may be a hydrogen-containing dielectric layer 10 or a hydrogen-blocking dielectric layer 30.

A spatially-extending sequence of surfaces comprises surface segments of the vertical stack (80L, 10, 30) may be formed around each vertically-extending via cavity 19. In one embodiment, the spatially-extending sequence of surfaces may comprise, from one end to another, a first electrically conductive surface (such as a sidewall of one of the electrically conductive material layers 80L), a first-type insulating surface (such as a surface of a hydrogen-containing dielectric layer 10), a second electrically conductive surface (such as a sidewall of another of the electrically conductive material layers 80L), a second-type insulating surface (such as a surface of a hydrogen-blocking dielectric layer 30), and a third electrically conductive surface (such as a sidewall of an additional one of the electrically conductive material layers 80L). The first-type insulating surface (such as a surface of a hydrogen-containing dielectric layer 10) is a surface of a hydrogen-containing dielectric material containing hydrogen atoms at a concentration greater than a first atomic concentration, which may be greater than 100 parts per million as discussed above. The second-type insulating surface (such as a surface of a hydrogen-blocking dielectric layer 30) of a hydrogen-impermeable surface of a hydrogen-blocking dielectric material.

In one embodiment, each vertical stack (80L, 10, 30) may be patterned such that each layer within the vertical stack (80L, 10, 30) has a respective sidewall. In one embodiment, the first electrically conductive surface is a sidewall of the first electrically conductive material layer 80L; the second electrically conductive surface is a sidewall of the second electrically conductive material layer 80L; and the third electrically conductive surface is a sidewall of the third electrically conductive material layer 80L. The hydrogen-blocking dielectric layer 30 has a substantially lower hydrogen concentration compared to the hydrogen-containing dielectric layer 10, and prevents diffusion of hydrogen atoms therethrough. The atomic concentration of hydrogen atoms in the hydrogen-blocking dielectric layer 30 may be less than a second atomic concentration (which may be 30 parts per million or less, and preferably 10 parts per million or less, and more preferably 3 parts per million or less).

In one embodiment, the first electrically conductive surface, the second electrically conductive surface, and the third electrically conductive surface are surface segments of a vertically-extending via cavity 19 that are vertically coincident with one another. As used herein, multiple surfaces are vertically coincident with each other or with one another if the multiple surfaces overlies or underlies one another, and are located within a vertical plane or a substantially vertical plane. As used herein, a Euclidean plane having a paper angle less than 10 degrees relative to a vertical direction is considered to be substantially vertical.

Generally speaking, a combination of a first-type insulating surface (such as a surface of a hydrogen-containing dielectric layer 10) and a second-type insulating surface (such as a surface of a hydrogen-blocking dielectric layer 30) may be formed over a substrate 8. The first-type insulating surface (such as a surface of a hydrogen-containing dielectric layer 10) is a surface of a hydrogen-containing dielectric material containing hydrogen atoms at a concentration greater than a first atomic concentration (which may be at least 100 parts per million as discussed above), and the second-type insulating surface (such as a surface of a hydrogen-blocking dielectric layer 30) is a hydrogen-impermeable surface of a hydrogen-blocking dielectric material.

In one embodiment, the first-type insulating surface (such as a surface of a hydrogen-containing dielectric layer 10) is formed between a first electrically conductive surface of a first electrically conductive material portion (such as an electrically conductive material layer 80L) and a second electrically conductive surface of a second electrically conductive material portion (such as another electrically conductive material layer 80L). The second-type insulating surface (such as a surface of a hydrogen-blocking dielectric layer 30) is formed between the second electrically conductive surface and a third electrically conductive surface of a third electrically conductive material portion (such as yet another electrically conductive material layer 80L).

In one embodiment, each of the first electrically conductive material portion, the second electrically conductive material portion, and the third electrically conductive material portion 80 comprises a respective source/drain electrode. In other words, the electrically conductive material layers 80L that are adjacent to the first-type insulating surface (such as a surface of a hydrogen-containing dielectric layer 10) and the second-type insulating surface (such as a surface of a hydrogen-blocking dielectric layer 30) may constitute source/drain electrodes of thin-film transistors to be subsequently formed.

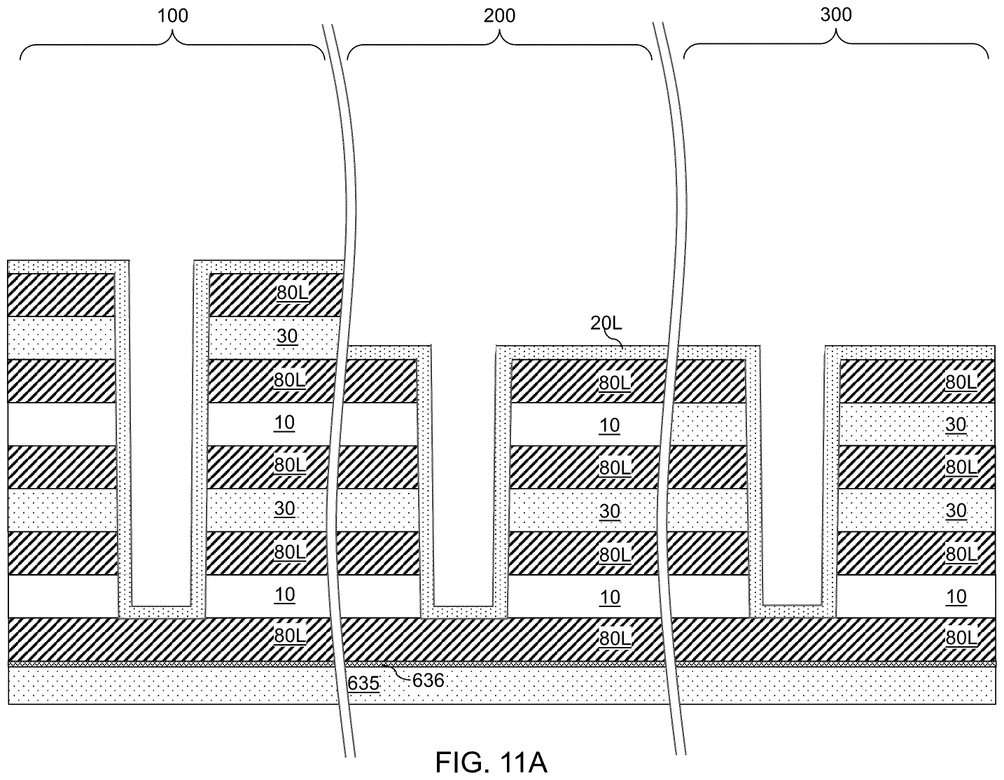

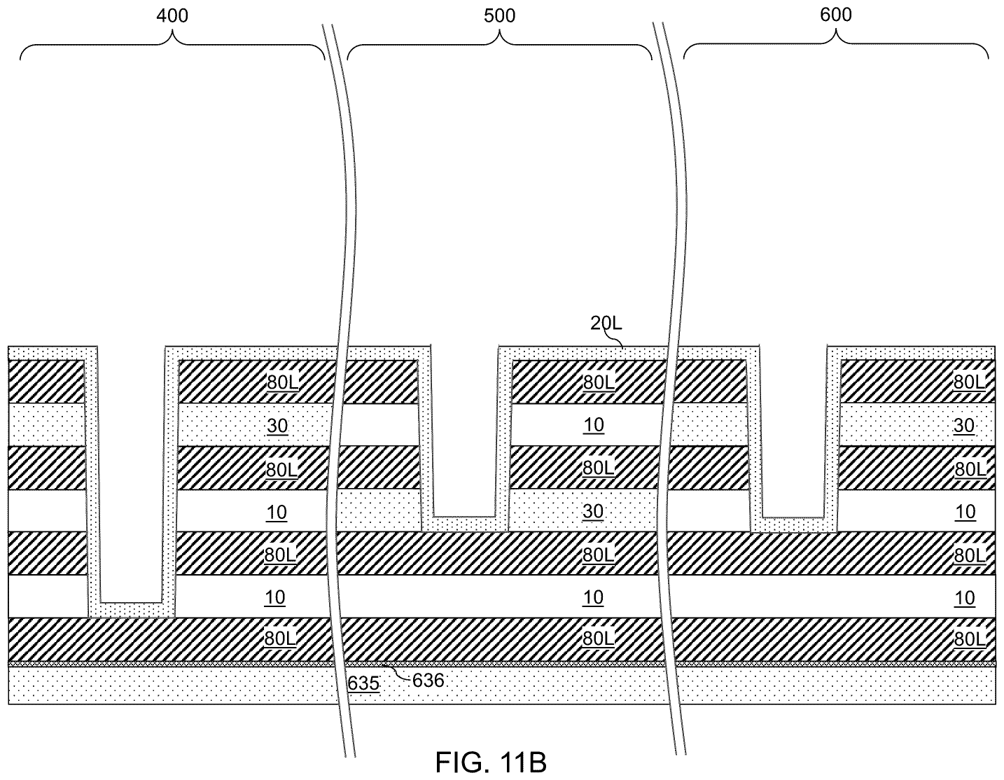

Referring to FIGS. 11A and 11B, an amorphous metal oxide layer 20L may be conformally deposited on the spatially-extending sequence of surfaces comprising at least the first-type insulating surface (such as a surface of a hydrogen-containing dielectric layer 10) and the second-type insulating surface (such as a surface of a hydrogen-blocking dielectric layer 30). In one embodiment, the amorphous metal oxide layer 20L may be conformally deposited in each of the vertically-extending via cavities 19 and over the physically exposed top surfaces of the electrically conductive material layers 80L. The amorphous metal oxide layer 20L may be deposited by physical vapor deposition, atomic layer deposition, or a suitable alternative deposition process. The thickness of the amorphous metal oxide layer 20L may be in a range from 2 nm to 30 nm, such as from 3 nm to 10 nm, although lesser and greater thicknesses may also be used.

According to an aspect of the present disclosure, the material of the amorphous metal oxide layer 20L is selected from materials of which the conductivity type (i.e., p-type or n-type) may be modulated by the oxygen content therein. Such materials comprise tin oxide and titanium oxide. In such embodiments, an n-type metal oxide material may be formed by promoting hydrogen diffusion from a hydrogen-containing dielectric layer into a portion of an amorphous metal oxide semiconductor layer. For example, in instances in which the amorphous metal oxide layer comprises tin oxide, a chemical reaction may accompany the anneal process. The chemical process may be represented by SnOₓ+δH₂→SnO_{x-δ}+δH₂O, in which x has a value that is greater than 1.0+δ and less than 2.0, and d is in a range from 0.05 to 0.5.

Tin oxide is a compound semiconductor material that may exhibit p-type conductivity under suitable conditions. in a crystalline state (which may be obtained by deposition of an amorphous tin oxide material followed by a crystallization anneal process). P-type conductivity means that the primary charge carriers in the material are “holes,” which are essentially places where an electron is absent, allowing for the movement of positive charge. The stoichiometry, or the ratio of oxygen to tin, plays a crucial role in determining the properties of tin oxide as a p-type semiconductor. The ideal stoichiometry of tin oxide for p-type conductivity is a 1:1 ratio of oxygen to tin, which corresponds to the stoichiometric compound of SnO. In a crystallized form of this stoichiometric form composition, SnO has a tetragonal crystal structure with each tin atom coordinated by two oxygen atoms in a linear fashion. This structure is conducive to the formation of holes, which are created when tin atoms have fewer than the expected number of oxygen neighbors, leading to an incomplete electron shell and the creation of a hole.

Generally, the electrical properties of a tin oxide material are critically dependent on the atomic ratio of oxygen to tin (O:Sn) in the tin oxide material. For a p-type tin oxide semiconductor material, the values for O:Sn may be in a range from 0.95 to 1.15. When the O:Sn is in this range, tin vacancies create holes which act as charge carriers, leading to p-type conductivity. Lower values below 0.95 for O:Sn result in metallic tin formation. Higher values above 1.15 results in transition to an n-type tin oxide material due to filling of the oxygen vacancies.

To elaborate, the electrical conductivity in tin oxide materials changes with the atomic ratio of oxygen to tin as follows. In stoichiometric tin oxide, the electrical conductivity is at a baseline value in a range from 10⁻³ S/m to 0.1 S/m. This state corresponds to the relatively low density of holes as charge carriers in stoichiometric tin monoxide. The hole mobility in SnO is also typically lower than the electron mobility in SnO2. In sub-stoichiometric tin oxide SnOy in which y is in a range from 0.95 to 1.0, the tin oxide material may still be a p-type semiconductor material. As the value of y decreases from 1.0 toward 0.95 and prior to formation of metallic tin grains, the electrically conductivity may increase as the number of holes increases, up to a point where it becomes too non-stoichiometric and starts to lose its p-type character. For a tin oxide material having a material composition of SnOx in which x is in a range from greater than 1.0 and less than 1.15, the electrical conductivity of the tin oxide material initially decreases within an increase in the value of x from 1.0 because the density of holes decreases. Upon further increase of the value of x toward a transition value of about 1.15, the tin oxide material changes the crystallographic phase into the phase of a tin dioxide material, and thus, becomes an n-type tin oxide material with free electrons providing high electrical conductivity type.

Generally, the electrical conductivity of stoichiometric tin monoxide (SnO) without any external doping may be in the range from 10⁻³ S/m to 0.1 S/m, although lower and higher electrical conductivities may also be realized by tuning deposition conditions. In one embodiment, the amorphous metal oxide layer 20L comprises, and/or consists essentially of, an amorphous tin oxide material having an atomic oxygen to tin ratio in a range from 0.95 to 1.15, and preferably from 0.98 to 1.10. Thus, in instances in which the The crystallization of this amorphous tin oxide material of the is facilitated by an annealing process conducted at elevated temperatures, typically ranging from 200 degrees Celsius to 400 degrees Celsius. The anneal process causes the initially amorphous metal oxide layer 20L crystallizestin oxide material to transition into a crystalline form without change inchanging the material composition. As a result of this anneal process, a p-doped tin oxide material is obtained.

Titanium oxide is a material of which the electrical conductivity type (which may be p-type or n-type) may be changed through modulation of the concentration of oxygen vacancies. Stoichiometric and near-stoichiometric titanium oxide may behave as an n-type semiconductor material. In other words, the majority of the charge carriers in the stoichiometric or near-stoichiometric titanium oxide are electrons. Oxygen vacancies in titanium oxide typically contribute to n-type conductivity because the oxygen vacancies act as electron donors. In instances in which oxygen atoms are removed as ions, free electrons are left behind, which increases the electron concentration and thus enhance the n-type conductivity.

Providing p-type conductivity in titanium oxide may be achieved by introducing p-type dopant atoms into titanium oxide. Nitrogen atoms, fluorine atoms, or boron atoms may be used as p-type dopants (i.e., acceptor dopants) for titanium oxide. Thus, when a sufficient atomic concentration of acceptor atoms are present in a titanium oxide material, the titanium oxide material may function as a p-type metal oxide semiconductor material.

Modulation of the conductivity type in titanium oxide may be effected by providing a doped titanium oxide material including a sufficiently high concentration of acceptor dopants so that the doped titanium oxide material exhibits p-type conductivity. N-type conductivity may be induced by increasing the oxygen vacancy concentration. A small level of increase in the concentration of oxygen vacancy may keep the conductivity of the doped titanium oxide material as p-type, while a sufficient level of increase in the concentration of oxygen vacancies leads to manifestation of n-type conductivity. Generally, oxygen vacancies act as electron donors as free electrons are left behind after removal of oxygen ions in a positive charged state. Reduction of the oxygen vacancies result in reduction of the free electrons, and thus, the conductivity type of the doped titanium oxide material may shift to the p-type conductivity.

Generally, any amorphous metal oxide material may be used for the amorphous metal oxide layer 20L provided that such the conductivity type of the amorphous metal oxide material may be switched between p-type and n-type depending on the concentration of oxygen vacancies by subsequently annealing the amorphous metal oxide material.

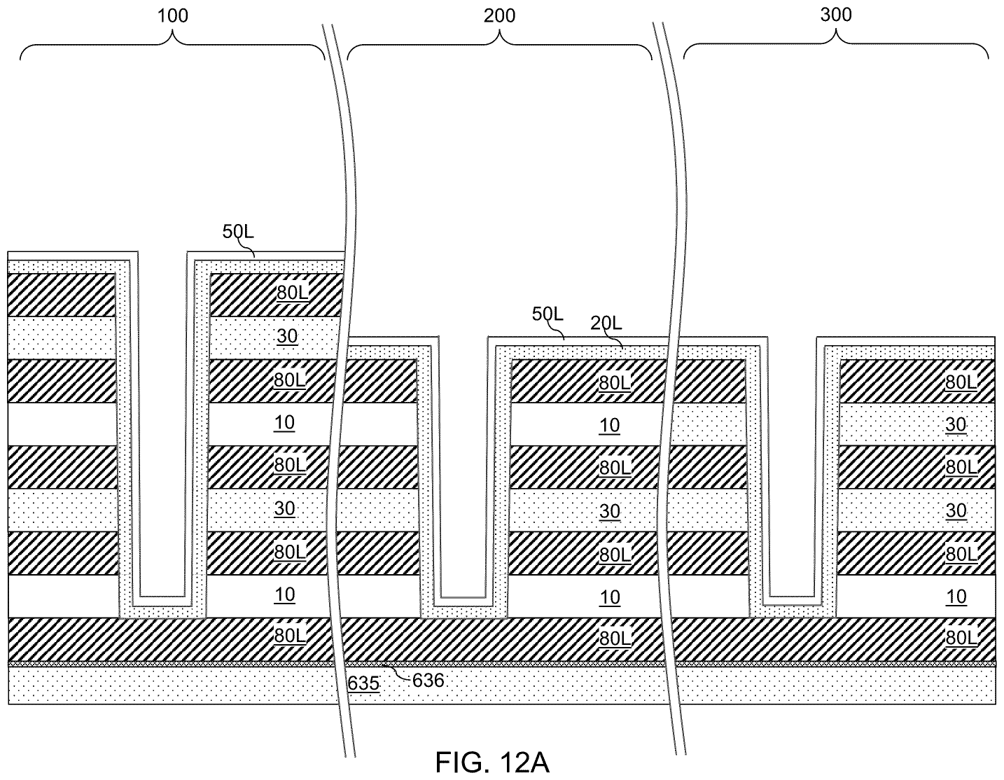

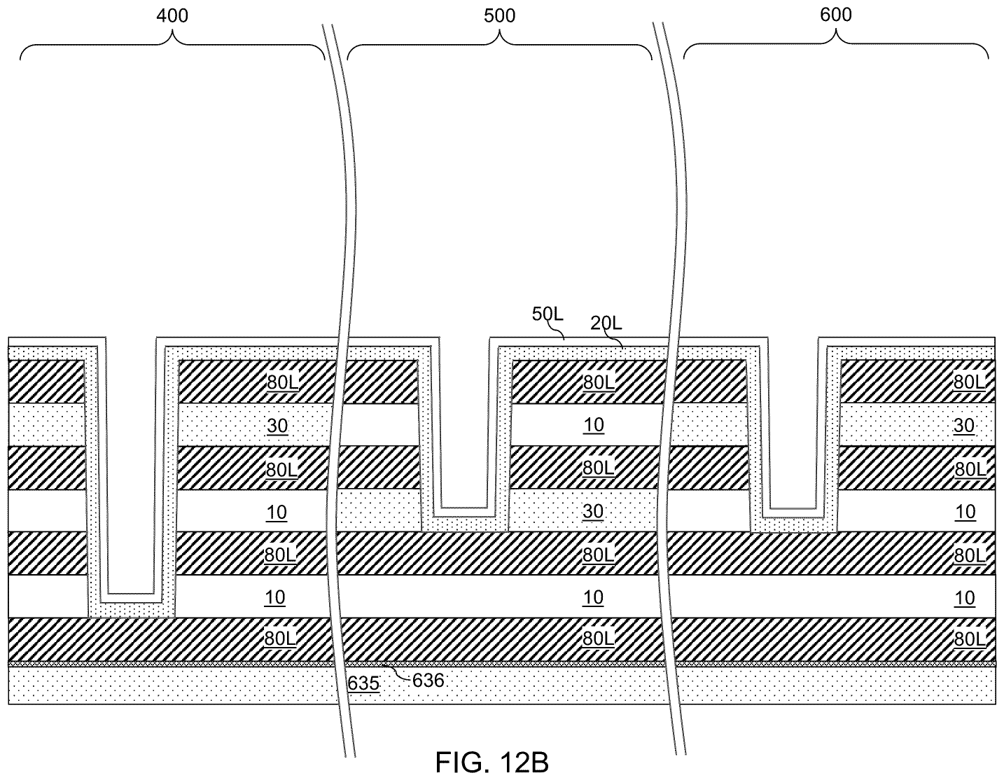

Referring to FIGS. 12A and 12B, a gate dielectric layer 50L may be conformally deposited on the amorphous metal oxide layer 20L. The gate dielectric layer 50L may include, but is not limited to, silicon oxide, silicon oxynitride, silicon nitride, a dielectric metal oxide (such as aluminum oxide, hafnium oxide, yttrium oxide, zirconium oxide, lanthanum oxide, etc.), or a stack thereof. In a non-limiting illustrative example, the gate dielectric layer 50L may comprise, and/or may consist essentially of at least one dielectric metal oxide material (such as aluminum oxide, hafnium oxide, titanium oxide, tantalum oxide, lanthanum oxide, hafnium silicate, etc.), silicon oxide, silicon nitride, an ONO stack, or other gate dielectric material known in the art. The gate dielectric layer 50L may be deposited by atomic layer deposition (ALD) or chemical vapor deposition (CVD). The thickness of the gate dielectric layer 50L may be in a range from 1 nm to 20 nm, such as from 5 nm to 10 nm, although lesser and greater thicknesses may also be used.

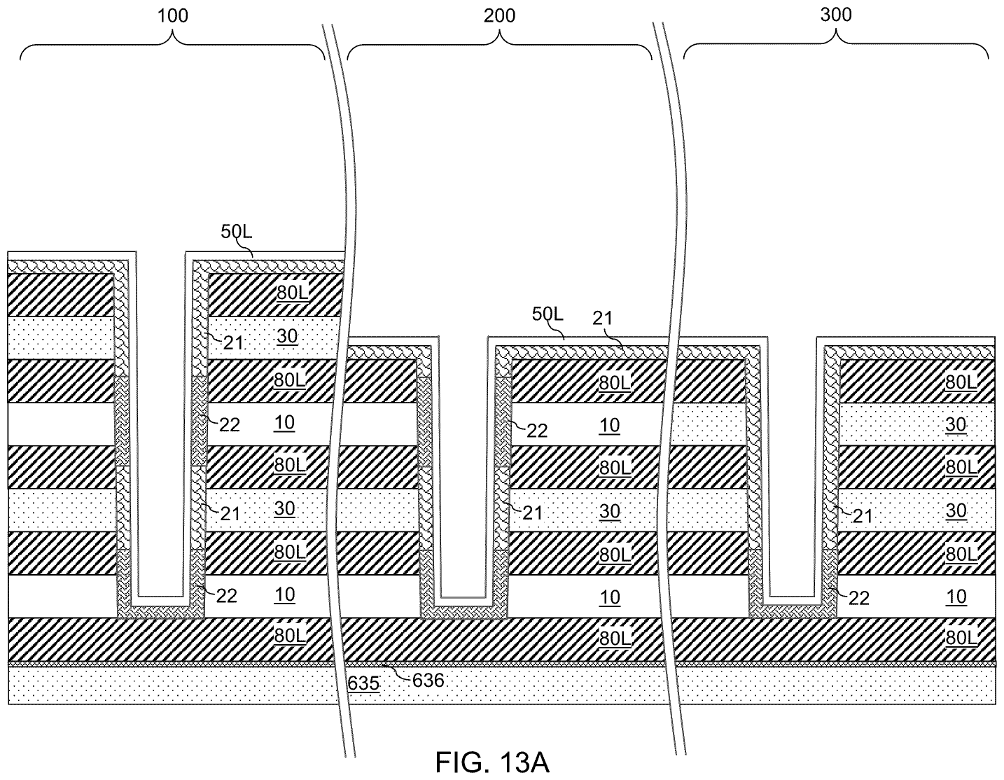

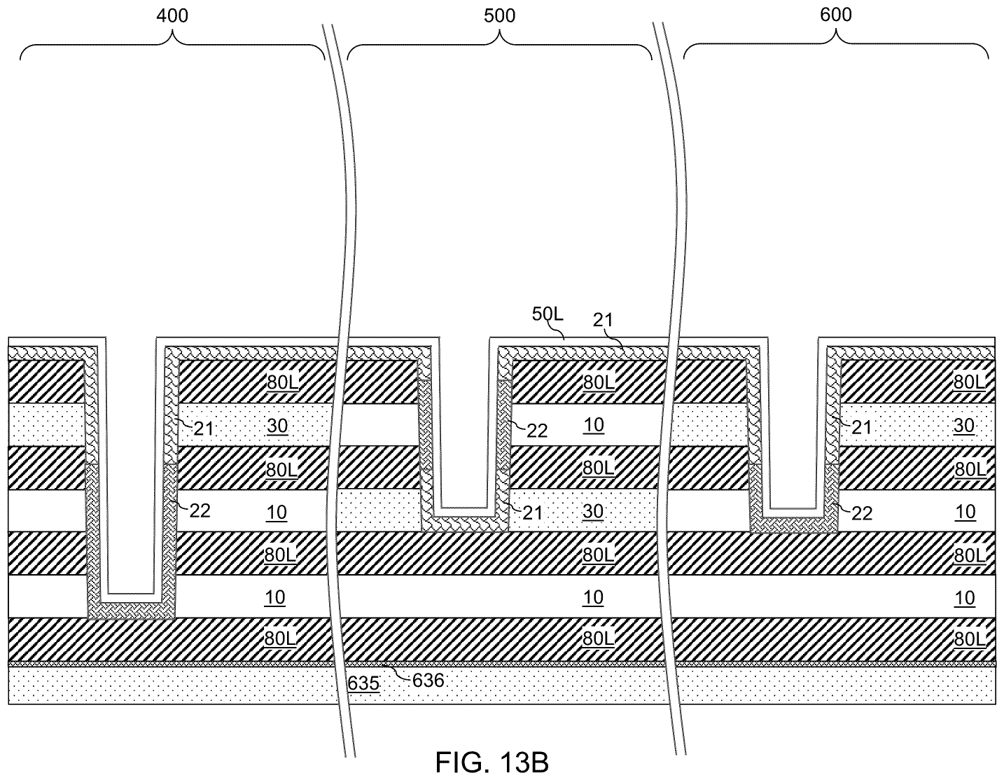

Referring to FIGS. 13A and 13B, an anneal process may be performed to convert the amorphous metal oxide layer 20L into crystalline metal oxide layers. The anneal process may be performed in an oxygen-free environment or in an oxygen-containing environment. Generally, the choice between the oxygen-containing environment and the oxygen-free environment is determined depending on the need to supply additional oxygen to the amorphous metal oxide layer 20L during the crystallization process to induce formation of two-types of metal oxide semiconductor materials. In instances in which the amorphous metal oxide layer 20L comprises a sufficient concentration of oxygen atoms for crystallizing into an n-type metal oxide semiconductor material, an oxygen-free environment may be used during the anneal process. For example, a nitrogen-containing environment may be used for the anneal process. In instances in which the amorphous metal oxide layer 20L comprises an insufficient concentration of oxygen atoms for crystallizing into an n-type metal oxide semiconductor material, an oxygen-containing environment may be used during the anneal process. For example, oxygen may be flowed into a process chamber during the anneal process. The temperature of the anneal process may be in a range from 200 degrees Celsius to 400 degrees Celsius, although lower and higher temperatures may also be used. The duration of the anneal process at the elevated temperature may be in a range from 1 minute to 120 minutes, although lesser and greater durations may also be used.

During the anneal process, the hydrogen-containing dielectric layers 10 function as oxygen sinks that absorb oxygen atoms from adjacent portions of the amorphous metal oxide layer 20L. Thus, portions of the amorphous metal oxide layer 20L that are proximal to the hydrogen-containing dielectric layers 10 lose oxygen atoms, acquire excess free electrons, and are converted into n-type metal oxide semiconductor layers 22 having n-type electrical conductivity, i.e., containing free electrons as free charge carriers.

The hydrogen-blocking dielectric layer 30 function as hydrogen barriers that block diffusion of hydrogen atoms therethrough. The hydrogen-blocking dielectric layers 30 do not absorb any oxygen atoms from the amorphous metal oxide layer 20L. Thus, portions of the amorphous metal oxide layer 20L that are proximal to the hydrogen-blocking dielectric layers 30 do not lose oxygen atoms, and are converted into p-type metal oxide semiconductor layer 21 having p-type electrical conductivity, i.e., containing holes as free charge carriers. Generally, a p-n junction may be formed at each interface between a contacting pair of a p-type metal oxide semiconductor layer 21 and an n-type metal oxide semiconductor layer 22.

In embodiments in which an oxidizing ambient is used during the anneal process, the partial pressure of oxygen atoms during the anneal process is controlled such that the number of oxygen atoms that diffuse from the oxygen ambient through the gate dielectric layer 50L into the amorphous metal oxide layer 20L is less than the number of oxygen atoms that portions of the amorphous metal oxide layer 20L that are proximal to the hydrogen-containing dielectric layers 10 lose to the hydrogen-containing dielectric layers 10. Thus, the oxygen concentration in the portions of the amorphous metal oxide layer 20L that are proximal to the hydrogen-containing dielectric layers 10 lose enough oxygen atoms, and are converted into the n-type metal oxide semiconductor layers 22 having n-type electrical conductivity. Use of an oxidizing ambient during the anneal process generally facilitates formation of the p-type metal oxide semiconductor layer 21 through reduction of the concentration of the oxygen vacancies in portions of the amorphous metal oxide layer 20L that are proximal to the hydrogen-blocking dielectric layers 30.

Generally, during the anneal process at an elevated temperature, the hydrogen-containing dielectric layers 10 function as oxygen sinks which absorb oxygen atoms from adjacent portions of amorphous metal oxide layer 20L. As a result, portions of the amorphous metal oxide layer 20L that are proximal to the hydrogen-containing dielectric layers 10 lose oxygen atoms, and thus, acquire excess free electrons during transition from an amorphous state to a crystalline state. The portions of the amorphous metal oxide layer 20L that acquire excess free electrons are converted into n-type metal oxide semiconductor layers 22, which exhibit n-type electrical conductivity due to presence of free electrons as charge carriers. In contrast, the hydrogen-blocking dielectric layers 30 act as hydrogen-diffusion barriers which inhibit the diffusion of hydrogen atoms therethrough. Thus, the hydrogen-blocking dielectric layers 30 do not absorb any oxygen atoms from the amorphous metal oxide layer 20L. Consequently, portions of the amorphous metal oxide layer 20L that are proximal to the hydrogen-blocking dielectric layers 30 retain oxygen atoms while transitioning from an amorphous state to a crystalline state during the anneal process. The portions of the amorphous metal oxide layer 20L that retain oxygen atoms therein are converted into p-type metal oxide semiconductor layers 21, which exhibit p-type electrical conductivity due to presence of holes as primary charge carriers. Generally, a first portion of the amorphous metal oxide layer 20L in contact with a first-type insulating surface (such as a surface of a hydrogen-containing dielectric layer 10) is converted into an n-type metal oxide semiconductor layer 22 due to oxygen loss to hydrogen atoms in the hydrogen-containing dielectric material during the anneal process, and a second portion of the amorphous metal oxide layer 20L in contact with a second-type insulating surface (such as a surface of a hydrogen-blocking dielectric layer 30) is converted into a p-type metal oxide semiconductor layer 21 during the anneal process around each vertically-extending via cavity 19. In one embodiment, the first portion of the amorphous metal oxide layer 20L which is converted into an n-type metal oxide semiconductor layer 22 may extend between a first electrically conductive surface (such as a sidewall of an electrically conductive material layer 80L) and a second electrically conductive surface (such as a sidewall of another electrically conductive material layer 80L); and a second portion of the amorphous metal oxide layer 20L which is converted into a p-type metal oxide semiconductor layer 21 may extend between the second electrically conductive surface and a third electrically conductive surface (such as a sidewall of an additional electrically conductive material layer 80L). Each p-type metal oxide semiconductor layer 21 may comprise a channel of a respective n-type thin-film transistor; and each n-type metal oxide semiconductor layer 22 may comprise a channel of a respective an n-channel thin-film transistor.

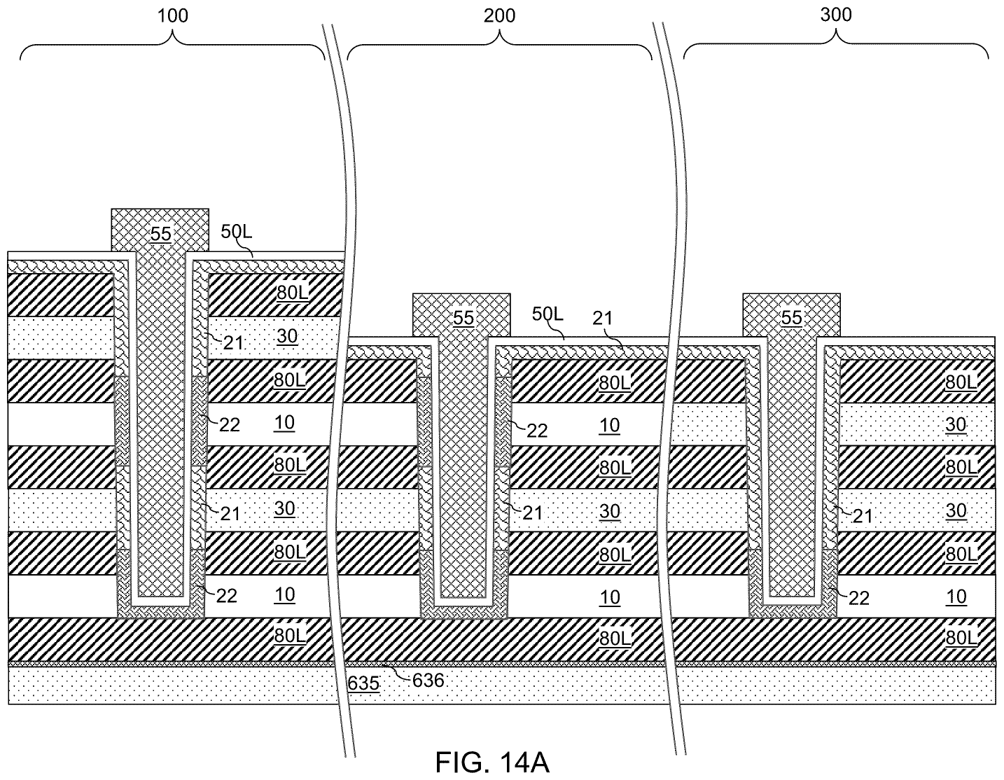

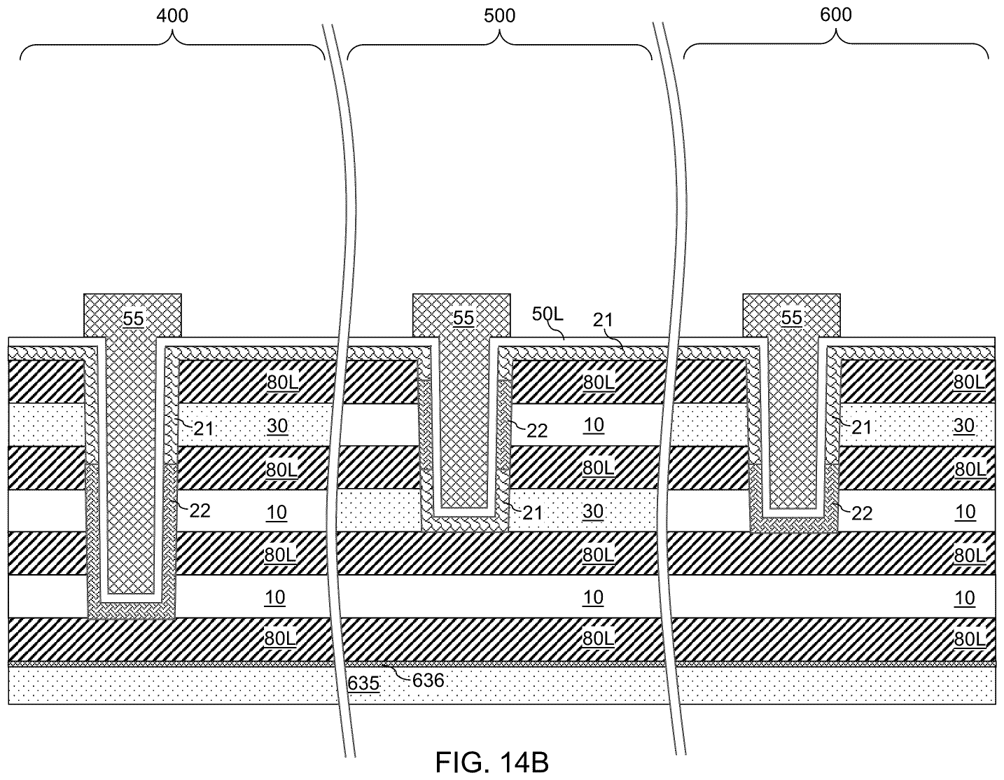

Referring to FIGS. 14A and 14B, a gate electrode material layer comprising at least one conductive gate electrode material may be deposited within each vertically-extending cavity 19. The at least one conductive gate electrode material may include, for example, a metallic barrier liner material (such as TiN, TaN, and/or WN) and/or a metallic fill material (such as Cu, W, Mo, Co, Ru, etc.). The gate electrode material layer may be deposited by chemical vapor deposition or physical vapor deposition. The gate electrode material layer 55 may completely fill the remaining volumes of the vertically-extending via cavities 19.

An etch mask layer (not shown) may be applied over the gate electrode material layer, and may be lithographically patterned to cover areas around the vertically-extending via cavities 19 in a plan view, such as a top-down view. A reactive ion etch process or an ion beam etch process may be performed to etch unmasked portions of the gate electrode material layer. Each patterned portion of the gate electrode material layer comprises a gate electrode 55, which may have shape of a plug having a vertically-extending portion located in a respective vertically-extending cavity 19 and a head portion overlying the respective vertically-extending cavity 19 and having a greater lateral extent than the vertically-extending portion. The etch mask layer may be subsequently removed.

A set of at least one vertical thin-film transistor may be formed within each device region (100, 200, 300, 400, 500, 600). The type of thin-film transistor(s) within each set of at least one vertical thin-film transistor may differ from device region (100, 200, 300, 400, 500, 600) to device region (100, 200, 300, 400, 500, 600). In some device regions (100, 200, 300, 400, 500, 600), a set of at least one vertical thin-film transistor may comprise a set of multiple vertical thin-film transistors. Each set of multiple vertical thin-film transistors may be formed within, and around, a respective vertically-extending cavity 19. Each transistor comprises a respective vertical semiconductor channel that comprises a portion of a respective one of the p-type metal oxide semiconductor layers 21 and the n-type metal oxide semiconductor layers 22. A neighboring pair of electrically conductive material portions 80 functions as a pair of source/drain electrodes, i.e., a source electrode and a drain electrode. Each set of multiple vertical thin-film transistors located within, and around, a respective vertically-extending cavity 19 shares a common gate electrode 55. The portion of the gate dielectric layer 50L interposed between the common gate electrode 55 and the sidewall of the vertically-extending cavity 19 constitutes a common gate dielectric for the set of multiple vertical thin-film transistors.

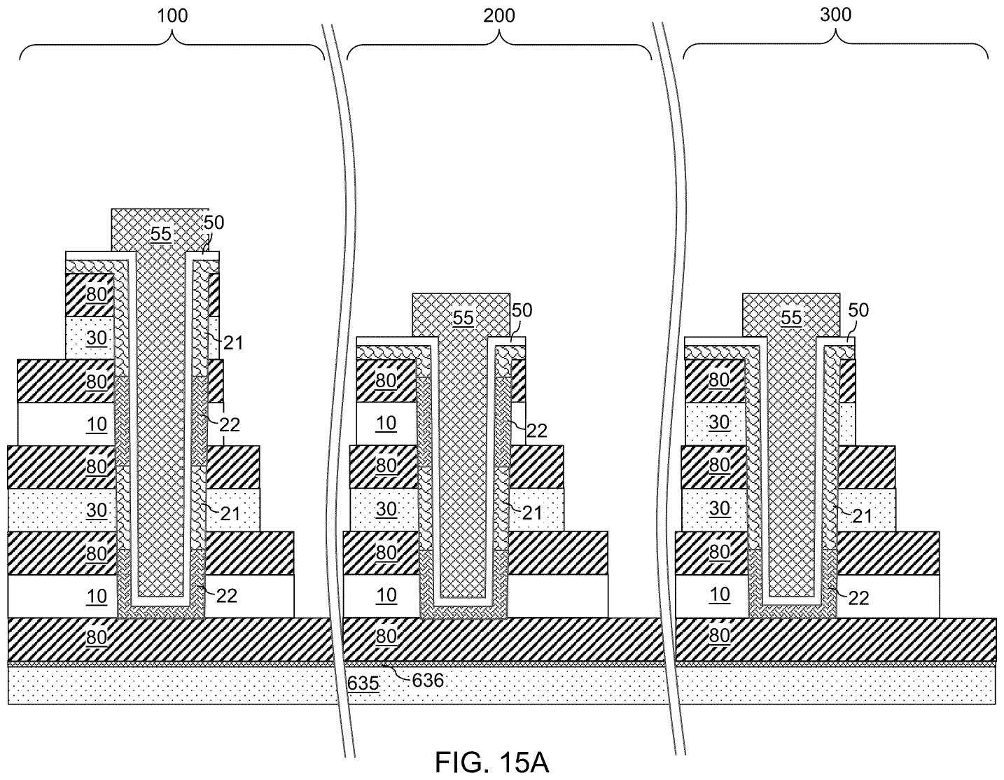

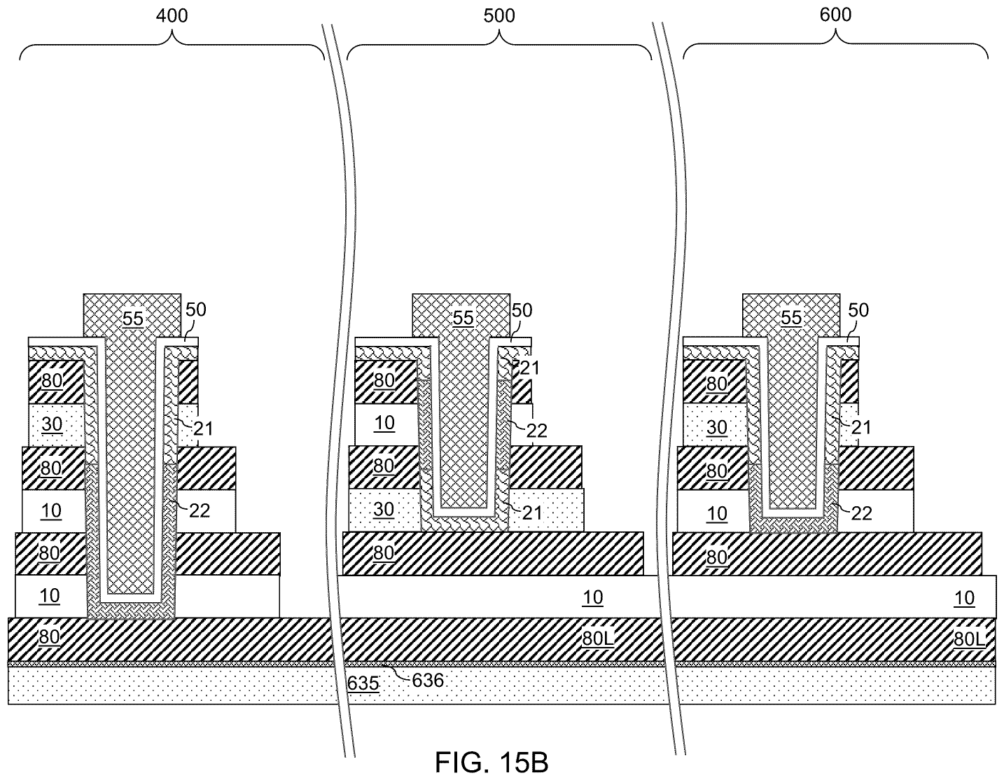

Referring to FIGS. 15A and 15B, a sequence of patterning processes may be performed to electrically isolate laterally-neighboring pairs of sets of at least one vertical thin-film transistors. For example, a combination of lithographic masking processes and etch processes may be used to pattern each electrically conductive material layer 80L that is in direct contact with any of the p-type metal oxide semiconductor layers 21 and the n-type metal oxide semiconductor layers 22 unless electrical connection between electrical nodes of adjacent vertical field transistors located at the same level is desired to provide circuit connections. Thus, each set of at least one vertical thin-film transistor located within, and around, a respective one of the vertically-extending via cavities 19 may be electrically isolated from one another unless lateral electrical connection for neighboring pairs of vertical thin-film transistors is desired.

Each patterned portion of the electrically conductive material layers 80L comprises an electrically conductive material portion 80, which functions as a source/drain electrode. Each source/drain electrode may operate as a source electrode or a drain electrode depending on the electrical bias conditions used to operate a respective thin-film transistor. Various types of series connections of vertical thin-film transistor sharing a common gate electrode 55 may be formed in each device region (100, 200, 300, 400, 500, 600). For example, the first device region 100 may include a series connection, from bottom to top, of a first n-channel thin-film transistor, a first p-channel thin film transistor, a second n-channel thin-film transistor, and a second p-channel thin-film transistor. The second device region 200 may include a series connection, from bottom to top, of a first n-channel thin-film transistor, a p-channel thin film transistor, and a second n-channel thin-film transistor. The third device region 300 may include a series connection, from bottom to top, of an n-channel thin-film transistor, a first p-channel thin film transistor, and a second p-channel thin-film transistor. The fourth device region 400 may include a series connection, from bottom to top, of a first n-channel thin-film transistor, a second n-channel thin-film transistor, and a p-channel thin-film transistor. The fifth device region 500 may include a series connection, from bottom to top, of a p-channel thin-film transistor and an n-channel thin-film transistor. The sixth device region 600 may include a series connection, from bottom to top, of an n-channel thin-film transistor and a p-channel thin-film transistor. The stack of thin-film transistors in the fifth device region 500 and the sixth device region 600 may function as inverter circuits. The functionality of an inverter circuit is well known in the art.

Generally, a series connection of any sequence of p-channel thin-film transistors and n-channel thin-film transistor may be formed using embodiments of the present disclosure. Further, a single thin-film transistors may also be formed by using a vertically-extending via cavity that vertically extends only between a vertically-neighboring pair of electrically conductive material layers 80L. Such variations are expressly contemplated herein.

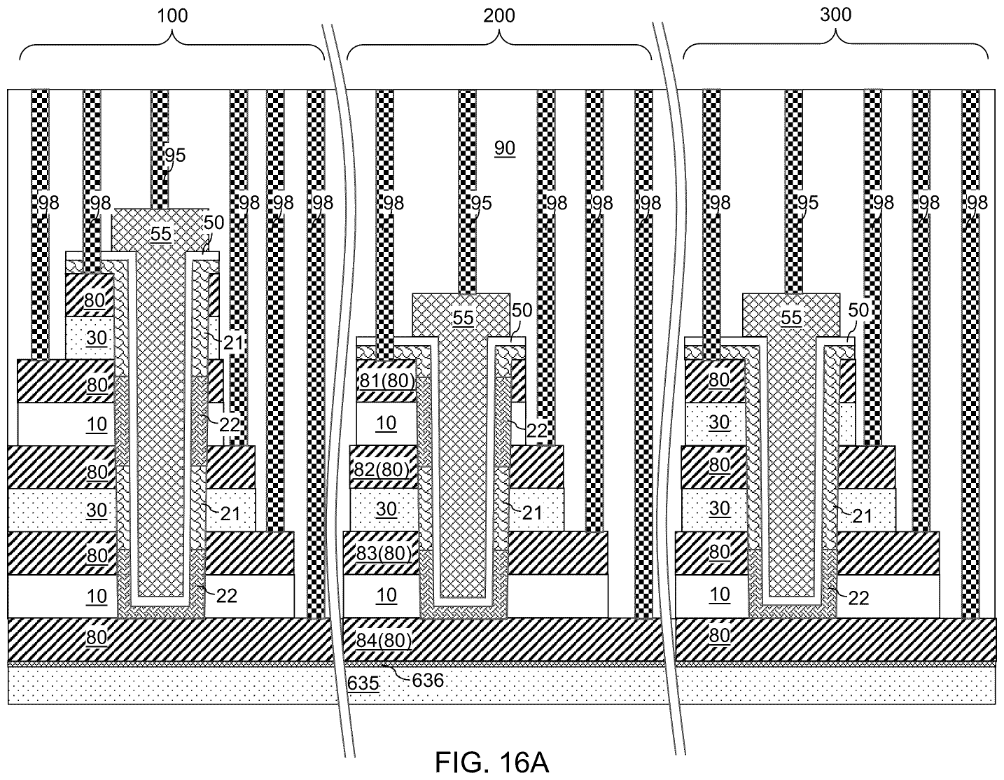

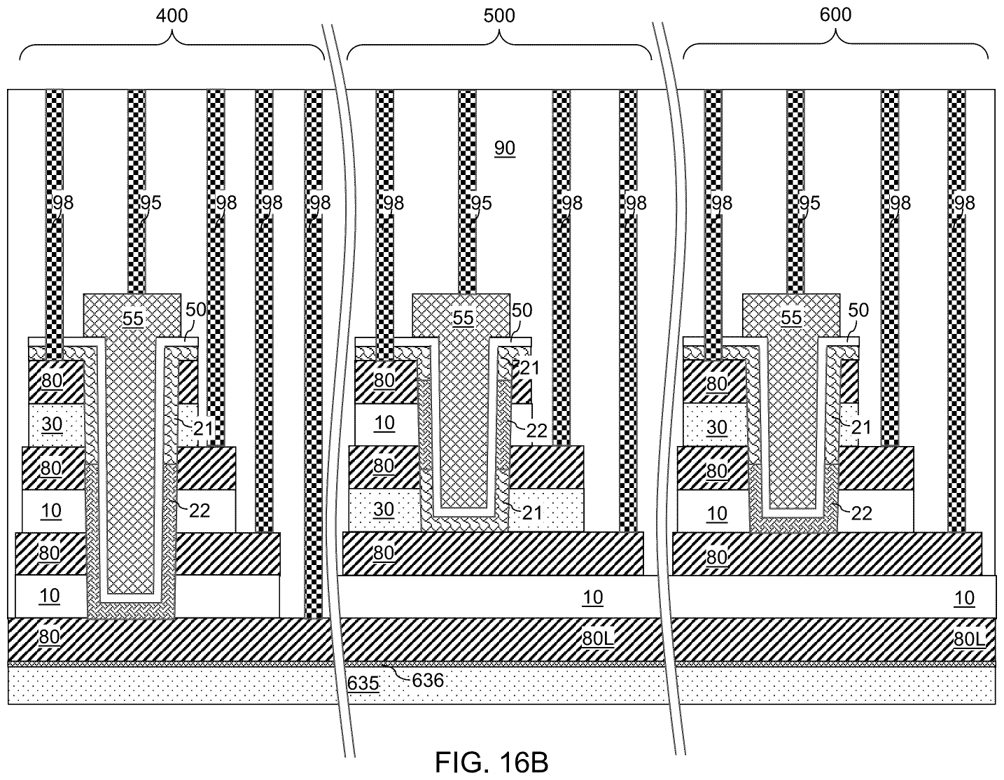

Referring to FIGS. 16A and 16B, a contact-level dielectric layer 90 may be deposited over the vertical stacks of vertical thin-film transistors. Various contact via cavities may be formed through the contact-level dielectric layer 90 over conductive structures embodying the electrical nodes of the vertical thin-film transistors. Various contact via structures (98, 95) may be formed in the various contact via cavities. The various contact via structures (98, 95) may comprise source/drain contact via structures 98 contacting a respective electrically conductive material portion 80 (which functions as a source/drain electrode) and gate contact via structures 95 contacting a respective gate electrode 55.

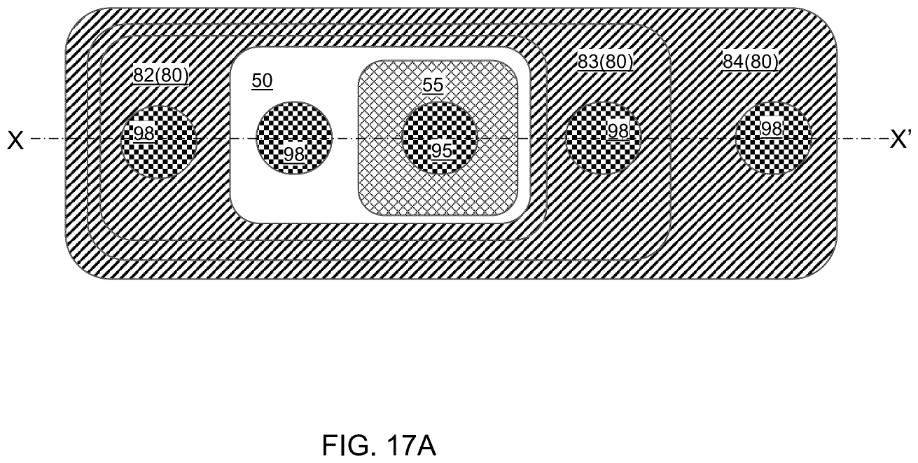

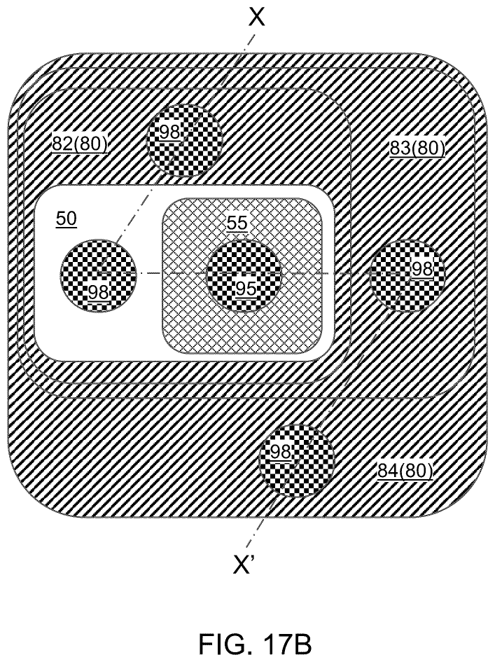

Referring to FIGS. 17A and 17B, exemplary layouts for contact via structures (98, 95) contacting electrical nodes of the vertical stack of vertical thin-film transistors in the second device region 200 are illustrated. The cut plane X-X′ in FIGS. 17A and 17B correspond to the cut plane for the view of the vertical stack of vertical thin-film transistors in the second device region 200 in FIG. 16A. For the purpose of illustration, the electrically conductive material portions 80 in the vertical thin-film transistors in the second device region 200 are labeled, from top to bottom, with reference numerals 81, 82, 83, and 84 in FIGS. 16A, 17A, and 17B. In other words, the electrically conductive material portions 80 in the vertical thin-film transistors in the second device region 200 comprise, from top to bottom, a topmost electrically conductive material layer 80L, a second-from-the-top electrically conductive material layer 82, a third-from-the-top electrically conductive material layer 83, and a bottom electrically conductive material layer 84. Generally, each of the electrically conductive material portions 80 in the vertical thin-film transistors may be patterned to enable formation of a respective contact via structure for electrically connecting the respective electrically conductive material portion 80.

Referring collectively to FIGS. 1-17B, a semiconductor structure is provided, which comprises: a p-n junction located at an interface between a p-type metal oxide semiconductor layer 21 and an n-type metal oxide semiconductor layer 22; a hydrogen-containing dielectric material portion containing hydrogen atoms at a concentration greater than a first atomic concentration (which may be at least 100 parts per million as discussed above) and having a first-type insulating surface (such as a surface of a hydrogen-containing dielectric layer 10) that contacts the n-type metal oxide semiconductor layer 22; and a hydrogen-blocking dielectric material portion comprising a second-type insulating surface (such as a surface of a hydrogen-blocking dielectric layer 30) that contacts the p-type metal oxide semiconductor layer 21, the second-type insulating surface (such as a surface of a hydrogen-blocking dielectric layer 30) being a hydrogen-impermeable surface.

In one embodiment, the semiconductor structure further comprises: a first electrically conductive material portion 80 in contact with a first portion of the p-type metal oxide semiconductor layer 21; a second electrically conductive material portion 80 in contact with a second portion of the p-type metal oxide semiconductor layer 21 and a first portion of the n-type metal oxide semiconductor layer 22; and a third electrically conductive material portion 80 in contact with a second portion of the n-type metal oxide semiconductor layer 22. In one embodiment, the first electrically conductive material portion 80, the second electrically conductive material portion 80, and the third electrically conductive material portion 80 comprise three electrically conductive material layers 80L that are vertically spaced from one another along a vertical direction that is perpendicular to a top surface of the substrate 8.

In one embodiment, the p-type metal oxide semiconductor layer 21 comprises a channel of a p-channel thin-film transistor; the n-type metal oxide semiconductor layer 22 comprises a channel of an n-channel thin-film transistor; and the first electrically conductive material portion 80, the second electrically conductive material portion 80, and the third electrically conductive material portion 80 comprise source/drain electrodes 80 of a combination of the n-type thin-film transistor and the n-channel thin-film transistor. In one embodiment, the semiconductor structure comprises at least one gate structure (50, 55) comprising a respective gate dielectric 50 and a respective gate electrode, wherein each of the p-type metal oxide semiconductor layer 21 and the n-type metal oxide semiconductor layer 22 is contacted by the at least one gate structure (50, 55).

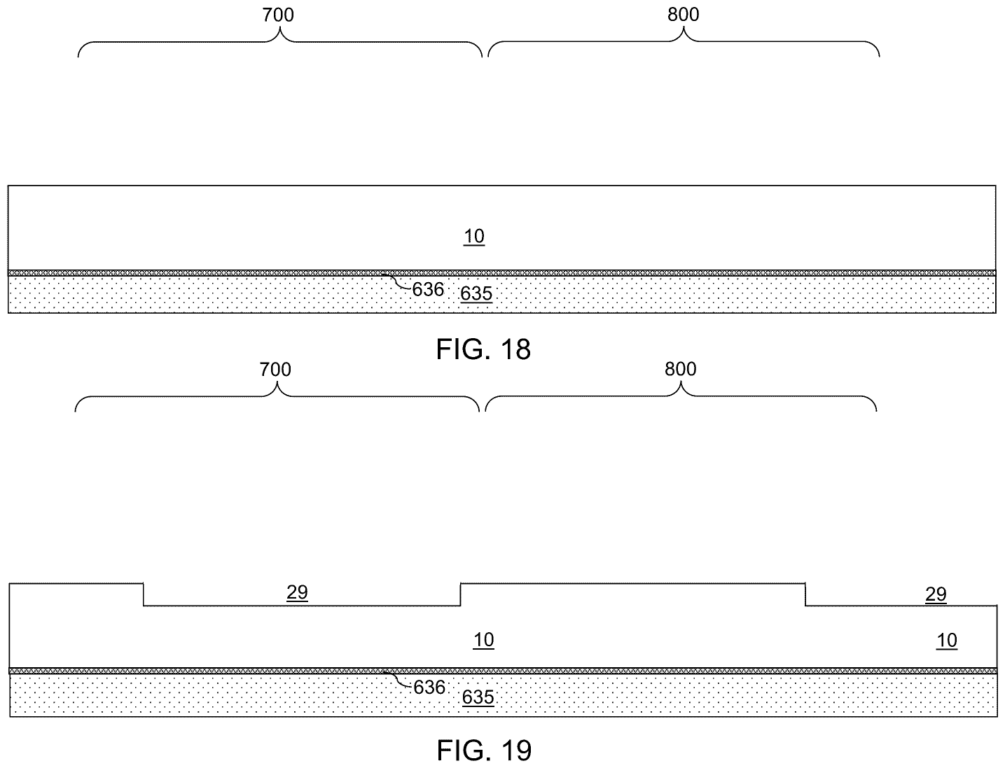

Referring to FIG. 18, a region of a second exemplary structure is illustrated according to an embodiment of the present disclosure. The second exemplary structure may be derived from the first exemplary structure illustrated in FIG. 1 by forming a hydrogen-containing dielectric layer 10 on a top surface of the etch stop dielectric layer 636. The second exemplary structure may comprise a p-channel transistor region 700 in which a p-channel thin-film transistor is to be subsequently formed, and an n-channel transistor region 800 in which an n-channel thin-film transistor is to be subsequently formed. The hydrogen-containing dielectric layer 10 in the second exemplary structure may have any material composition of the hydrogen-containing dielectric layer 10 described with reference to the first exemplary structure. The thickness of the hydrogen-containing dielectric layer 10 in the second exemplary structure may be in a range from 50 nm to 500 nm, such as from 100 nm to 300 nm, although lesser and greater thicknesses may also be used.

Referring to FIG. 19, recess regions 29 may be optionally formed by vertically recessing upper portions of the hydrogen-containing dielectric layer 10. The areas in which the upper portions of the hydrogen-containing dielectric layer 10 are recessed correspond to areas in which p-type metal oxide semiconductor layers are to be subsequently formed. For example, a recess region 29 is formed around a center area of the p-channel transistor region 700, and is not formed around a center area of the n-channel transistor region 800. One of the recess regions 29 may be formed in a peripheral area of the n-channel transistor region 800.

In one embodiment, a photoresist layer (not shown) may be applied over the top surface of the hydrogen-containing dielectric layer 10, and may be lithographically patterned to form openings over the areas in which formation of p-type metal oxide semiconductor layers is desired. An etch process may be performed to vertically recess unmasked portions of the hydrogen-containing dielectric layer 10. A wet etch process or a reactive ion etch process may be performed. The recess depth of the recess regions 29 may be in a range from 5 nm to 100 nm, such as from 10 nm to 50 nm, although lesser and greater recess depths may also be used. The photoresist layer may be subsequently removed, for example, by ashing.

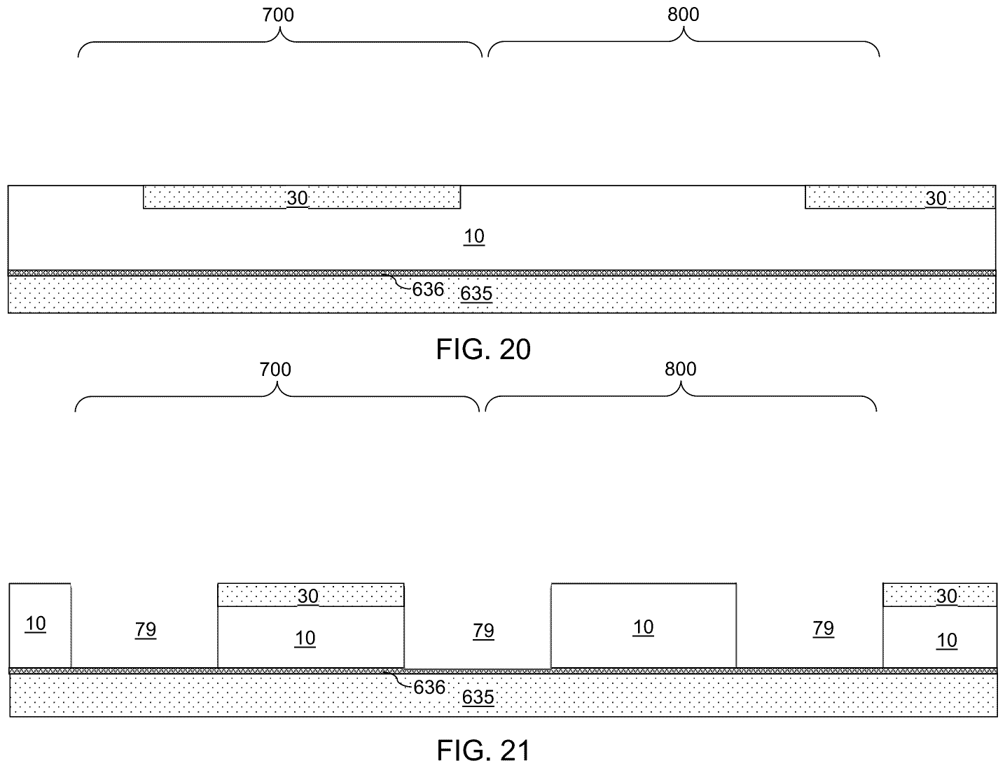

Referring to FIG. 20, a hydrogen-blocking dielectric material may be deposited in the recess regions 29. The hydrogen-blocking dielectric material may comprise any of the hydrogen-blocking dielectric materials that may be used for the hydrogen-blocking dielectric layers 30 in the first exemplary structure. The thickness of the hydrogen-blocking dielectric material may be about the same as, or may be greater than, the recess depth of the recess regions 29. Excess portions of the hydrogen-blocking dielectric material may be removed from outside the areas of the recess regions 29. For example, a patterned photoresist layer may be formed to cover portions of the hydrogen-blocking dielectric material that are located inside the areas of the recess regions 29. Portions of the hydrogen-blocking dielectric material that are located outside the areas of the recess regions 29 may be removed by performing an etch process. The photoresist layer may be subsequently removed, for example, by ashing. Alternatively, the excess portions of the hydrogen-blocking dielectric material may be removed from outside the areas of the recess regions 29 by performing a planarization process. In this embodiment, the planarization process may comprise a chemical mechanical polishing process.

A hydrogen-blocking dielectric layer 30 may be formed within each recess region 29. The hydrogen-blocking dielectric layers 30 in the second exemplary structure may have the same material composition as any hydrogen-blocking dielectric layer 30 that may be used in the first exemplary structure. To reiterate, each hydrogen-blocking dielectric layer 30 of the present disclosure may comprise a dielectric material that is substantially free of hydrogen atoms, or contains hydrogen atoms at a low atomic concentration such as an atomic concentration lower than a second atomic concentration (which may be 30 parts per million or less, and preferably 10 parts per million or less, and more preferably 3 parts per million or less). Further, the dielectric material of the hydrogen-blocking dielectric layers 30 is selected from dielectric materials that effectively block diffusion of hydrogen atoms therethrough. Examples of such dielectric materials include alkaline-earth oxides such as magnesium oxide, calcium oxide, and strontium oxide. In one embodiment, the hydrogen-blocking dielectric layers 30 comprise, and/or consist essentially of, at least one alkaline-earth oxide material. In one embodiment, the hydrogen-blocking dielectric layers 30 consist of magnesium oxide, calcium oxide, or an alloy or a stack thereof. The thickness of the hydrogen-blocking dielectric layers 30 may be in a range from 5 nm to 100 nm, such as from 10 nm to 50 nm, although lesser and greater recess depths may also be used. The top surfaces of the hydrogen-blocking dielectric layers 30 may be coplanar with, may protrude above, or may be recessed below, a horizontal plane including the top surface of the hydrogen-containing dielectric layer 10.

A combination of a first-type insulating surface (such as a surface of a hydrogen-containing dielectric layer 10) and a second-type insulating surface (such as a surface of a hydrogen-blocking dielectric layer 30) may be formed. The first-type insulating surface (such as a surface of a hydrogen-containing dielectric layer 10) comprises a remaining portion of the top surface of the hydrogen-containing dielectric layer 10. The second-type insulating surface (such as a surface of a hydrogen-blocking dielectric layer 30) comprises a top surface of a portion of the hydrogen-blocking dielectric material, i.e., a top surface of a hydrogen-blocking dielectric layer 30.

Generally, a combination of a first-type insulating surface (such as a surface of a hydrogen-containing dielectric layer 10) and a second-type insulating surface (such as a surface of a hydrogen-blocking dielectric layer 30) may be formed over a substrate 8. The first-type insulating surface (such as a surface of a hydrogen-containing dielectric layer 10) is a surface of a hydrogen-containing dielectric material containing hydrogen atoms at a concentration greater than a first atomic concentration (which may be at least 100 parts per million as discussed above), and the second-type insulating surface (such as a surface of a hydrogen-blocking dielectric layer 30) is a hydrogen-impermeable surface of a hydrogen-blocking dielectric material.

Referring to FIG. 21, a photoresist layer (not shown) may be applied over a combination of the insulating layer (such as the hydrogen-containing dielectric layer 10) and portions of the hydrogen-blocking dielectric material (such as the hydrogen-blocking dielectric layers 30). The photoresist layer may be lithographically patterned to form a pair of elongated openings in each area in which source/drain electrodes of thin-film transistors are to be subsequently formed. Neighboring pairs of elongated openings may be laterally spaced from each other by a respective uniform lateral spacing, which is the channel length of a respective thin-film transistor to be subsequently formed. The channel length may be in a range from 5 nm to 300 nm, such as from 10 nm to 50 nm, although lesser and greater channel lengths may also be used. In one embodiment, the elongated openings in the photoresist layer may be formed over a subset of non-horizontal boundaries between the hydrogen-containing dielectric layer 10 and the hydrogen-blocking dielectric layers 30.

An anisotropic etch process may be performed to transfer the pattern of the elongated openings through the insulating layer 10. Source/drain cavities 79 may be formed through the combination of the hydrogen-containing dielectric layer 10 and the hydrogen-blocking dielectric layers 30 underneath the elongated openings in the photoresist layer. In one embodiment, a surface segment of the top surface of the etch stop dielectric layer 636 may be physically exposed underneath each of the source/drain cavities 79. Generally, the depth of the source/drain cavities 79 may be the same as, or less than, the maximum thickness of the hydrogen-containing dielectric layer 10. The photoresist layer may be subsequently removed, for example, by ashing.

At least one conductive material, such as at least one metallic material, may be deposited in the source/drain cavities 79 and over the combination of the hydrogen-containing dielectric layer 10 and the hydrogen-blocking dielectric layers 30. The at least one conductive material may include a metallic barrier liner layer including a metallic barrier liner material and a metallic fill material layer including a metallic fill material. The metallic barrier liner material may include a conductive metallic nitride or a conductive metallic carbide such as TiN, TaN, WN, TiC, TaC, and/or WC. The metallic fill material may include W, Cu, Al, Co, Ru, Mo, Ta, Ti, alloys thereof, and/or combinations thereof.

Portions of the at least one metallic material may be removed from outside the source/drain cavities 79 by a planarization process, which may use a chemical mechanical polishing (CMP) process and/or a recess etch process. Each remaining portion of the at least one conductive material filling a source/drain cavity constitutes an electrically conductive material portion 80, which is a source/drain electrode. In one embodiment, each source/drain electrode 80 may include a metallic barrier liner 80A that is a remaining portion of the metallic barrier liner material, and a metal fill portion 80F that is a remaining portion of the metallic fill material.

Generally, a spatially-extending sequence of surfaces may be formed. The spatially-extending sequence of surfaces may be arranged along a horizontal direction, and may comprise, from one end to another, a first electrically conductive surface, a first-type insulating surface (such as a surface of a hydrogen-containing dielectric layer 10), a second electrically conductive surface, a second-type insulating surface (such as a surface of a hydrogen-blocking dielectric layer 30), and a third electrically conductive surface, wherein the first-type insulating surface (such as a surface of a hydrogen-containing dielectric layer 10) is a surface of a hydrogen-containing dielectric material containing hydrogen atoms at a concentration greater than a first atomic concentration (which may be at least 100 parts per million as discussed above), and the second-type insulating surface (such as a surface of a hydrogen-blocking dielectric layer 30) of a hydrogen-impermeable surface of a hydrogen-blocking dielectric material.

In one embodiment, the first-type insulating surface (such as a surface of a hydrogen-containing dielectric layer 10) is formed between a first electrically conductive surface of a first electrically conductive material portion 80 and a second electrically conductive surface of a second electrically conductive material portion 80. In one embodiment, the second-type insulating surface (such as a surface of a hydrogen-blocking dielectric layer 30) is formed between the second electrically conductive surface and a third electrically conductive surface of a third electrically conductive material portion 80. The electrically conductive material portion may be formed by filling the source/drain cavities 79 with at least one electrically conductive material. The first electrically conductive material portion 80, the second electrically conductive material portion 80, and the third electrically conductive material portion 80 may comprise a respective portion of the at least one electrically conductive material that fills a respective one of the source/drain cavities 79. In one embodiment, each of the first electrically conductive material portion 80, the second electrically conductive material portion 80, and the third electrically conductive material portion 80 comprises a respective source/drain electrode 80 of thin-film transistors to be subsequently formed.

Referring to FIG. 23, the processing steps described with reference to FIGS. 11A and 11B may be performed to deposit an amorphous metal oxide layer 20L. The material composition and the thickness range of the amorphous metal oxide layer 20L in the second exemplary structure may be the same as the material composition and the thickness range of the amorphous metal oxide layer 20L in the first exemplary structure. The amorphous metal oxide layer 20L in the second exemplary structure does not require a conformal deposition process because the amorphous metal oxide layer 20L is formed on planar surfaces.

The processing steps described with reference to FIGS. 12A and 12B may be performed to form a gate dielectric layer 50L. The material composition and the thickness range of the gate dielectric layer 50L in the second exemplary structure may be the same as the material composition and the thickness range of the gate dielectric layer 50L in the first exemplary structure.

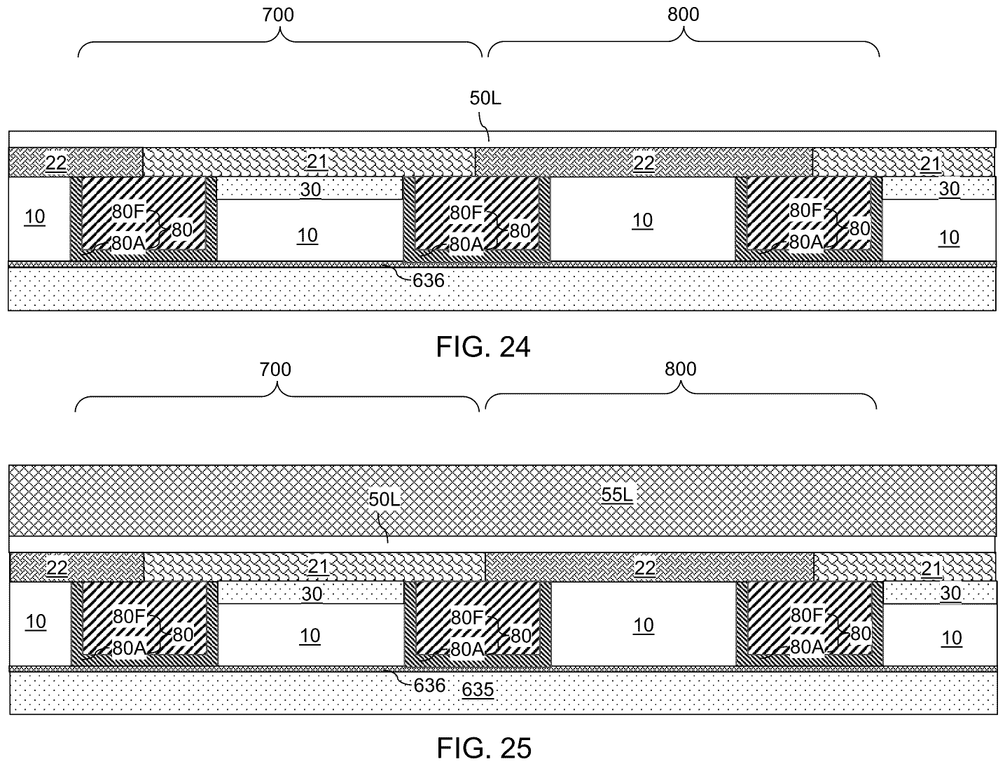

Referring to FIG. 24, the anneal process described with reference to FIGS. 13A and 13B may be performed to convert the amorphous metal oxide layer 20L into combination of p-type metal oxide semiconductor layers 21 and n-type metal oxide semiconductor layers 22. The process conditions for the anneal process at this processing step may be the same as the process conditions for the anneal process described with reference to FIGS. 13A and 13B.

Upon performing the anneal process at an elevated temperature, a first portion of the amorphous metal oxide layer 20L in contact with a first-type insulating surface (such as a surface of a hydrogen-containing dielectric layer 10) is converted into an n-type metal oxide semiconductor layer 22 due to oxygen loss to hydrogen atoms in the hydrogen-containing dielectric material in the hydrogen-containing dielectric layer 10 during the anneal process. A second portion of the amorphous metal oxide layer 20L in contact with a second-type insulating surface (such as a surface of a hydrogen-blocking dielectric layer 30) is converted into a p-type metal oxide semiconductor layer 21 during the anneal process.

In one embodiment, a first portion of the amorphous metal oxide layer 20L which is converted into an n-type metal oxide semiconductor layer 22 extends between a first electrically conductive surface (such as a top surface of a first electrically conductive material portion 80) and the second electrically conductive surface (such as a top surface of a second electrically conductive material portion 80); and a second portion of the amorphous metal oxide layer 20L which is converted into a p-type metal oxide semiconductor layer 21 extends between the second electrically conductive surface and the third electrically conductive surface (such as a top surface of a third electrically conductive material portion 80). In one embodiment, a p-type metal oxide semiconductor layer 21 comprises a channel of a p-channel thin-film transistor, and an n-type metal oxide semiconductor layer 22 comprises a channel of an n-channel thin-film transistor.

Generally, the conductivity type of the crystallized portions of the amorphous metal oxide layer 20L is determined by presence or absence of a contact with a hydrogen-blocking dielectric layer 30 at, or around, the crystallized portion. Each crystallized portion of the amorphous metal oxide layer 20L in contact with the hydrogen-containing dielectric layer 10 is converted into an n-type metal oxide semiconductor layer 22 due to loss of oxygen atoms and accumulation of free electrons. Each crystallized portion of the amorphous metal oxide layer 20L in contact with a hydrogen-blocking dielectric layer 30 is converted into a p-type metal oxide semiconductor layer 21. Portions of the crystallized portion of the amorphous metal oxide layer 20L not in contact with the hydrogen-containing dielectric layer 10 or a hydrogen-blocking dielectric layer 30 may be converted into a portion of an n-type metal oxide semiconductor layer 22 or into a portion of a p-type metal oxide semiconductor layer 21 depending on the relative proximity to the hydrogen-containing dielectric layer 10 and to the hydrogen-blocking dielectric layer 30.

In embodiments in which a top surface of an electrically conductive material portion 80 is located between a first-type insulating surface (such as a surface of a hydrogen-containing dielectric layer 10) and a second-type insulating surface (such as a surface of a hydrogen-blocking dielectric layer 30), a p-n junction may be formed on the top surface of the electrically conductive material portion 80.

Referring to FIG. 25, a gate electrode material layer 55L may be deposited over the gate dielectric layer 50L. The gate electrode material layer 55L comprises at least one conductive gate electrode material. The at least one conductive gate electrode material may include, for example, a metallic barrier liner material (such as TiN, TaN, and/or WN) and a metallic fill material (such as Cu, W, Mo, Co, Ru, etc.). The gate electrode material layer 55L may be deposited by chemical vapor deposition or physical vapor deposition. The thickness of the gate electrode material layer 55L may be in a range from 20 nm to 200 nm, although lesser and greater thicknesses may also be used.

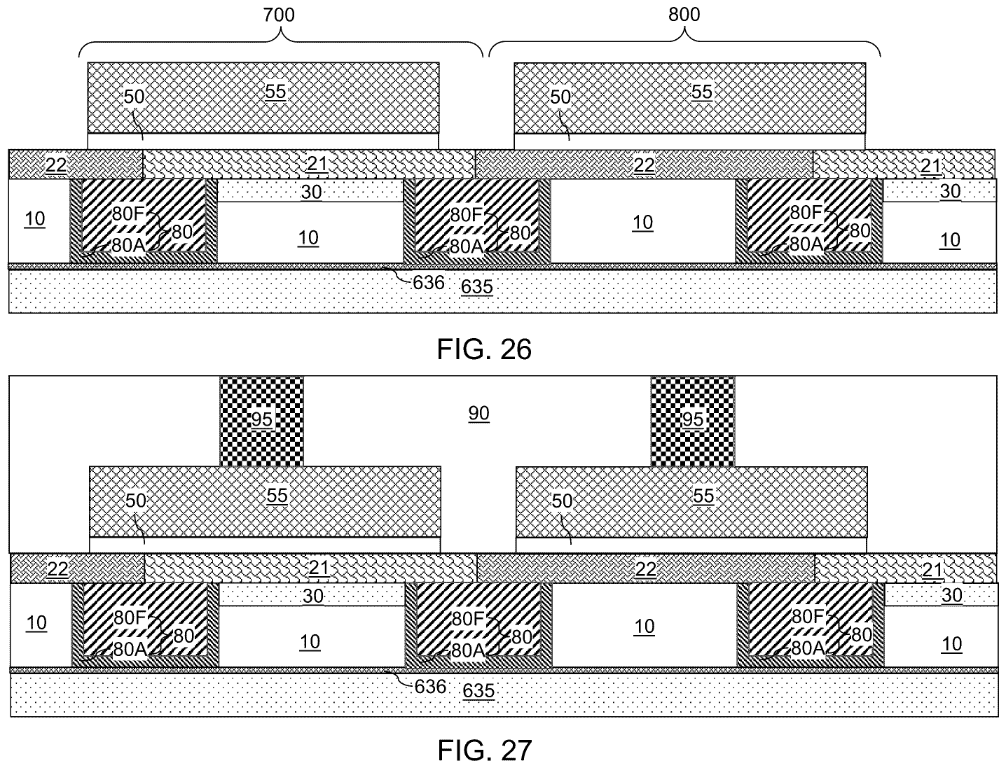

Referring to FIG. 26, the gate electrode material layer 55L and the gate dielectric layer 50L may be patterned to form gate structures (50, 55). Each gate structure (50, 55) may comprise a combination of a gate dielectric 50 and a gate electrode 55. Each gate dielectric 50 is a patterned portion of the gate dielectric layer 50L. Each gate electrode 55 is a patterned portion of the gate electrode material layer 55L. Each gate structure (50, 55) may laterally extend between a respective neighboring pair of electrically conductive material portions 80, which are source/drain electrodes. In one embodiment, a gate dielectric 50 may be in contact with a top edge of a p-n junction between a neighboring pair of a p-type metal oxide semiconductor layer 21 and an n-type metal oxide semiconductor layer 22.

A p-channel thin-film transistor is formed in the p-channel transistor region 700, and an n-channel thin-film transistor is formed in the n-channel transistor region 800. A contiguous set of at least one p-type metal oxide semiconductor layer 21 and at least one n-type metal oxide semiconductor layer 22 is formed. In some embodiments, one or more of the electrically conductive material portions 80 (which are source/drain electrodes) may contact a respective one of the p-n junctions between neighboring pairs of a p-type metal oxide semiconductor layers 21 and a n-type metal oxide semiconductor layers 22. The contiguous set of at least one p-type metal oxide semiconductor layer 21 and at least one n-type metal oxide semiconductor layer 22 may be optically patterned to provide electrical isolation from neighboring pairs of thin-film transistors. Further, for neighboring pairs of thin-film transistors for which electrical connection between source/drain electrodes is desirable, a source/drain electrode (comprising an electrically conductive material portion 80) may be shared. In this embodiment, a combination of a p-type metal oxide semiconductor layers 21 and a n-type metal oxide semiconductor layers 22 with a p-n junction therebetween may be used to form a serial connection of an n-channel thin-film transistor and a p-channel thin-film transistor. A p-n junction may contact a top surface of the shared source/drain electrode.

Referring to FIG. 27, a contact-level dielectric layer 90 may be deposited over the thin-film transistors. Various contact via cavities may be formed through the contact-level dielectric layer 90 over conductive structures embodying the electrical nodes of the thin-film transistors. Various contact via structures may be formed in the various contact via cavities. The various contact via structures may comprise source/drain contact via structures (not illustrated) contacting a respective electrically conductive material portion 80 (which functions as a source/drain electrode) and gate contact via structures 95 contacting a respective gate electrode 55.

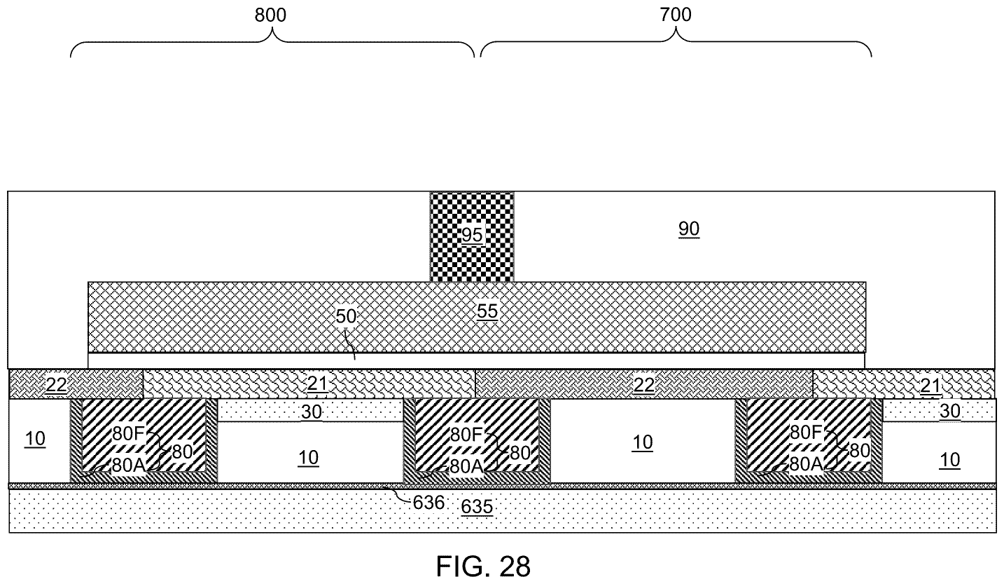

Referring to FIG. 28, a region of an alternative configuration of the second exemplary structure is illustrated according to an embodiment of the present disclosure. The alternative configuration illustrates embodiments in which a gate dielectric 50 and a gate electrode 55 are shared between a neighboring pair of an n-channel thin-film transistor and a p-channel thin-film transistor. This configuration embodies an inverter circuit, of which the functionality is well known in the art.

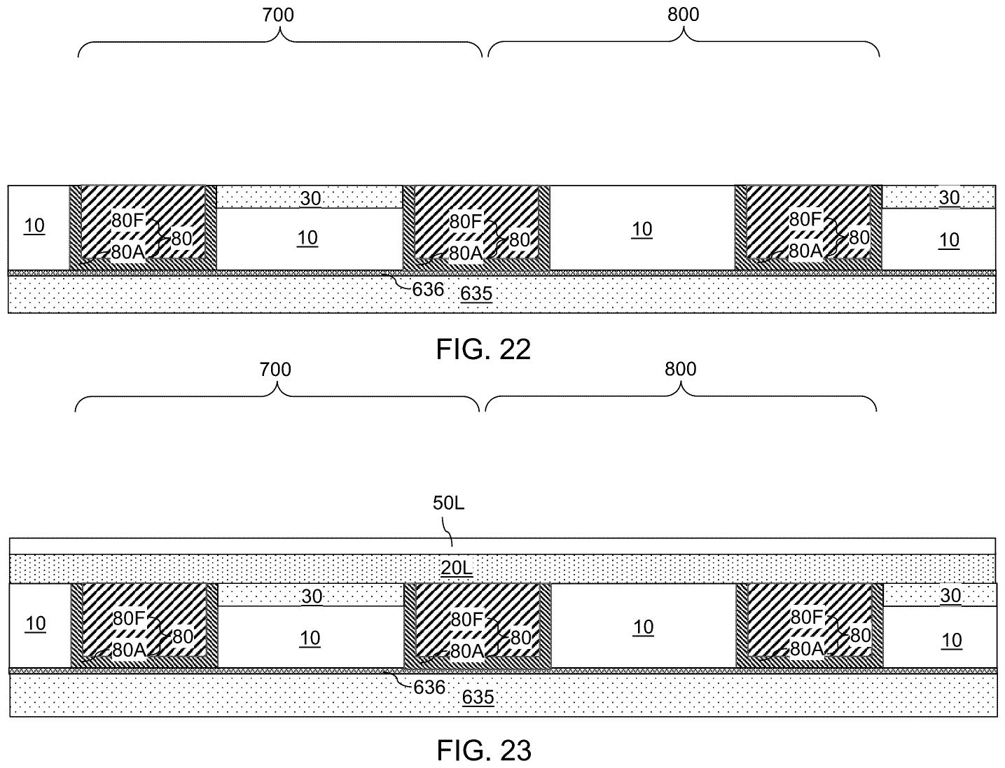

Referring collectively to FIGS. 1 and 18-28 and according to various embodiments of the present disclosure, a semiconductor structure is provided. The semiconductor structure comprises: a p-n junction located at an interface between a p-type metal oxide semiconductor layer 21 and an n-type metal oxide semiconductor layer 22; a hydrogen-containing dielectric material portion containing hydrogen atoms at a concentration greater than a first atomic concentration (which may be at least 100 parts per million as discussed above) and having a first-type insulating surface (such as a surface of a hydrogen-containing dielectric layer 10) that contacts the n-type metal oxide semiconductor layer 22; and a hydrogen-blocking dielectric material portion comprising a second-type insulating surface (such as a surface of a hydrogen-blocking dielectric layer 30) that contacts the p-type metal oxide semiconductor layer 21, the second-type insulating surface (such as a surface of a hydrogen-blocking dielectric layer 30) being a hydrogen-impermeable surface.

In one embodiment, the semiconductor structure comprises: a first electrically conductive material portion 80 in contact with a first portion of the p-type metal oxide semiconductor layer 21; a second electrically conductive material portion 80 in contact with a second portion of the p-type metal oxide semiconductor layer 21 and a first portion of the n-type metal oxide semiconductor layer 22; and a third electrically conductive material portion 80 in contact with a second portion of the n-type metal oxide semiconductor layer 22. In one embodiment, first electrically conductive material portion 80, the second electrically conductive material portion 80, and the third electrically conductive material portion 80 comprise three electrically conductive material portions 80 that are laterally spaced from one another along a horizontal direction that is parallel to a top surface of the substrate 8.

In one embodiment, the p-type metal oxide semiconductor layer 21 comprises a channel of a p-channel thin-film transistor; the n-type metal oxide semiconductor layer 22 comprises a channel of an n-channel thin-film transistor; and the first electrically conductive material portion 80, the second electrically conductive material portion 80, and the third electrically conductive material portion 80 comprise source/drain electrodes 80 of a combination of the n-type thin-film transistor and the n-channel thin-film transistor. In one embodiment, the semiconductor structure comprises at least one gate structure (50, 55) comprising a respective gate dielectric 50 and a respective gate electrode 55. Each of the p-type metal oxide semiconductor layer 21 and the n-type metal oxide semiconductor layer 22 is contacted by the at least one gate structure (50, 55).

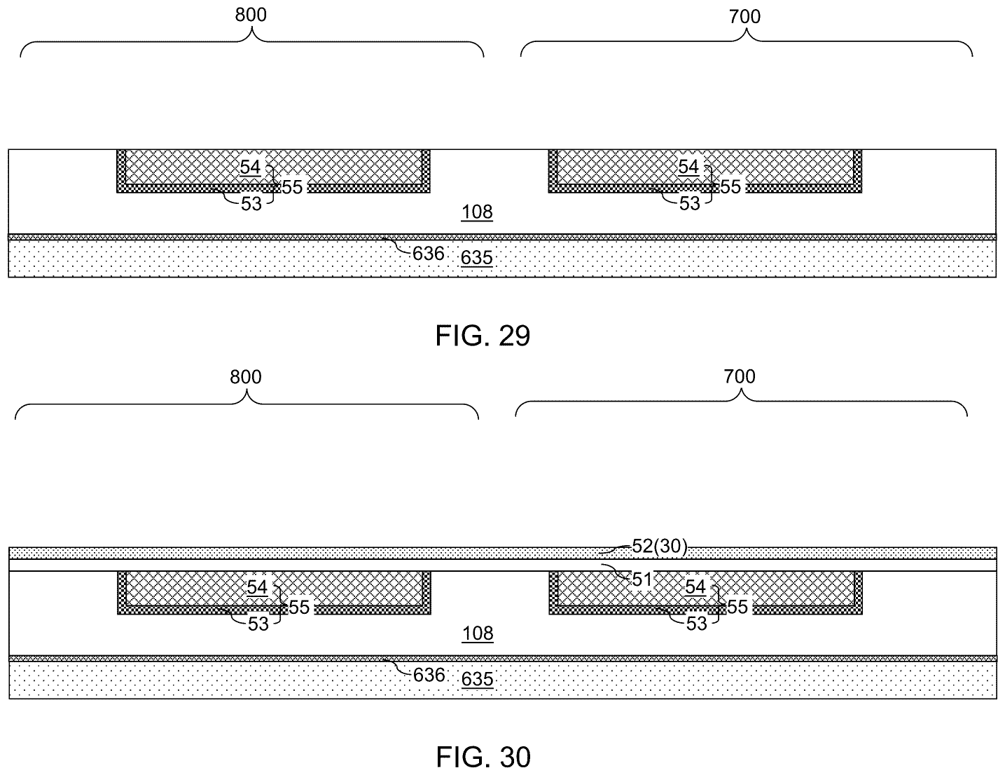

Referring to FIG. 29, a region of a third exemplary structure according to an embodiment of the present disclosure is illustrated. The third exemplary structure may be derived from the first exemplary structure by forming a dielectric matrix layer 108 over the etch stop dielectric layer 636. The dielectric matrix layer 108 may comprise any material that may be used for the hydrogen-containing dielectric layers 10 described with reference to the first exemplary structure. In one embodiment, the dielectric matrix layer 108 may comprise undoped silicate glass or a doped silicate glass. The thickness of the dielectric matrix layer 108 may be in a range from 100 nm to 400 nm, although lesser and greater thicknesses may also be used.

The third exemplary structure may comprise an n-channel transistor region 800 and a p-channel transistor region 700. A gate cavity may be formed in each of the n-channel transistor region 800 and the p-channel transistor region 700. The gate cavities may be subsequently filled with at least one gate electrode material to form gate electrodes 55. In one embodiment, the at least one gate electrode material may include a metallic barrier liner material (such as TiN, TaN, and/or WN) and a metallic fill material (such as Cu, W, Mo, Co, Ru, etc.). Excess portions of the at least one gate electrode material may be removed from above the horizontal plane including the top surface of the dielectric matrix layer 108 using a planarization process. The planarization process may comprise a chemical mechanical polishing process and/or a recess etch process. Each contiguous portion of the at least one gate electrode material that fills a respective gate cavity constitutes a gate electrode 55. In one embodiment, each gate electrode 55 may comprise a gate electrode liner 53 comprising a remaining portion of the metallic barrier liner material, and a gate electrode fill material portion 54 comprising a remaining portion of the metallic fill material. Top surfaces of the gate electrodes 55 may be formed within the horizontal plane including the top surface of the dielectric matrix layer 108. In one embodiment, a first gate electrode 55 and a second gate electrode 55 embedded within a dielectric matrix layer 108 over the substrate 8 in the n-channel transistor region 800 and in the p-channel transistor region 700, respectively.

Referring to FIG. 30, a first gate dielectric component layer 51 and a second gate dielectric component layer 52 may be deposited. The first gate dielectric component layer 51 may comprise silicon oxide, aluminum oxide, or a transition metal oxide, and may have a thickness in a range from 1 nm to 6 nm, such as from 1.5 nm to 3 nm. According to an embodiment of the present disclosure, the second gate dielectric component layer 52 comprises a hydrogen-blocking dielectric layer 30.

The hydrogen-blocking dielectric layer 30 in the third exemplary structure may have any material composition that may be used for the hydrogen-blocking dielectric layers 30 in the first exemplary structure. As such, the hydrogen-blocking dielectric layer 30 comprises a dielectric material that is substantially free of hydrogen atoms, or contains hydrogen atoms at a low atomic concentration such as an atomic concentration lower than a second atomic concentration (which may be 30 parts per million or less, and preferably 10 parts per million or less, and more preferably 3 parts per million or less). Further, the dielectric material of the hydrogen-blocking dielectric layer 30 is selected from dielectric materials that effectively block diffusion of hydrogen atoms therethrough. Examples of such dielectric materials include alkaline-earth oxides such as magnesium oxide, calcium oxide, and strontium oxide. In one embodiment, the hydrogen-blocking dielectric layer 30 comprises, and/or consists essentially of, at least one alkaline-earth oxide material. In one embodiment, the hydrogen-blocking dielectric layer 30 consists of magnesium oxide, calcium oxide, or an alloy or a stack thereof. The thickness of the hydrogen-blocking dielectric layer 30 may be in a range from 1 nm to 6 nm, such as from 1.5 nm to 3 nm, although lesser and greater thicknesses may also be used.

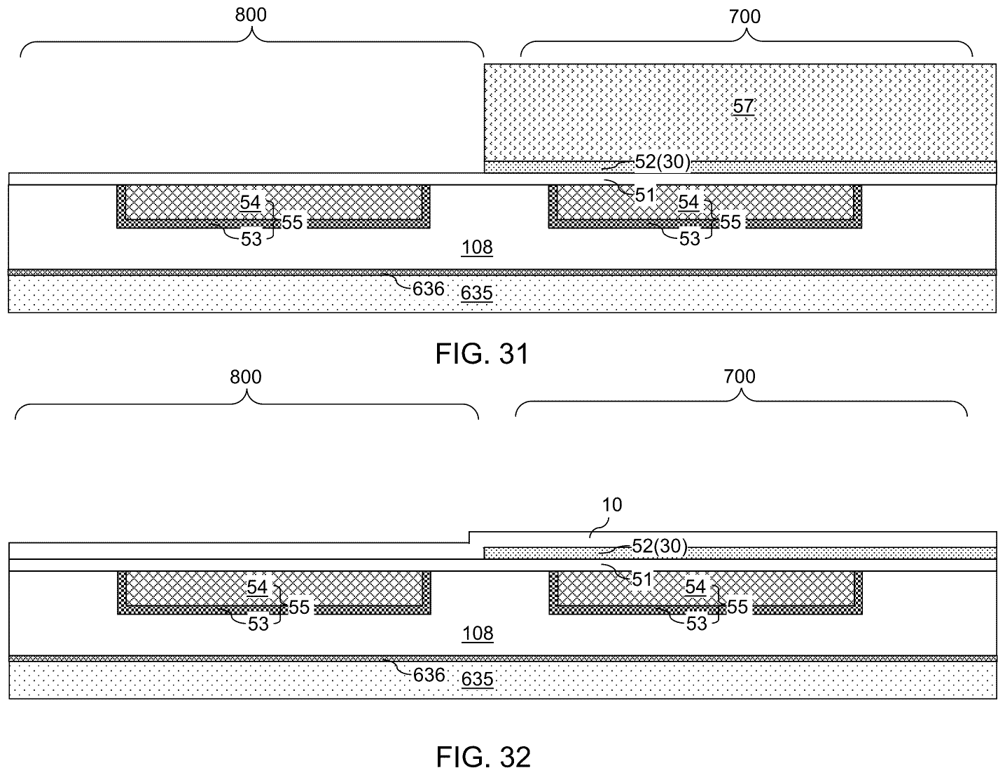

Referring to FIG. 31, a first photoresist layer 57 may be applied over the second gate dielectric component layer 52 (i.e., the hydrogen-blocking dielectric layer 30), and may be lithographically patterned to cover the p-channel transistor region 700 without covering the n-channel transistor region 800. A selective etch process may be performed to etch the material of the hydrogen-blocking dielectric layer 30 without etching the material of the first gate dielectric component layer 51. Unmasked portions of the second gate dielectric component layer 52 (i.e., the hydrogen-blocking dielectric layer 30) are removed by the selective etch process. The first photoresist layer 57 may be subsequently removed, for example, by ashing.

Referring to FIG. 32, a hydrogen-containing dielectric layer 10 may be deposited as a third gate dielectric component layer. The hydrogen-containing dielectric layer 10 may comprise any material that is suitable as a gate dielectric material selected from the hydrogen-containing dielectric materials of the hydrogen-containing dielectric layer 10 as discussed with reference to the first exemplary structure. For example, the hydrogen-containing dielectric layer 10 in the third exemplary structure may comprise silicon oxide, or a dielectric metal oxide material deposited in a hydrogen-containing ambient or using a hydrogen-containing precursor gas. The thickness of the hydrogen-containing dielectric layer 10 may be in a range from 1 nm to 6 nm, such as from 1.5 nm to 3 nm, although lesser and greater thicknesses may also be used.

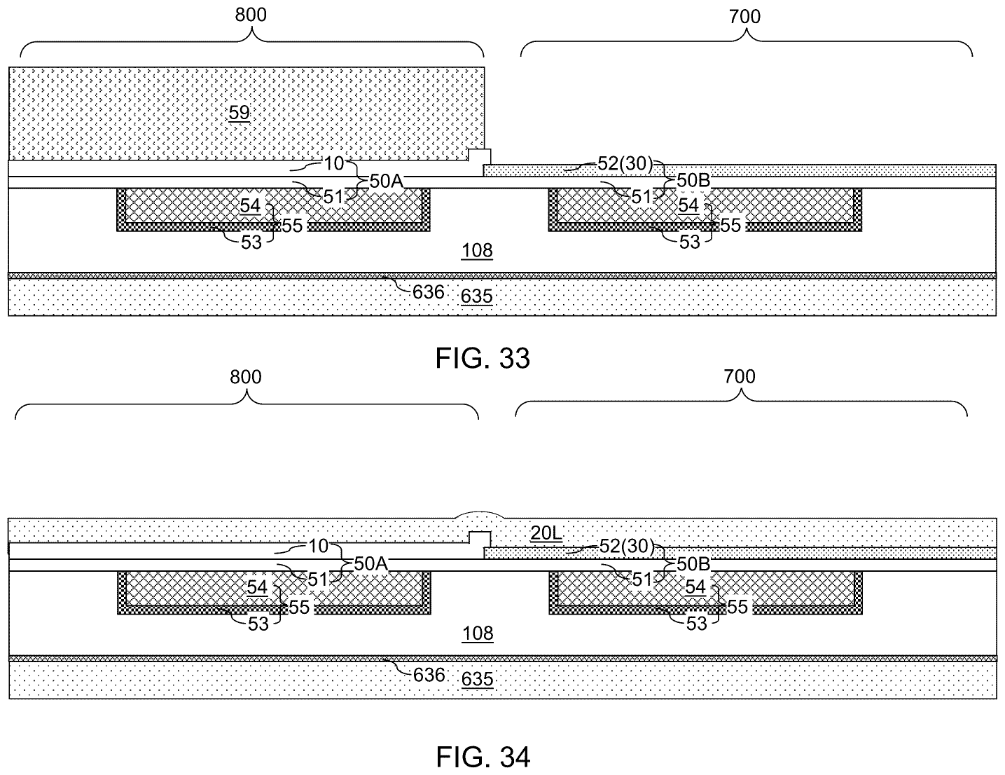

Referring to FIG. 33, a second photoresist layer 59 may be applied over the hydrogen-containing dielectric layer 10, and may be lithographically patterned to cover the n-channel transistor region 800 without covering the p-channel transistor region 700. A selective etch process may be performed to etch the material of the hydrogen-containing dielectric layer 10 without etching the material of the hydrogen-blocking dielectric layer 30. Unmasked portions of the hydrogen-containing dielectric layer 10 are removed by the selective etch process. The second photoresist layer 59 may be subsequently removed, for example, by ashing.

Upon removal of the second photoresist layer 59, a combination of a first-type insulating surface (such as a surface of a hydrogen-containing dielectric layer 10) and a second-type insulating surface (such as a surface of a hydrogen-blocking dielectric layer 30) is formed over a substrate 8. The first-type insulating surface (such as a surface of a hydrogen-containing dielectric layer 10) is a surface of a hydrogen-containing dielectric material containing hydrogen atoms at a concentration greater than a first atomic concentration (which may be at least 100 parts per million as discussed above), and the second-type insulating surface (such as a surface of a hydrogen-blocking dielectric layer 30) is a hydrogen-impermeable surface of a hydrogen-blocking dielectric material.

The combination of the portion of the first gate dielectric component layer 51 in the n-channel transistor region 800 and the hydrogen-containing dielectric layer 10 comprises a first-type gate dielectric 50A. The first-type gate dielectric 50A is formed over a first gate electrode 55 located in the n-channel transistor region 800. The combination of the portion of the first gate dielectric component layer 51 in the p-channel transistor region 700 and the hydrogen-blocking dielectric layer 30 comprises a second-type gate dielectric 50B. The second-type gate dielectric 50B is formed over a second gate electrode 55 located in the p-channel transistor region 700. In one embodiment, the first-type insulating surface (such as a surface of a hydrogen-containing dielectric layer 10) is a top surface of the first-type gate dielectric 50A, and the second-type insulating surface (such as a surface of a hydrogen-blocking dielectric layer 30) is a top surface of the second-type gate dielectric 50B.

Referring to FIG. 34, the processing steps described with reference to FIGS. 11A and 11B may be performed to deposit an amorphous metal oxide layer 20L. The material composition and the thickness range of the amorphous metal oxide layer 20L in the third exemplary structure may be the same as the material composition and the thickness range of the amorphous metal oxide layer 20L in the first exemplary structure. The amorphous metal oxide layer 20L in the third exemplary structure does not require a conformal deposition process because the amorphous metal oxide layer 20L is formed on planar surfaces. The amorphous metal oxide layer 20L is deposited on the first-type insulating surface (such as a surface of a hydrogen-containing dielectric layer 10) and the second-type insulating surface (such as a surface of a hydrogen-blocking dielectric layer 30). In some embodiments, a top surface of a portion of the hydrogen-containing dielectric layer 10 that overlies an edge portion of the hydrogen-blocking dielectric layer 30 may have a vertically-protruding bump segment. An overlying portion of the top surface of the amorphous metal oxide layer 20L may have a bump segment that protrude above a horizontally-extending segment of the top surface of the amorphous metal oxide layer 20L.

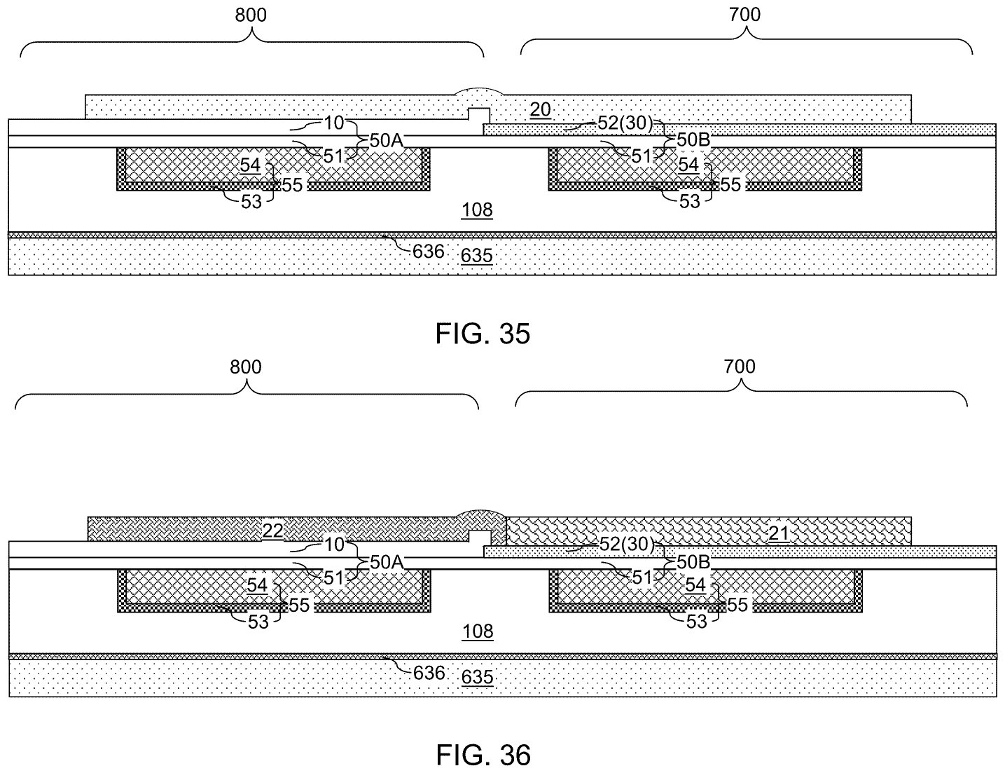

Referring to FIG. 35, the amorphous metal oxide layer 20L may be patterned to provide electrical isolation from thin-film transistors to be subsequently formed as necessary. A patterned amorphous metal oxide layer 20 may be formed.

Referring to FIG. 36, an anneal process described with reference to FIGS. 13A and 13B may be performed to convert each patterned amorphous metal oxide layer 20 into a respective set of at least one crystalized metal oxide semiconductor layer. Since the surfaces of the patterned amorphous metal oxide layer 20 are exposed to the ambient during the anneal process, and are prone to oxygen ingress during the anneal process, an oxygen-free ambient may be preferred for the anneal process in order to avoid excess ingress of oxygen into the patterned amorphous metal oxide layer 20 during the anneal process. In one embodiment, a patterned amorphous metal oxide layer 20 may be converted into a combination including at least one n-type metal oxide semiconductor layer 22 and at least one p-type metal oxide semiconductor layer 21.

Upon performing the anneal process at an elevated temperature, a first portion of the patterned amorphous metal oxide layer 20 in contact with a first-type insulating surface (such as a surface of a hydrogen-containing dielectric layer 10) is converted into an n-type metal oxide semiconductor layer 22 due to oxygen loss to hydrogen atoms in the hydrogen-containing dielectric material in the hydrogen-containing dielectric layer 10 during the anneal process. A second portion of the patterned amorphous metal oxide layer 20 in contact with a second-type insulating surface (such as a surface of a hydrogen-blocking dielectric layer 30) is converted into a p-type metal oxide semiconductor layer 21 during the anneal process. In one embodiment, a p-type metal oxide semiconductor layer 21 comprises a channel of a p-channel thin-film transistor, and an n-type metal oxide semiconductor layer 22 comprises a channel of an n-channel thin-film transistor.

Upon completion of the anneal process described in FIGS. 13A and 13B, portions of the amorphous metal oxide layer 20L undergo a phase transition to a crystalline state. The conductivity type of the newly crystallized portions of the metal oxide material is determined by whether each metal oxide material portion is in contact with a hydrogen-containing dielectric layer 10 or a hydrogen-blocking dielectric layer 30. Each portion of the amorphous metal oxide layer 20L in contact with a hydrogen-containing dielectric layer 10 is transformed into an n-type metal oxide semiconductor layer 22 due to the loss of oxygen atoms and the accumulation of free electrons, while each portion of the amorphous metal oxide layer 20L in contact with a hydrogen-blocking dielectric layer 30 is transformed into a p-type metal oxide semiconductor layer 21. Specifically, each crystallized portion of the amorphous metal oxide layer 20L in contact with a hydrogen-containing dielectric layer 10 is converted into an n-type metal oxide semiconductor layer 22 due to loss of oxygen atoms and accumulation of free electrons. Each crystallized portion of the amorphous metal oxide layer 20L in contact with a hydrogen-blocking dielectric layer 30 is generally converted into a p-type metal oxide semiconductor layer 21 except at peripheries that are proximal to a hydrogen-containing dielectric layer 10. A p-n junction between a p-type metal oxide semiconductor layer 21 and an n-type metal oxide semiconductor layer 22 may be formed at, or in proximity to, an interface between a hydrogen-containing dielectric layer 10 and a hydrogen-blocking dielectric layer 30.

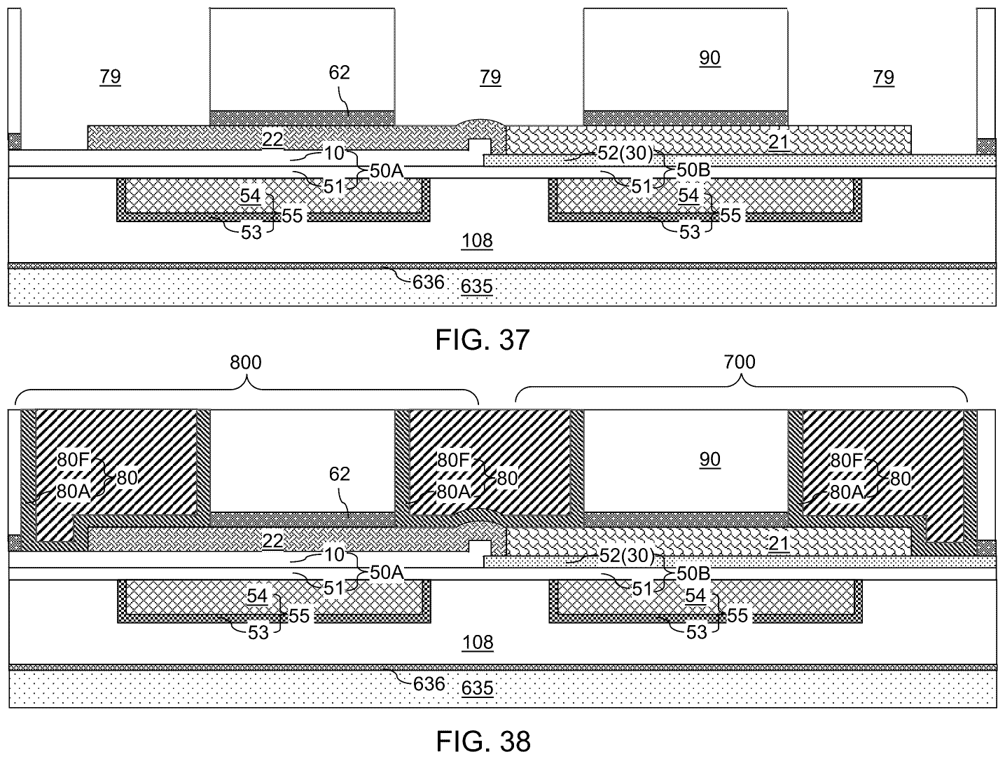

Referring to FIG. 37, an optional passivation dielectric layer 62 may be deposited over, and around, the p-type metal oxide semiconductor layers 21 and the n-type metal oxide semiconductor layers 22 and above physically exposed portion of the top surface of the hydrogen-containing dielectric layer 10 and the hydrogen-blocking dielectric layer 30. The passivation dielectric layer 62, if used, comprises a dielectric material that may function as a diffusion barrier material. For example, the passivation dielectric layer 62 may comprise silicon nitride, silicon carbide nitride, or silicon oxide nitride.

A dielectric material such as undoped silicate glass or a doped silicate glass may be deposited over the passivation dielectric layer 62. A planarization process, such as a chemical mechanical planarization process, may be performed to planarized the top surface of the deposited dielectric material. The remaining portion of the deposited dielectric material is herein referred to as a contact-level dielectric layer 90.

A photoresist layer (not shown) may be applied over the contact-level dielectric layer 90, and may be lithographically patterned to form discrete openings therein. The pattern of the discrete openings in the photoresist layer may be transferred through the contact-level dielectric layer 90 and the passivation dielectric layer 62 by an anisotropic etch process to form source/drain cavities 79. A pair of source/drain cavities 79 may be formed above end portions of each semiconductor channel that overlies a respective one of the gate electrodes 55. The photoresist layer may be subsequently removed, for example, by ashing.

Referring to FIG. 38, at least one conductive material may be deposited in the source/drain cavities 79 and over the contact-level dielectric layer 90. The at least one conductive material may include a metallic barrier liner layer including a metallic barrier liner material and a metallic fill material layer including a metallic fill material. The metallic barrier liner material may include a conductive metallic nitride or a conductive metallic carbide such as TiN, TaN, WN, TiC, TaC, and/or WC. The metallic fill material may include W, Cu, Al, Co, Ru, Mo, Ta, Ti, alloys thereof, and/or combinations thereof. Excess portions of the at least one conductive material may be removed from above the horizontal plane including the top surface of the contact-level dielectric layer by a planarization process, which may use a chemical mechanical polishing (CMP) process and/or a recess etch process. Each remaining portion of the at least one conductive material filling a source/drain cavity 79 constitutes a source/drain electrode 80, which is an electrically conductive material portion 80. In one embodiment, each source/drain electrode 80 may include a metallic barrier liner 80A that is a remaining portion of the metallic barrier liner material, and a metal fill portion 80F that is a remaining portion of the metallic fill material. Generally, the source/drain electrodes 80 may be formed through the contact-level dielectric layer 90 on a respective portion of the p-type metal oxide semiconductor layer 21 and the n-type metal oxide semiconductor layer 22.

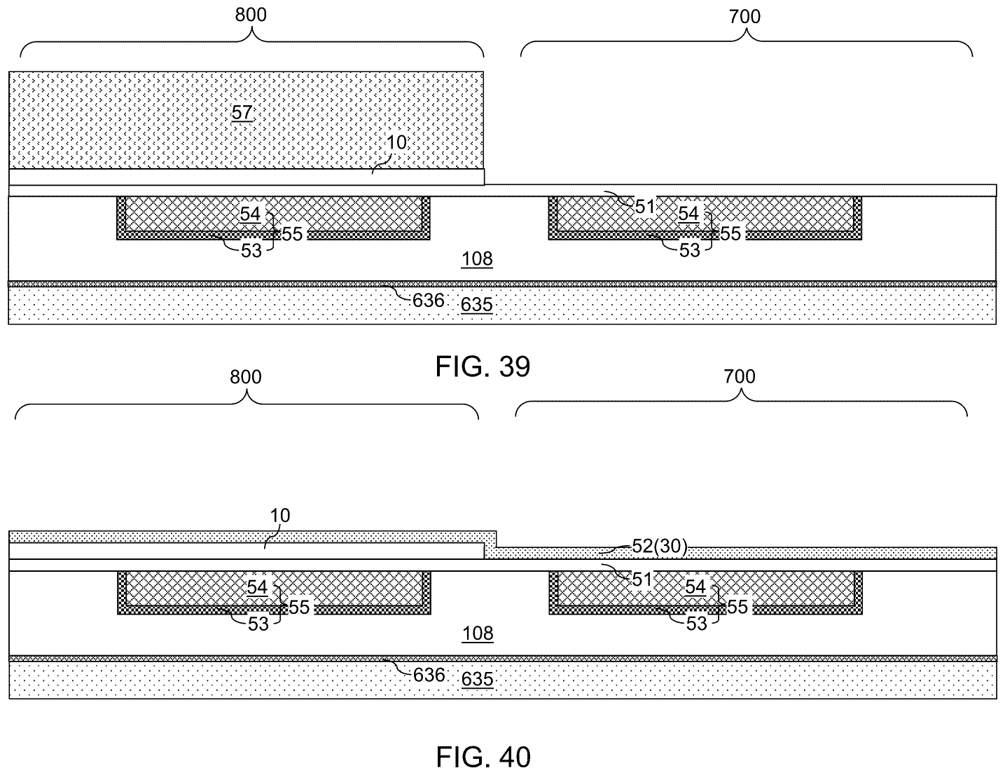

Referring to FIG. 39, a region of a fourth exemplary structure according to an embodiment of the present disclosure is illustrated. The fourth exemplary structure may be derived from the third exemplary structure illustrated in FIG. 29 by depositing a first gate dielectric component layer 51 and a hydrogen-containing dielectric layer 10. The hydrogen-containing dielectric layer 10 may be deposited as a gate dielectric component layer. The hydrogen-containing dielectric layer 10 may comprise any material that is suitable as a gate dielectric material selected from the hydrogen-containing dielectric materials of the hydrogen-containing dielectric layer 10 as discussed with reference to the first exemplary structure. For example, the hydrogen-containing dielectric layer 10 in the fourth exemplary structure may comprise silicon oxide, or a dielectric metal oxide material deposited in a hydrogen-containing ambient or using a hydrogen-containing precursor gas. The thickness of the hydrogen-containing dielectric layer 10 may be in a range from 1 nm to 6 nm, such as from 1.5 nm to 3 nm, although lesser and greater thicknesses may also be used.

A first photoresist layer 57 may be applied over the hydrogen-containing dielectric layer 10, and may be lithographically patterned to cover the n-channel transistor region 800 without covering the p-channel transistor region 700. A selective etch process may be performed to etch the material of the hydrogen-containing dielectric layer 10 without etching the material of the first gate dielectric component layer 51. Unmasked portions of the second gate dielectric component layer 52 (i.e., the hydrogen-blocking dielectric layer 30) are removed by the selective etch process. The first photoresist layer 57 may be subsequently removed, for example, by ashing.

Referring to FIG. 40, a second gate dielectric component layer 52 may be deposited. According to an embodiment of the present disclosure, the second gate dielectric component layer 52 comprises a hydrogen-blocking dielectric layer 30. The hydrogen-blocking dielectric layer 30 in the fourth exemplary structure may have any material composition that may be used for the hydrogen-blocking dielectric layers 30 in the first exemplary structure. As such, the hydrogen-blocking dielectric layer 30 comprises a dielectric material that is substantially free of hydrogen atoms, or contains hydrogen atoms at a low atomic concentration such as an atomic concentration lower than a second atomic concentration (which may be 30 parts per million or less, and preferably 10 parts per million or less, and more preferably 3 parts per million or less). Further, the dielectric material of the hydrogen-blocking dielectric layer 30 is selected from dielectric materials that effectively block diffusion of hydrogen atoms therethrough. Examples of such dielectric materials include alkaline-earth oxides such as magnesium oxide, calcium oxide, and strontium oxide. In one embodiment, the hydrogen-blocking dielectric layer 30 comprises, and/or consists essentially of, at least one alkaline-earth oxide material. In one embodiment, the hydrogen-blocking dielectric layer 30 consists of magnesium oxide, calcium oxide, or an alloy or a stack thereof. The thickness of the hydrogen-blocking dielectric layer 30 may be in a range from 1 nm to 6 nm, such as from 1.5 nm to 3 nm, although lesser and greater thicknesses may also be used.

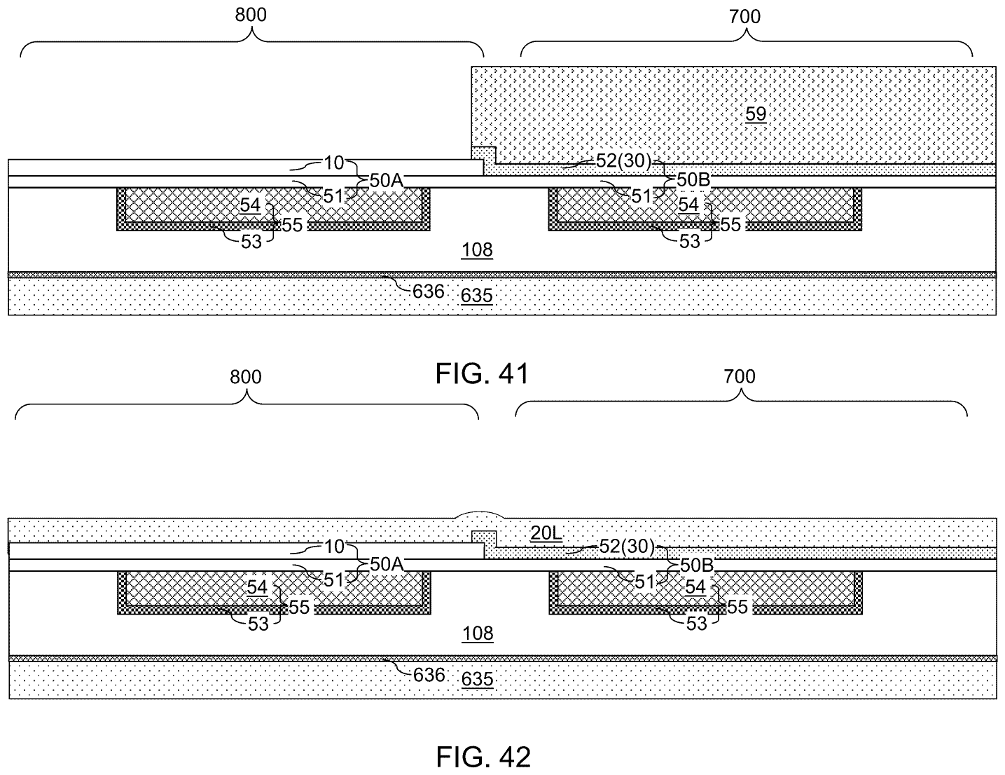

Referring to FIG. 41, a second photoresist layer 59 may be applied over the hydrogen-blocking dielectric layer 30, and may be lithographically patterned to cover the p-channel transistor region 700 without covering the n-channel transistor region 800. A selective etch process may be performed to etch the material of the hydrogen-blocking dielectric layer 30 without etching the material of the hydrogen-containing dielectric layer 10. Unmasked portions of the hydrogen-blocking dielectric layer 30 are removed by the selective etch process. The second photoresist layer 59 may be subsequently removed, for example, by ashing.

Upon removal of the second photoresist layer 59, a combination of a first-type insulating surface (such as a surface of a hydrogen-containing dielectric layer 10) and a second-type insulating surface (such as a surface of a hydrogen-blocking dielectric layer 30) is formed over a substrate 8. The first-type insulating surface (such as a surface of a hydrogen-containing dielectric layer 10) is a surface of a hydrogen-containing dielectric material containing hydrogen atoms at a concentration greater than a first atomic concentration (which may be at least 100 parts per million as discussed above), and the second-type insulating surface (such as a surface of a hydrogen-blocking dielectric layer 30) is a hydrogen-impermeable surface of a hydrogen-blocking dielectric material.

The combination of the portion of the first gate dielectric component layer 51 in the n-channel transistor region 800 and the hydrogen-containing dielectric layer 10 comprises a first-type gate dielectric 50A. The first-type gate dielectric 50A is formed over a first gate electrode 55 located in the n-channel transistor region 800. The combination of the portion of the first gate dielectric component layer 51 in the p-channel transistor region 700 and the hydrogen-blocking dielectric layer 30 comprises a second-type gate dielectric 50B. The second-type gate dielectric 50B is formed over a second gate electrode 55 located in the p-channel transistor region 700. In one embodiment, the first-type insulating surface (such as a surface of a hydrogen-containing dielectric layer 10) is a top surface of the first-type gate dielectric 50A, and the second-type insulating surface (such as a surface of a hydrogen-blocking dielectric layer 30) is a top surface of the second-type gate dielectric 50B.

Referring to FIG. 42, the processing steps described with reference to FIGS. 11A and 11B may be performed to deposit an amorphous metal oxide layer 20L. The material composition and the thickness range of the amorphous metal oxide layer 20L in the fourth exemplary structure may be the same as the material composition and the thickness range of the amorphous metal oxide layer 20L in the first exemplary structure. The amorphous metal oxide layer 20L in the fourth exemplary structure does not require a conformal deposition process because the amorphous metal oxide layer 20L is formed on planar surfaces. The amorphous metal oxide layer 20L is deposited on the first-type insulating surface (such as a surface of a hydrogen-containing dielectric layer 10) and the second-type insulating surface (such as a surface of a hydrogen-blocking dielectric layer 30). In some embodiments, a top surface of a portion of the hydrogen-blocking dielectric layer 30 that overlies an edge portion of the hydrogen-containing dielectric layer 10 may have a vertically-protruding bump segment. An overlying portion of the top surface of the amorphous metal oxide layer 20L may have a bump segment that protrude above a horizontally-extending segment of the top surface of the amorphous metal oxide layer 20L.

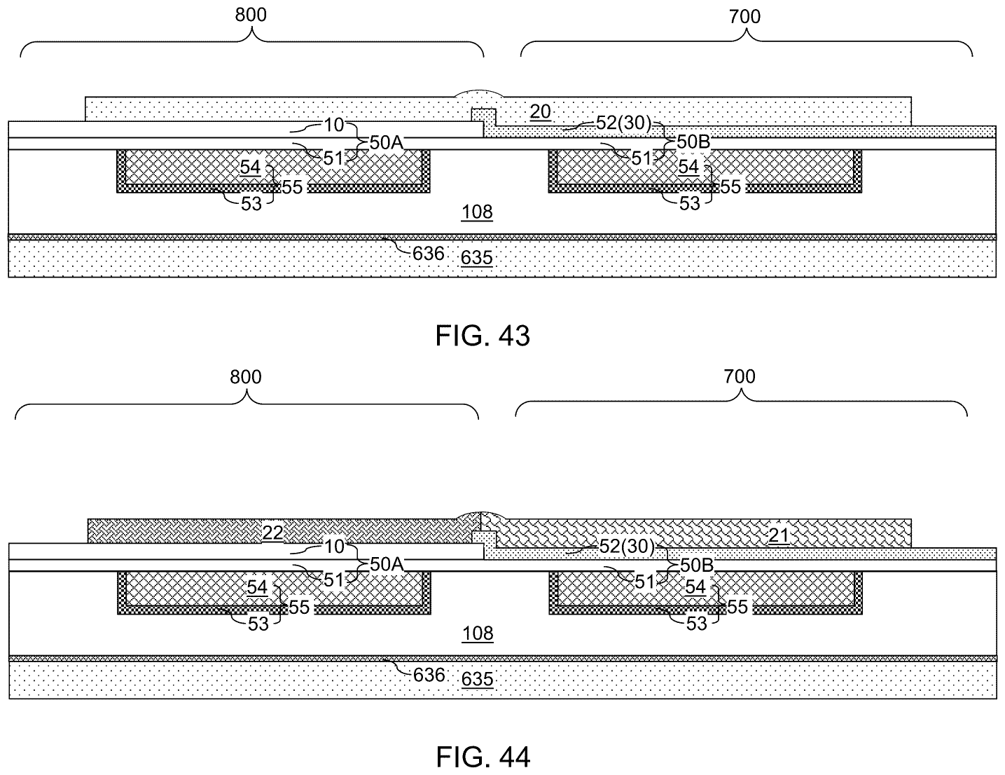

Referring to FIG. 43, the amorphous metal oxide layer 20L may be patterned to provide electrical isolation from thin-film transistors to be subsequently formed as necessary. A patterned amorphous metal oxide layer 20 may be formed.

Referring to FIG. 44, an anneal process described with reference to FIGS. 13A and 13B may be performed to convert each patterned amorphous metal oxide layer 20 into a respective set of at least one crystalized metal oxide semiconductor layer. Since the surfaces of the patterned amorphous metal oxide layer 20 are exposed to the ambient during the anneal process, and are prone to oxygen ingress during the anneal process, an oxygen-free ambient may be preferred for the anneal process in order to avoid excess ingress of oxygen into the patterned amorphous metal oxide layer 20 during the anneal process. In one embodiment, a patterned amorphous metal oxide layer 20 may be converted into a combination including at least one n-type metal oxide semiconductor layer 22 and at least one p-type metal oxide semiconductor layer 21.

Upon performing the anneal process at an elevated temperature, a first portion of the patterned amorphous metal oxide layer 20 in contact with a first-type insulating surface (such as a surface of a hydrogen-containing dielectric layer 10) is converted into an n-type metal oxide semiconductor layer 22 due to oxygen loss to hydrogen atoms in the hydrogen-containing dielectric material in the hydrogen-containing dielectric layer 10 during the anneal process. A second portion of the patterned amorphous metal oxide layer 20 in contact with a second-type insulating surface (such as a surface of a hydrogen-blocking dielectric layer 30) is converted into a p-type metal oxide semiconductor layer 21 during the anneal process. In one embodiment, a p-type metal oxide semiconductor layer 21 comprises a channel of a p-channel thin-film transistor, and an n-type metal oxide semiconductor layer 22 comprises a channel of an n-channel thin-film transistor.

As discussed above, the conductivity type of each crystallized metal oxide portions derived from the amorphous metal oxide layer 20L is determined by presence or absence of a contact with a hydrogen-blocking dielectric layer 30 at, or around, the respective crystallized metal oxide portion. Each portion of the amorphous metal oxide layer 20L in contact with the hydrogen-containing dielectric layer 10 is crystallized into an n-type metal oxide semiconductor layer 22 due to loss of oxygen atoms and accumulation of free electrons. Each portion of the amorphous metal oxide layer 20L in contact with a hydrogen-blocking dielectric layer 30 is generally crystallized into a p-type metal oxide semiconductor layer 21 except at peripheries that are proximal to a hydrogen-containing dielectric layer 10. A p-n junction between a p-type metal oxide semiconductor layer 21 and an n-type metal oxide semiconductor layer 22 may be formed at, or in proximity to, an interface between a hydrogen-containing dielectric layer 10 and a hydrogen-blocking dielectric layer 30.

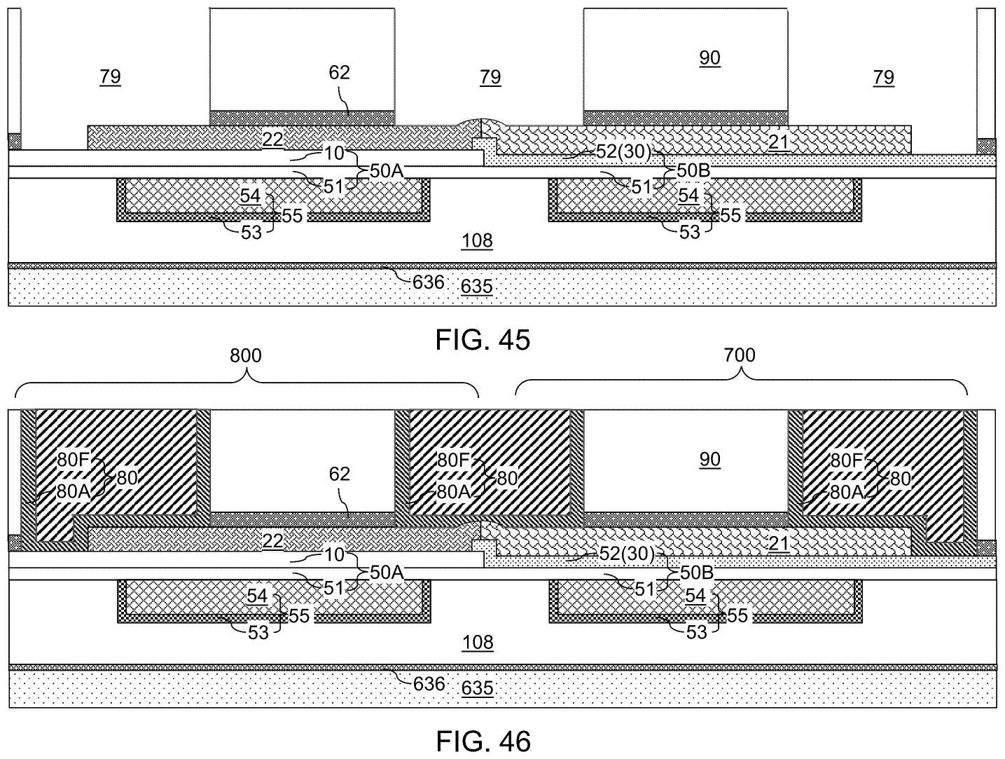

Referring to FIG. 45, an optional passivation dielectric layer 62 may be deposited over, and around, the p-type metal oxide semiconductor layers 21 and the n-type metal oxide semiconductor layers 22 and above physically exposed portion of the top surface of the hydrogen-containing dielectric layer 10 and the hydrogen-blocking dielectric layer 30. The passivation dielectric layer 62, if used, comprises a dielectric material that may function as a diffusion barrier material. For example, the passivation dielectric layer 62 may comprise silicon nitride, silicon carbide nitride, or silicon oxide nitride.

A dielectric material such as undoped silicate glass or a doped silicate glass may be deposited over the passivation dielectric layer 62. A planarization process, such as a chemical mechanical planarization process, may be performed to planarized the top surface of the deposited dielectric material. The remaining portion of the deposited dielectric material is herein referred to as a contact-level dielectric layer 90.

A photoresist layer (not shown) may be applied over the contact-level dielectric layer 90, and may be lithographically patterned to form discrete openings therein. The pattern of the discrete openings in the photoresist layer may be transferred through the contact-level dielectric layer 90 and the passivation dielectric layer 62 by an anisotropic etch process to form source/drain cavities 79. A pair of source/drain cavities 79 may be formed above end portions of each semiconductor channel that overlies a respective one of the gate electrodes 55. The photoresist layer may be subsequently removed, for example, by ashing.

Referring to FIG. 46, at least one conductive material may be deposited in the source/drain cavities 79 and over the contact-level dielectric layer 90. The at least one conductive material may include a metallic barrier liner layer including a metallic barrier liner material and a metallic fill material layer including a metallic fill material. The metallic barrier liner material may include a conductive metallic nitride or a conductive metallic carbide such as TiN, TaN, WN, TiC, TaC, and/or WC. The metallic fill material may include W, Cu, Al, Co, Ru, Mo, Ta, Ti, alloys thereof, and/or combinations thereof. Excess portions of the at least one conductive material may be removed from above the horizontal plane including the top surface of the contact-level dielectric layer by a planarization process, which may use a chemical mechanical polishing (CMP) process and/or a recess etch process. Each remaining portion of the at least one conductive material filling a source/drain cavity 79 constitutes a source/drain electrode 80, which is an electrically conductive material portion 80. In one embodiment, each source/drain electrode 80 may include a metallic barrier liner 80A that is a remaining portion of the metallic barrier liner material, and a metal fill portion 80F that is a remaining portion of the metallic fill material. Generally, the source/drain electrodes 80 may be formed through the contact-level dielectric layer 90 on a respective portion of the p-type metal oxide semiconductor layer 21 and the n-type metal oxide semiconductor layer 22.

Referring to FIGS. 1 and 29-46 and according to various embodiments of the present disclosure, a semiconductor structure is provided. The semiconductor structure comprises: a p-n junction located at an interface between a p-type metal oxide semiconductor layer 21 and an n-type metal oxide semiconductor layer 22; a hydrogen-containing dielectric material portion containing hydrogen atoms at a concentration greater than a first atomic concentration (which may be at least 100 parts per million as discussed above) and having a first-type insulating surface (such as a surface of a hydrogen-containing dielectric layer 10) that contacts the n-type metal oxide semiconductor layer 22; and a hydrogen-blocking dielectric material portion comprising a second-type insulating surface (such as a surface of a hydrogen-blocking dielectric layer 30) that contacts the p-type metal oxide semiconductor layer 21, the second-type insulating surface (such as a surface of a hydrogen-blocking dielectric layer 30) being a hydrogen-impermeable surface.

In one embodiment, the semiconductor structure comprises: a first electrically conductive material portion 80 in contact with a first portion of the p-type metal oxide semiconductor layer 21; a second electrically conductive material portion 80 in contact with a second portion of the p-type metal oxide semiconductor layer 21 and a first portion of the n-type metal oxide semiconductor layer 22; and a third electrically conductive material portion 80 in contact with a second portion of the n-type metal oxide semiconductor layer 22.

In one embodiment, the first electrically conductive material portion 80, the second electrically conductive material portion 80, and the third electrically conductive material portion 80 comprise three electrically conductive material portions 80 that are laterally spaced from one another along a horizontal direction that is parallel to a top surface of the substrate 8. In one embodiment, the p-type metal oxide semiconductor layer 21 comprises a channel of a p-channel thin-film transistor; the n-type metal oxide semiconductor layer 22 comprises a channel of an n-channel thin-film transistor; and the first electrically conductive material portion 80, the second electrically conductive material portion 80, and the third electrically conductive material portion 80 comprise source/drain electrodes 80 of a combination of the p-channel thin-film transistor and the n-channel thin-film transistor. In one embodiment, the semiconductor structure comprises at least one gate structure (50, 55) comprising a respective gate dielectric 50 and a respective gate electrode, wherein each of the p-type metal oxide semiconductor layer 21 and the n-type metal oxide semiconductor layer 22 is contacted by the at least one gate structure (50, 55).

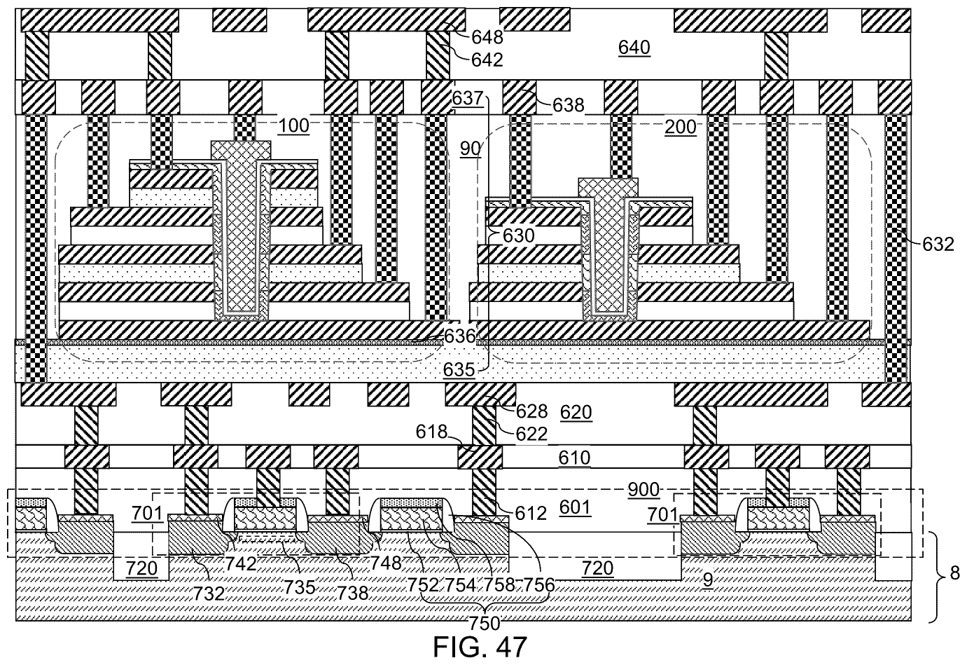

Referring to FIG. 47, the first exemplary structure (discussed with reference to FIGS. 1-17B) is illustrated after performing additional processing steps. The first exemplary structure illustrated in FIG. 47 may be derived from the first exemplary structure illustrated in FIGS. 16A, 16B, 17A, and 17B by forming second metal via structures 632 through a stack of the insulating material layer 635, the etch stop dielectric layer 636, and the contact-level dielectric layer 90. The second metal via structures 632 may be formed on top surfaces of the second metal line structures 628.

A third line-level dielectric layer 637 may be formed above the insulating layer 40. Third metal line structures 638 may be formed in the third line-level dielectric layer 637 on the top surfaces of the various contact via structures (95, 98) and the second metal via structures 632. The combination of the insulating material layer 635, the etch stop dielectric layer 636, the contact-level dielectric layer 90, and the third line-level dielectric layer 637 constitutes a third interconnect-level dielectric layer 630. While only the first device region 100 and the second device region 200 are expressly shown in FIG. 47, each of the various device regions (100, 200, 300, 400, 500, 600) may be located within the third interconnect-level dielectric layer 630.

A fourth interconnect-level dielectric layer 640 embedding third metal via structures 642 and fourth metal lines 648 may be formed above the third interconnect-level dielectric layer 630. Additional metal interconnect structures (not shown) embedded in additional dielectric material layers (not shown) may be subsequently formed over the fourth interconnect-level dielectric layer 640 as needed.

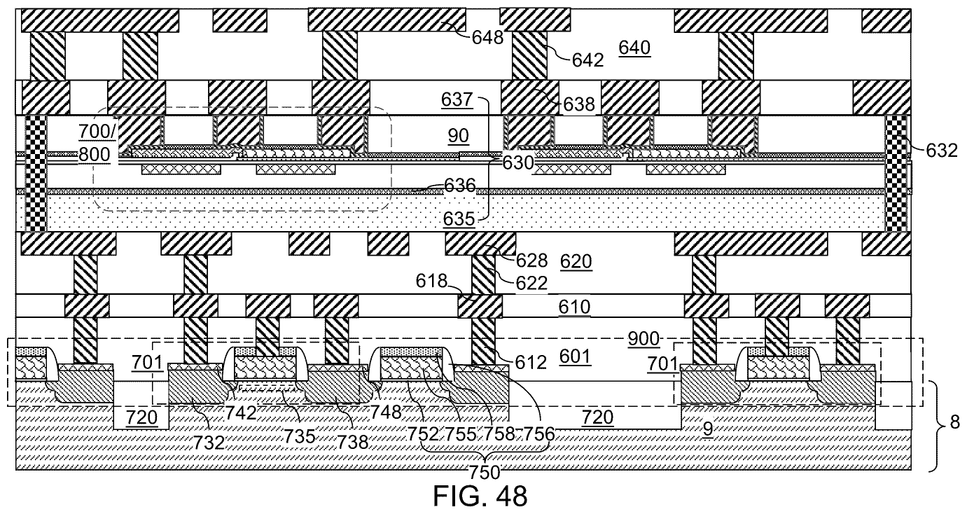

FIG. 48 schematically represents the second exemplary structure, the third exemplary structure, or the fourth exemplary structure after performing additional processing steps. The second exemplary structure, the third exemplary structure, or the fourth exemplary structure illustrated in FIG. 48 may be derived from the second exemplary structures illustrated in FIGS. 27 and 28, the third exemplary structure illustrated in FIG. 38, or the fourth exemplary structure illustrated in FIG. 46 by forming second metal via structures 632 through a stack of the insulating material layer 635, the etch stop dielectric layer 636, and all other dielectric material layers that are formed above the etch stop dielectric layer 636 as shown in FIG. 27, 28, 38, or 46. The second metal via structures 632 may be formed on top surfaces of the second metal line structures 628.

A third line-level dielectric layer 637 may be formed above the contact-level dielectric layer 90. Third metal line structures 638 may be formed in the third line-level dielectric layer 637 on the top surfaces of the various contact via structures (in the embodiment of the second exemplary structure) or on the top surfaces of the source/drain electrodes 80, and on the top surfaces of the second metal via structures 632. The combination of the insulating material layer 635, the etch stop dielectric layer 636, the third line-level dielectric layer 637, and all dielectric material layers between the etch stop dielectric layer 636 and the third line-level dielectric layer 637 constitutes a third interconnect-level dielectric layer 630. P-channel transistor regions 700 and n-channel transistor regions 800 may be located within the third interconnect-level dielectric layer 630.

A fourth interconnect-level dielectric layer 640 embedding third metal via structures 642 and fourth metal lines 648 may be formed above the third interconnect-level dielectric layer 630. Additional metal interconnect structures (not shown) embedded in additional dielectric material layers (not shown) may be subsequently formed over the fourth interconnect-level dielectric layer 640 as needed.

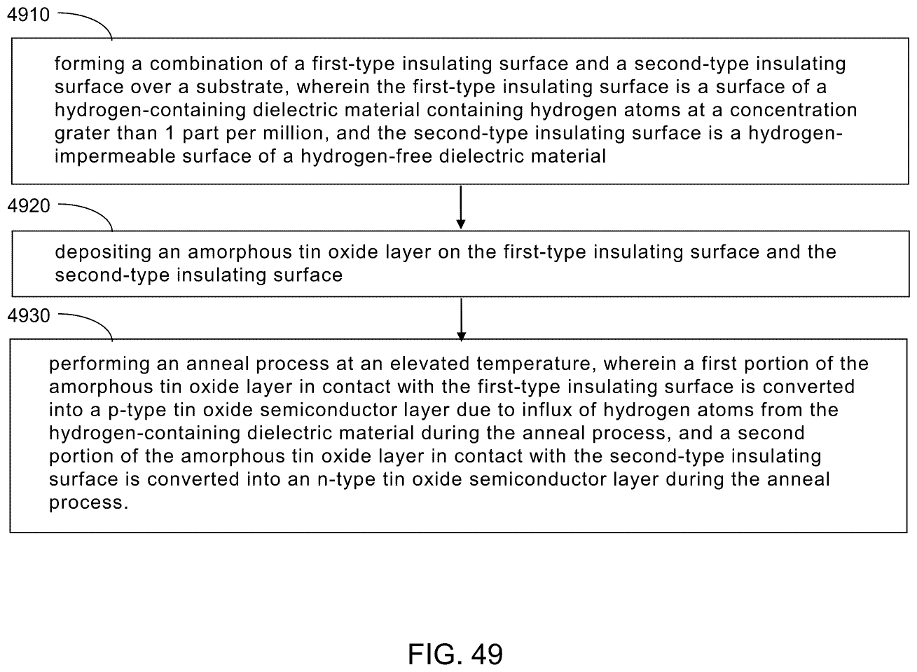

FIG. 49 is a first flowchart that illustrates the general processing steps for manufacturing the semiconductor devices of the present disclosure.

Referring to step 4910 and FIGS. 1-10B, 18-22, 29-33, and 39-41, a combination of a first-type insulating surface (such as a surface of a hydrogen-containing dielectric layer 10) and a second-type insulating surface (such as a surface of a hydrogen-blocking dielectric layer 30) may be formed over a substrate 8. The first-type insulating surface (such as a surface of a hydrogen-containing dielectric layer 10) is a surface of a hydrogen-containing dielectric material containing hydrogen atoms at a concentration greater than a first atomic concentration (which may be at least 100 parts per million as discussed above), and the second-type insulating surface (such as a surface of a hydrogen-blocking dielectric layer 30) is a hydrogen-impermeable surface of a hydrogen-blocking dielectric material.

Referring to step 4920 and FIGS. 11A and 11B, 23, 34, and 42, an amorphous metal oxide layer 20L may be deposited on the first-type insulating surface (such as a surface of a hydrogen-containing dielectric layer 10) and the second-type insulating surface (such as a surface of a hydrogen-blocking dielectric layer 30).

Referring to step 4930 and FIGS. 12A-17B, 24-28, 35-38, and 43-48, an anneal process may be performed at an elevated temperature. A first portion of the amorphous metal oxide layer 20L in contact with the first-type insulating surface (such as a surface of a hydrogen-containing dielectric layer 10) is converted into an n-type metal oxide semiconductor layer 22 due to oxygen loss to hydrogen atoms in the hydrogen-containing dielectric material during the anneal process, and a second portion of the amorphous metal oxide layer 20L in contact with the second-type insulating surface (such as a surface of a hydrogen-blocking dielectric layer 30) is converted into a p-type metal oxide semiconductor layer 21 during the anneal process.

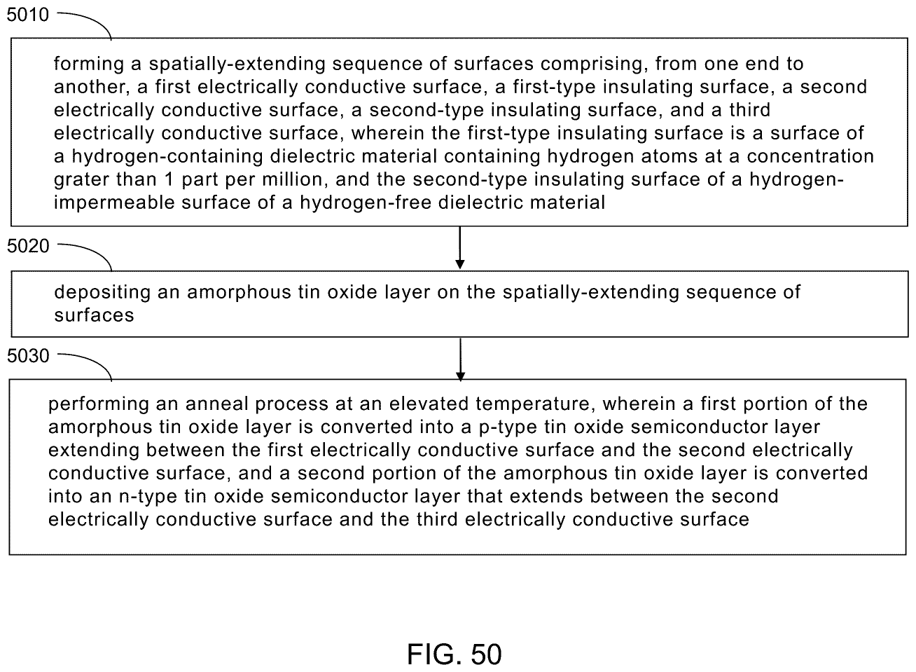

FIG. 50 is a second flowchart that illustrates the general processing steps for manufacturing the semiconductor devices of the present disclosure.

Referring to step S010 and FIGS. 1-10B and 18-22, a spatially-extending sequence of surfaces may be formed, which comprises, from one end to another, a first electrically conductive surface, a first-type insulating surface (such as a surface of a hydrogen-containing dielectric layer 10), a second electrically conductive surface, a second-type insulating surface (such as a surface of a hydrogen-blocking dielectric layer 30), and a third electrically conductive surface. The first-type insulating surface (such as a surface of a hydrogen-containing dielectric layer 10) is a surface of a hydrogen-containing dielectric material containing hydrogen atoms at a concentration greater than a first atomic concentration (which may be at least 100 parts per million as discussed above), and the second-type insulating surface (such as a surface of a hydrogen-blocking dielectric layer 30) of a hydrogen-impermeable surface of a hydrogen-blocking dielectric material;

Referring to step S020 and FIGS. 11A and 11B and 23, an amorphous metal oxide layer 20L may be deposited on the spatially-extending sequence of surfaces.

Referring to step S030 and FIGS. 12A-17B, 24-28, 47, and 48, an anneal process may be performed at an elevated temperature. A first portion of the amorphous metal oxide layer 20L is converted into a p-type metal oxide semiconductor layer 21 extending between the first electrically conductive surface and the second electrically conductive surface, and a second portion of the amorphous metal oxide layer 20L is converted into an n-type metal oxide semiconductor layer 22 extending between the second electrically conductive surface and the third electrically conductive surface.

The various embodiments of the present disclosure may be used to provide a combination of a p-type metal oxide semiconductor layer 21 and an n-type metal oxide semiconductor layer 22 by depositing a amorphous metal oxide layer 20L and differentiating the post-anneal properties of different regions of the amorphous metal oxide layer 20L through modulation of the concentration of oxygen vacancy. The modulation of the concentration of oxygen vacancy may be effected through use of a combination of a hydrogen-containing dielectric layer 10 and a hydrogen-blocking dielectric layer 30. Alkaline-earth metal oxide layers may be used for the hydrogen-blocking dielectric layer 30.

The foregoing outlines features of several embodiments so that those skilled in the art may better understand the aspects of the present disclosure. Each embodiment described using the term “comprises” also inherently discloses that the term “comprises” may be replaced with “consists essentially of” or with the term “consists of” in some embodiments, unless expressly disclosed otherwise herein. Whenever two or more elements are listed as alternatives in a same paragraph of in different paragraphs, a Markush group including a listing of the two or more elements may be also impliedly disclosed in some embodiments. Whenever the auxiliary verb “can” is used in this disclosure to describe formation of an element or performance of a processing step, an embodiment in which such an element or such a processing step is not performed is also expressly contemplated, provided that the resulting apparatus or device may provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor structure comprising:
forming a combination of a first-type insulating surface and a second-type insulating surface over a substrate, wherein the first-type insulating surface is a surface of a hydrogen-containing dielectric material containing hydrogen atoms at a first atomic concentration, and the second-type insulating surface is a hydrogen-impermeable surface of a hydrogen-blocking dielectric material containing hydrogen atoms at a second atomic concentration lower than the first atomic concentration;
depositing an amorphous metal oxide layer on the first-type insulating surface and the second-type insulating surface; and
performing an anneal process at an elevated temperature, wherein a first portion of the amorphous metal oxide layer in contact with the first-type insulating surface is converted into an n-type metal oxide semiconductor layer during the anneal process, and a second portion of the amorphous metal oxide layer in contact with the second-type insulating surface is converted into a p-type metal oxide semiconductor layer during the anneal process.

2. The method of claim 1, wherein:
the first-type insulating surface is formed between a first electrically conductive surface of a first electrically conductive material portion and a second electrically conductive surface of a second electrically conductive material portion; and
the second-type insulating surface is formed between the second electrically conductive surface and a third electrically conductive surface of a third electrically conductive material portion.

3. The method of claim 2, wherein:
each of the first electrically conductive material portion, the second electrically conductive material portion, and the third electrically conductive material portion comprises a respective source/drain electrode;
the p-type metal oxide semiconductor layer comprises a channel of a p-channel thin-film transistor; and
the n-type metal oxide semiconductor layer comprises a channel of an n-channel thin-film transistor.

4. The method of claim 2, further comprising:
forming a vertical stack comprising, from bottom to top or from bottom to top, a first electrically conductive material layer, a first insulating material layer comprising the hydrogen-containing dielectric material, a second electrically conductive material layer, a second insulating material layer comprising the hydrogen-blocking dielectric material, and a third electrically conductive material layer; and
patterning the vertical stack such that each layer within the vertical stack has a respective sidewall, wherein:
the first electrically conductive surface is a sidewall of the first electrically conductive material layer;
the second electrically conductive surface is a sidewall of the second electrically conductive material layer; and
the third electrically conductive surface is a sidewall of the third electrically conductive material layer.

5. The method of claim 4, wherein the method comprises forming a vertically-extending via cavity through the vertical stack, wherein the first electrically conductive surface, the second electrically conductive surface, and the third electrically conductive surface are surface segments of the vertically-extending via cavity that are vertically coincident with one another.

6. The method of claim 2, wherein the combination of the first-type insulating surface and the second-type insulating surface is formed by:
forming an insulating layer comprising the hydrogen-containing dielectric material over the substrate;
forming a recess region by vertically recessing a portion of a top surface of the insulating layer; and
filling the recess region with a portion of the hydrogen-blocking dielectric material, wherein:
the first-type insulating surface comprises a remaining portion of the top surface of the insulating layer; and
the second-type insulating surface comprises a top surface of the portion of the hydrogen-blocking dielectric material.

7. The method of claim 6, further comprising:
forming cavities in a combination comprising the insulating layer and the portion of the hydrogen-blocking dielectric material; and
filling the cavities with at least one electrically conductive material, wherein the first electrically conductive material portion, the second electrically conductive material portion, and the third electrically conductive material portion comprise a respective portion of the at least one electrically conductive material that fills a respective one of the cavities.

8. The method of claim 1, further comprising depositing a gate dielectric layer over the amorphous metal oxide layer, wherein the anneal process is performed after depositing the gate dielectric layer.

9. The method of claim 8, further comprising:
depositing a gate electrode material layer over the gate dielectric layer; and
patterning the gate electrode material layer and the gate dielectric layer into at least one gate electrode and at least one gate dielectric.

10. The method of claim 1, further comprising:
forming a first gate electrode and a second gate electrode embedded within a dielectric matrix layer over the substrate;
forming a first-type gate dielectric over the first gate electrode and a second-type gate dielectric over the second gate electrode, wherein:
the first-type insulating surface is a top surface of the first-type gate dielectric; and
the second-type insulating surface is a top surface of the second-type gate dielectric.

11. The method of claim 10, further comprising:
forming a contact-level dielectric layer over the p-type metal oxide semiconductor layer and the n-type metal oxide semiconductor layer; and
forming source/drain electrodes through the contact-level dielectric layer on a respective portion of the p-type metal oxide semiconductor layer and the n-type metal oxide semiconductor layer.

12. A method of forming a semiconductor structure comprising:
forming a spatially-extending sequence of surfaces comprising, from one end to another, a first electrically conductive surface, a first-type insulating surface, a second electrically conductive surface, a second-type insulating surface, and a third electrically conductive surface, wherein the first-type insulating surface is a surface of a hydrogen-containing dielectric material containing hydrogen atoms at a concentration greater than a first atomic concentration, and the second-type insulating surface of a hydrogen-impermeable surface of a hydrogen-blocking dielectric material;
depositing an amorphous metal oxide layer on the spatially-extending sequence of surfaces; and
performing an anneal process at an elevated temperature, wherein a first portion of the amorphous metal oxide layer is converted into an n-type metal oxide semiconductor layer extending between the first electrically conductive surface and the second electrically conductive surface, and a second portion of the amorphous metal oxide layer is converted into a p-type metal oxide semiconductor layer extending between the second electrically conductive surface and the third electrically conductive surface.

13. The method of claim 12, wherein the spatially-extending sequence of surfaces is formed by:
forming a vertical stack comprising, from bottom to top or from bottom to top, a first electrically conductive material layer, a first insulating material layer comprising the hydrogen-containing dielectric material, a second electrically conductive material layer, a second insulating material layer comprising the hydrogen-blocking dielectric material, and a third electrically conductive material layer; and
performing an anisotropic etch process that patterns the vertical stack using an etch mask.

14. The method of claim 13, wherein:
the anisotropic etch process forms a vertically-extending via cavity through the vertical stack; and
the spatially-extending sequence of surfaces comprises surface segments of the vertical stack around the vertically-extending via cavity.

15. The method claim 14, further comprising:
depositing a gate dielectric layer over the amorphous metal oxide layer, wherein the anneal process is performed after depositing the gate dielectric layer; and
forming a gate electrode on the gate dielectric layer.

16. A semiconductor structure comprising:
a p-type metal oxide semiconductor layer and an n-type metal oxide semiconductor layer;
a hydrogen-containing dielectric material portion having a first-type insulating surface that contacts the n-type metal oxide semiconductor layer; and
a hydrogen-blocking dielectric material portion comprising a second-type insulating surface that contacts the p-type metal oxide semiconductor layer, the second-type insulating surface being a hydrogen-impermeable surface.

17. The semiconductor structure of claim 16, further comprising:
a first electrically conductive material portion in contact with a first portion of the p-type metal oxide semiconductor layer;
a second electrically conductive material portion in contact with a second portion of the p-type metal oxide semiconductor layer and a first portion of the n-type metal oxide semiconductor layer; and
a third electrically conductive material portion in contact with a second portion of the n-type metal oxide semiconductor layer.

18. The semiconductor structure of claim 17, wherein the first electrically conductive material portion, the second electrically conductive material portion, and the third electrically conductive material portion comprise three electrically conductive material layers that are vertically spaced from one another along a vertical direction that is perpendicular to a top surface of a substrate.

19. The semiconductor structure of claim 17, wherein:
the p-type metal oxide semiconductor layer comprises a channel of a p-channel thin-film transistor;
the n-type metal oxide semiconductor layer comprises a channel of an n-channel thin-film transistor; and
the first electrically conductive material portion, the second electrically conductive material portion, and the third electrically conductive material portion comprise source/drain electrodes of a combination of the p-channel thin-film transistor and the n-channel thin-film transistor.

20. The semiconductor structure of claim 16, further comprising at least one gate structure comprising a respective gate dielectric and a respective gate electrode, wherein each of the p-type metal oxide semiconductor layer and the n-type metal oxide semiconductor layer is contacted by the at least one gate structure.
